(19) United States
(12) Patent Application Publication
(10) Pub. No.: US 2013/0299794 A1
(43) Pub. Date: Nov. 14, 2013

(54) COMPOUND FOR ORGANIC OPTOELECTRONIC DEVICE, ORGANIC LIGHT EMITTING DIODE INCLUDING THE SAME AND DISPLAY INCLUDING THE ORGANIC LIGHT EMITTING DIODE

(71) Applicants: Ho-Kuk JUNG, Uiwang-si (KR); Dong-Min KANG, Uiwang-si (KR); Myeong-Soon KANG, Uiwang-si (KR); Eui-Su KANG, Uiwang-si (KR); Nam-Soo KIM, Uiwang-si (KR); Nam-Heon LEE, Uiwang-si (KR); Mi-Young CHAE, Uiwang-si (KR)

(72) Inventors: Ho-Kuk JUNG, Uiwang-si (KR); Dong-Min KANG, Uiwang-si (KR); Myeong-Soon KANG, Uiwang-si (KR); Eui-Su KANG, Uiwang-si (KR); Nam-Soo KIM, Uiwang-si (KR); Nam-Heon LEE, Uiwang-si (KR); Mi-Young CHAE, Uiwang-si (KR)

(21) Appl. No.: 13/931,829

(22) Filed: Jun. 29, 2013

Related U.S. Application Data
(63) Continuation of application No. PCT/KR2011/005378, filed on Jul. 21, 2011.

(30) Foreign Application Priority Data
Dec. 31, 2010 (KR) 10-2010-0140595

(51) Int. Cl. H01L 51/00

(52) U.S. Cl. CPC H01L 51/0072; H01L 51/0058
USPC 257/40; 544/333

(57) ABSTRACT

A compound for an organic optoelectronic device, the compound being represented by the following Chemical Formula 1:

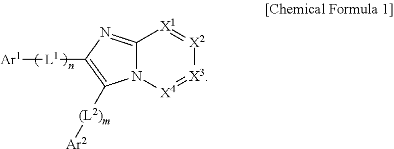

### CROSS-REFERENCE TO RELATED APPLICATIONS

This application is a continuation of pending International Application No. PCT/KR2011/005378, entitled “Compound for Organic Optoelectronic Device, Organic Light Emitting Diode Including the Same and Display Including the Organic Light Emitting Diode,” which was filed on Jul. 21, 2011, the entire contents of which are hereby incorporated by reference.

Korean Patent Application No. 10-2010-0140595, filed on Dec. 31, 2010, in the Korean Intellectual Property Office, and entitled: “Compound for Organic Optoelectronic Device, Organic Light Emitting Diode Including the Same and Display Including the Organic Light Emitting Diode,” is incorporated by reference herein in its entirety.

### BACKGROUND

1. Field

Embodiments relate to a compound for an organic optoelectronic device, an organic light emitting diode including the same, and a display device including the organic light emitting diode.

2. Description of the Related Art

An organic optoelectronic device is, in a broad sense, a device for transforming photo-energy to electrical energy or conversely, a device for transforming electrical energy to photo-energy.

An organic optoelectronic device may be classified as follows in accordance with its driving principles. One type of organic optoelectronic device is an electronic device driven as follows: excitons are generated in an organic material layer by photons from an external light source; the excitons are separated into electrons and holes; and the electrons and holes are transferred to different electrodes as a current source (voltage source).

Another type of organic optoelectronic device is an electronic device driven as follows: a voltage or a current is applied to at least two electrodes to inject holes and/or electrons into an organic material semiconductor positioned at an interface of the electrodes, and the device is driven by the injected electrons and holes.

Examples of the organic optoelectronic device may include an organic light emitting diode, an organic solar cell, an organic photo conductor drum, and an organic transistor, and the like, which require a hole injecting or transport material, an electron injecting or transport material, or a light emitting material.

### SUMMARY

Embodiments are directed to a compound for an organic optoelectronic device, an organic light emitting diode including the same, and a display device including the organic light emitting diode.

The embodiments may be realized by providing a compound for an organic optoelectronic device, the compound being represented by the following Chemical Formula 1:

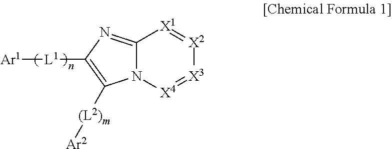

wherein, in Chemical Formula 1, X¹ to X⁴ are each independently —N—, —CR¹—, —CR²—, —CR³— or —CR⁴—, R¹ to R⁴ are each independently hydrogen, deuterium, a substituted or unsubstituted C1 to C20 alkyl group, a substituted or unsubstituted C6 to C30 aryl group, a substituted or unsubstituted C3 to C30 heteroaryl group, or a combination thereof, L¹ and L² are each independently a single bond, a substituted or unsubstituted C2 to C6 alkenyl group, a substituted or unsubstituted C2 to C6 alkynyl group, a substituted or unsubstituted C6 to C30 arylene group, a substituted or unsubstituted C3 to C30 heteroarylene group, or a combination thereof, n and m are each independently 1 or 2, Ar¹ and Ar² are each independently hydrogen, deuterium, a substituted or unsubstituted C1 to C20 alkyl group, a substituted or unsubstituted C6 to C30 aryl group, a substituted or unsubstituted C3 to C30 heteroaryl group, or a combination thereof, and at least one of Ar¹ or Ar² is a substituted or unsubstituted C3 to C30 heteroaryl group having electronic properties.

The compound may be represented by the following Chemical Formula 2:

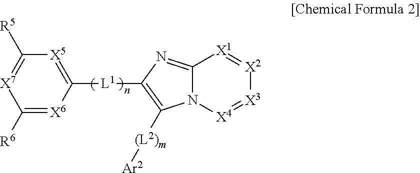

wherein, in Chemical Formula 2, X¹ to X⁴ are each independently —N—, —CR¹—, —CR²—, —CR³— or —CR⁴—, R¹ to R⁶ are each independently hydrogen, deuterium, a substituted or unsubstituted C1 to C20 alkyl group, a substituted or unsubstituted C6 to C30 aryl group, a substituted or unsubstituted C3 to C30 heteroaryl group, or a combination thereof, L¹ and L² are each independently a single bond, a substituted or unsubstituted C2 to C6 alkenyl group, a substituted or unsubstituted C2 to C6 alkynyl group, a substituted or unsubstituted C6 to C30 arylene group, a substituted or unsubstituted C3 to C30 heteroarylene group, or a combination thereof, n and m are each independently 1 or 2, Ar² is hydrogen, deuterium, a substituted or unsubstituted C1 to C20 alkyl group, a substituted or unsubstituted C6 to C30 aryl group, a substituted or unsubstituted C3 to C30 heteroaryl group, or a combination thereof, X⁵ to X⁷ are each independently —N— or —CR′—, wherein R′ is hydrogen or deuterium, and at least one of X⁵ to X⁷ is —N—.

Ar² may be a substituted or unsubstituted naphthyl group, a substituted or unsubstituted anthracenyl group, a substituted or unsubstituted phenanthrenyl group, a substituted or unsubstituted triphenylenyl group, a substituted or unsubstituted pyrenyl group, a substituted or unsubstituted chrysenyl group, or a combination thereof.

The compound may be represented by the following Chemical Formula 3:

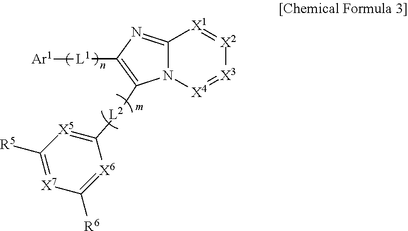

wherein, in Chemical Formula 3, X¹ to X⁴ are each independently —N—, —CR¹—, —CR²—, —CR³— or —CR⁴—, R¹ to R⁶ are each independently hydrogen, deuterium, a substituted or unsubstituted C1 to C20 alkyl group, a substituted or unsubstituted C6 to C30 aryl group, a substituted or unsubstituted C3 to C30 heteroaryl group, or a combination thereof, L¹ and L² are each independently a single bond, a substituted or unsubstituted C2 to C6 alkenyl group, a substituted or unsubstituted C2 to C6 alkynyl group, a substituted or unsubstituted C6 to C30 arylene group, a substituted or unsubstituted C3 to C30 heteroarylene group, or a combination thereof, n and m are each independently 1 or 2, Ar¹ is hydrogen, deuterium, a substituted or unsubstituted C1 to C20 alkyl group, a substituted or unsubstituted C6 to C30 aryl group, a substituted or unsubstituted C3 to C30 heteroaryl group, or a combination thereof, X⁵ to X⁷ are each independently —N— or —CR′—, wherein R′ is hydrogen or deuterium, and at least one of X⁵ to X⁷ is —N—.

Ar¹ may be a substituted or unsubstituted naphthyl group, a substituted or unsubstituted anthracenyl group, a substituted or unsubstituted phenanthrenyl group, a substituted or unsubstituted triphenylenyl group, a substituted or unsubstituted pyrenyl group, a substituted or unsubstituted chrysenyl group, or a combination thereof.

The substituted or unsubstituted C3 to C30 heteroaryl group having the electronic properties may be a substituted or unsubstituted imidazolyl group, a substituted or unsubstituted triazolyl group, a substituted or unsubstituted tetrazolyl group, a substituted or unsubstituted carbazolyl group, a substituted or unsubstituted oxadiazolyl group, a substituted or unsubstituted oxatriazolyl group, a substituted or unsubstituted thiatriazolyl group, a substituted or unsubstituted benzimidazolyl group, a substituted or unsubstituted benzotriazolyl group, a substituted or unsubstituted pyridinyl group, a substituted or unsubstituted pyrimidinyl group, a substituted or unsubstituted triazinyl group, a substituted or unsubstituted pyrazinyl group, a substituted or unsubstituted pyridazinyl group, a substituted or unsubstituted purinyl group, a substituted or unsubstituted quinolinyl group, a substituted or unsubstituted isoquinolinyl group, a substituted or unsubstituted phthalazinyl group, a substituted or unsubstituted naphpyridinyl group, a substituted or unsubstituted quinoxalinyl group, a substituted or unsubstituted quinazolinyl group, a substituted or unsubstituted acridinyl group, a substituted or unsubstituted phenanthrolinyl group, a substituted or unsubstituted phenazinyl group, or a combination thereof.

The compound may be represented by one of the following Chemical Formulae A1 to A63:

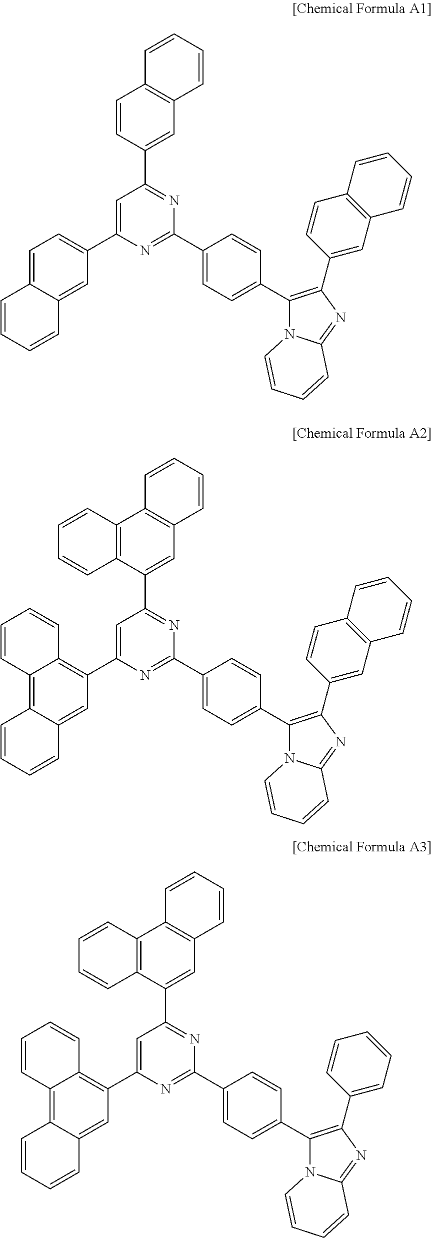 [SMILES: c1ccc2cc(-c3cc(-c4ccc5ccccc5c4)nc(-c4ccc(-c5c(-c6ccc7ccccc7c6)nc6ccccn56)cc4)n3)ccc2c1 ; c1ccc2cc(-c3nc4ccccn4c3-c3ccc(-c4nc(-c5cc6ccccc6c6ccccc56)cc(-c5cc6ccccc6c6ccccc56)n4)cc3)ccc2c1 ; c1ccc(-c2nc3ccccn3c2-c2ccc(-c3nc(-c4cc5ccccc5c5ccccc45)cc(-c4cc5ccccc5c5ccccc45)n3)cc2)cc1]

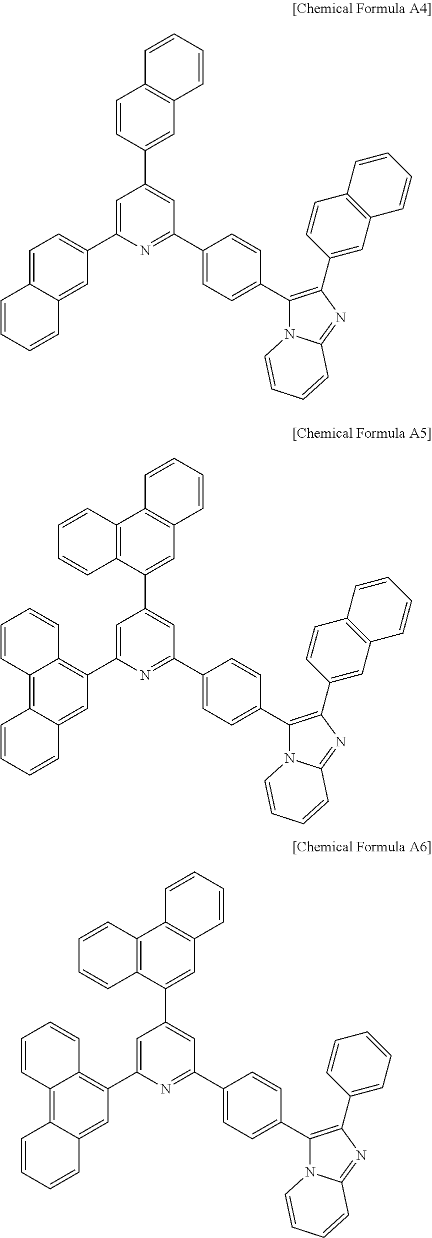 [SMILES: c1ccc2cc(-c3cc(-c4ccc(-c5c(-c6ccc7ccccc7c6)nc6ccccn56)cc4)nc(-c4ccc5ccccc5c4)c3)ccc2c1 ; c1ccc2cc(-c3nc4ccccn4c3-c3ccc(-c4cc(-c5cc6ccccc6c6ccccc56)cc(-c5cc6ccccc6c6ccccc56)n4)cc3)ccc2c1 ; c1ccc(-c2nc3ccccn3c2-c2ccc(-c3cc(-c4cc5ccccc5c5ccccc45)cc(-c4cc5ccccc5c5ccccc45)n3)cc2)cc1]

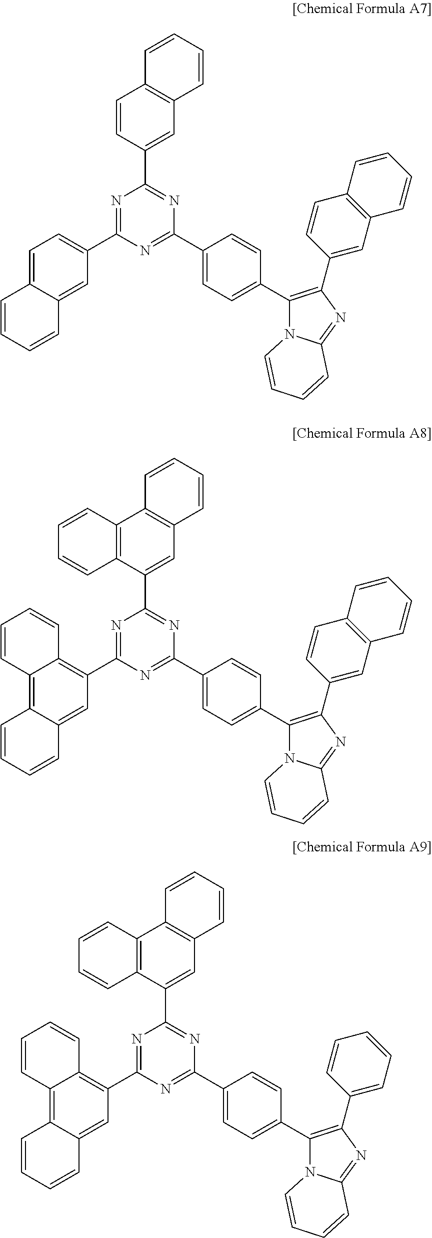 [SMILES: c1ccc2cc(-c3nc(-c4ccc(-c5c(-c6ccc7ccccc7c6)nc6ccccn56)cc4)nc(-c4ccc5ccccc5c4)n3)ccc2c1 ; c1ccc2cc(-c3nc4ccccn4c3-c3ccc(-c4nc(-c5cc6ccccc6c6ccccc56)nc(-c5cc6ccccc6c6ccccc56)n4)cc3)ccc2c1 ; c1ccc(-c2nc3ccccn3c2-c2ccc(-c3nc(-c4cc5ccccc5c5ccccc45)nc(-c4cc5ccccc5c5ccccc45)n3)cc2)cc1]

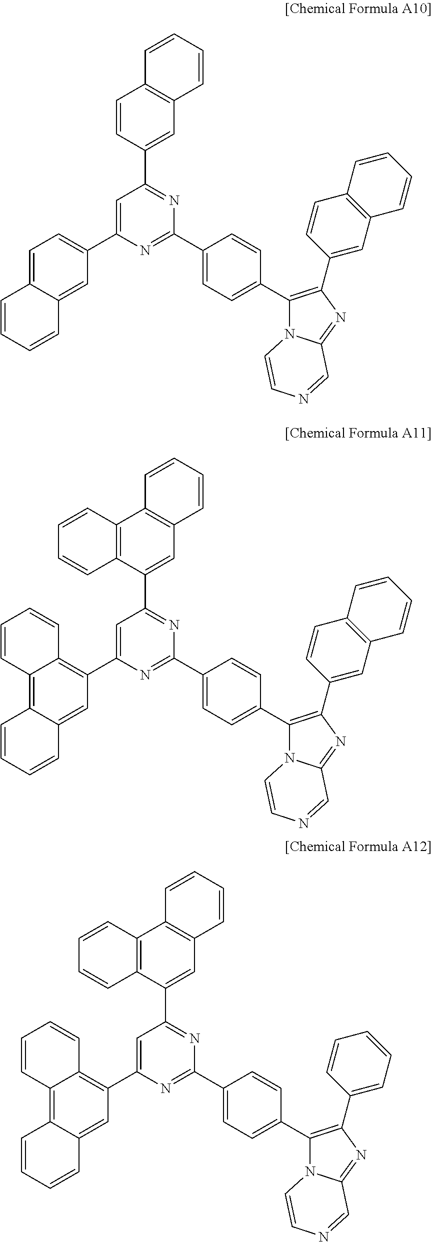 [SMILES: c1ccc2cc(-c3cc(-c4ccc5ccccc5c4)nc(-c4ccc(-c5c(-c6ccc7ccccc7c6)nc6cnccn56)cc4)n3)ccc2c1 ; c1ccc2cc(-c3nc4cnccn4c3-c3ccc(-c4nc(-c5cc6ccccc6c6ccccc56)cc(-c5cc6ccccc6c6ccccc56)n4)cc3)ccc2c1 ; c1ccc(-c2nc3cnccn3c2-c2ccc(-c3nc(-c4cc5ccccc5c5ccccc45)cc(-c4cc5ccccc5c5ccccc45)n3)cc2)cc1]

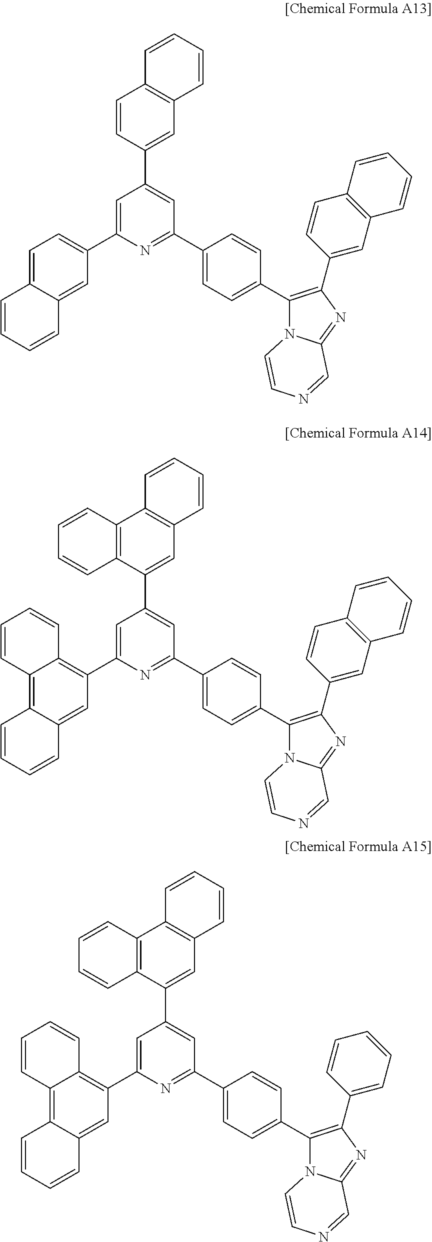 [SMILES: c1ccc2cc(-c3cc(-c4ccc(-c5c(-c6ccc7ccccc7c6)nc6cnccn56)cc4)nc(-c4ccc5ccccc5c4)c3)ccc2c1 ; c1ccc2cc(-c3nc4cnccn4c3-c3ccc(-c4cc(-c5cc6ccccc6c6ccccc56)cc(-c5cc6ccccc6c6ccccc56)n4)cc3)ccc2c1 ; c1ccc(-c2nc3cnccn3c2-c2ccc(-c3cc(-c4cc5ccccc5c5ccccc45)cc(-c4cc5ccccc5c5ccccc45)n3)cc2)cc1]

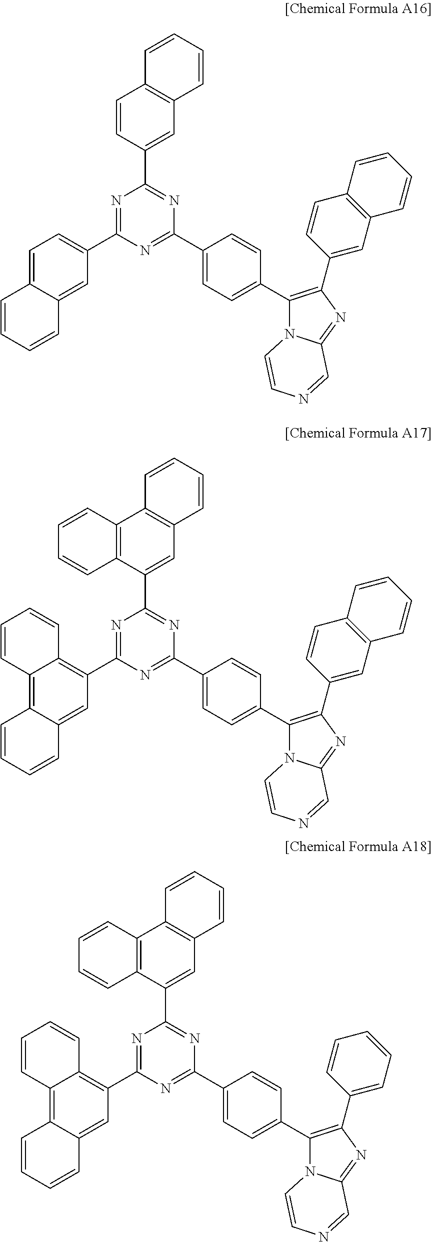 [SMILES: c1ccc2cc(-c3nc(-c4ccc(-c5c(-c6ccc7ccccc7c6)nc6cnccn56)cc4)nc(-c4ccc5ccccc5c4)n3)ccc2c1 ; c1ccc2cc(-c3nc4cnccn4c3-c3ccc(-c4nc(-c5cc6ccccc6c6ccccc56)nc(-c5cc6ccccc6c6ccccc56)n4)cc3)ccc2c1 ; c1ccc(-c2nc3cnccn3c2-c2ccc(-c3nc(-c4cc5ccccc5c5ccccc45)nc(-c4cc5ccccc5c5ccccc45)n3)cc2)cc1]

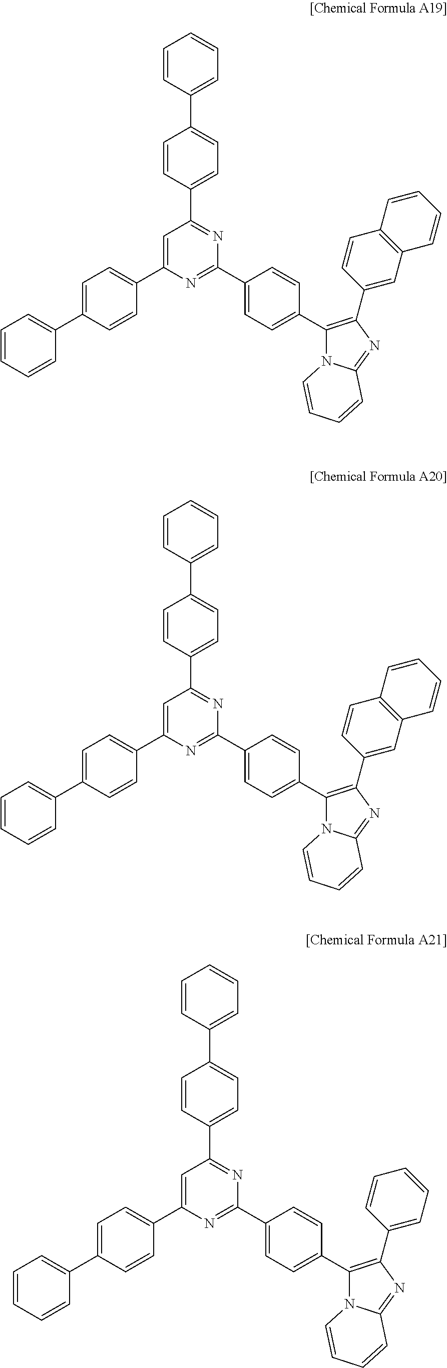 [SMILES: c1ccc(-c2ccc(-c3cc(-c4ccc(-c5ccccc5)cc4)nc(-c4ccc(-c5c(-c6ccc7ccccc7c6)nc6ccccn56)cc4)n3)cc2)cc1 ; c1ccc(-c2ccc(-c3cc(-c4ccc(-c5ccccc5)cc4)nc(-c4ccc(-c5c(-c6ccc7ccccc7c6)nc6ccccn56)cc4)n3)cc2)cc1 ; c1ccc(-c2ccc(-c3cc(-c4ccc(-c5ccccc5)cc4)nc(-c4ccc(-c5c(-c6ccccc6)nc6ccccn56)cc4)n3)cc2)cc1]

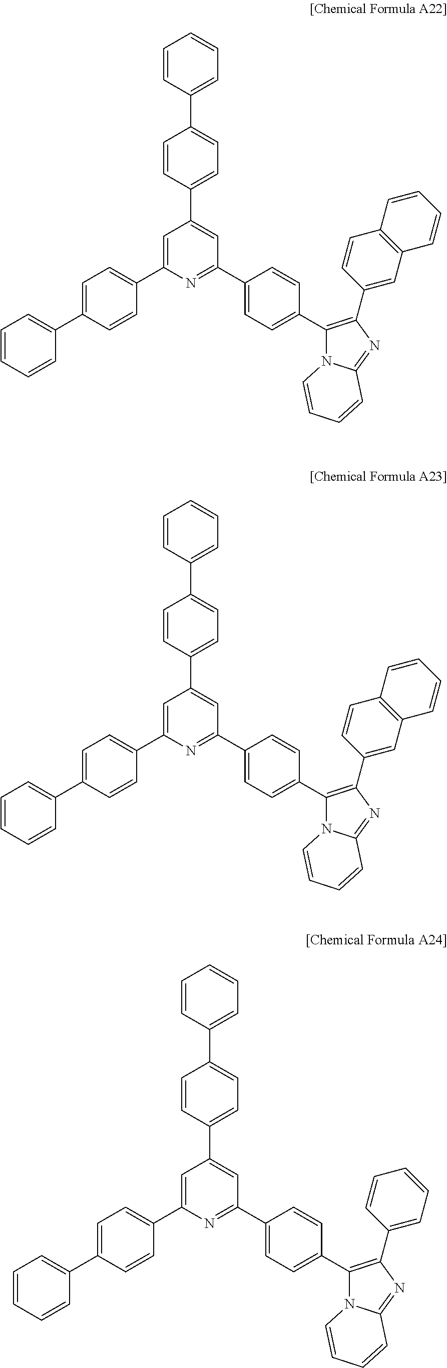 [SMILES: c1ccc(-c2ccc(-c3cc(-c4ccc(-c5ccccc5)cc4)nc(-c4ccc(-c5c(-c6ccc7ccccc7c6)nc6ccccn56)cc4)c3)cc2)cc1 ; c1ccc(-c2ccc(-c3cc(-c4ccc(-c5ccccc5)cc4)nc(-c4ccc(-c5c(-c6ccc7ccccc7c6)nc6ccccn56)cc4)c3)cc2)cc1 ; c1ccc(-c2ccc(-c3cc(-c4ccc(-c5ccccc5)cc4)nc(-c4ccc(-c5c(-c6ccccc6)nc6ccccn56)cc4)c3)cc2)cc1]

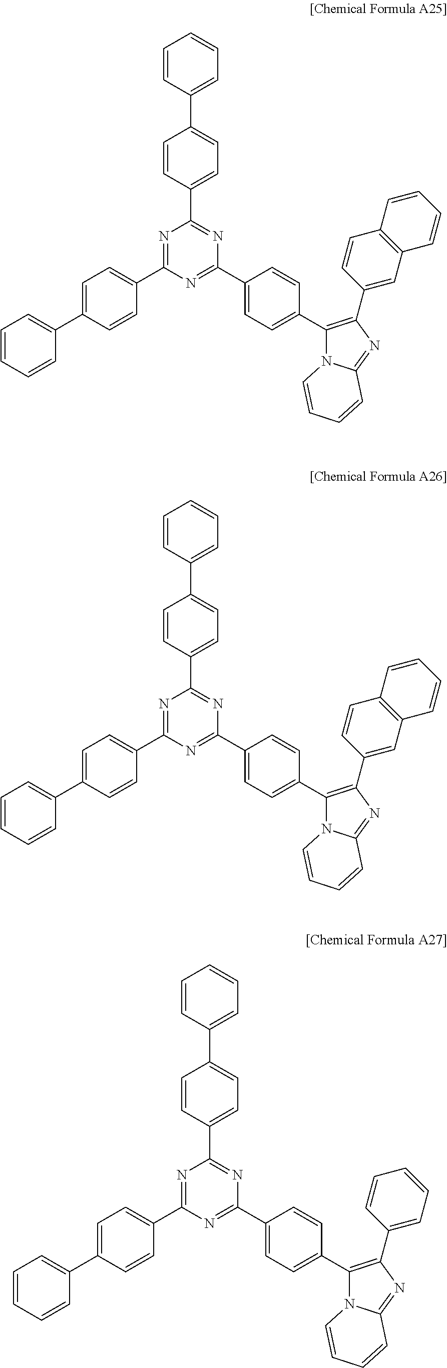 [SMILES: c1ccc(-c2ccc(-c3nc(-c4ccc(-c5ccccc5)cc4)nc(-c4ccc(-c5c(-c6ccc7ccccc7c6)nc6ccccn56)cc4)n3)cc2)cc1 ; c1ccc(-c2ccc(-c3nc(-c4ccc(-c5ccccc5)cc4)nc(-c4ccc(-c5c(-c6ccc7ccccc7c6)nc6ccccn56)cc4)n3)cc2)cc1 ; c1ccc(-c2ccc(-c3nc(-c4ccc(-c5ccccc5)cc4)nc(-c4ccc(-c5c(-c6ccccc6)nc6ccccn56)cc4)n3)cc2)cc1]

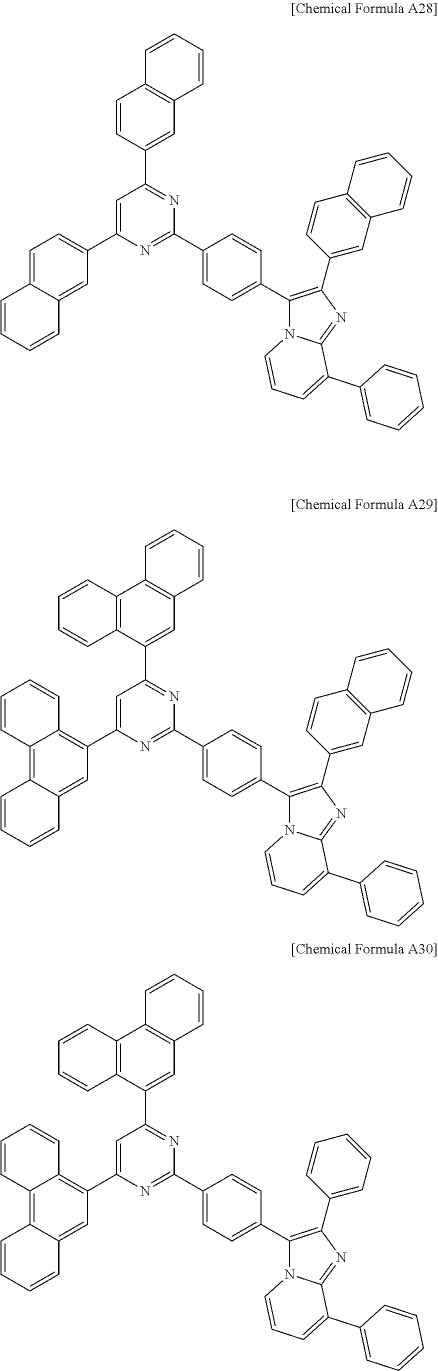 [SMILES: c1ccc(-c2cccn3c(-c4ccc(-c5nc(-c6ccc7ccccc7c6)cc(-c6ccc7ccccc7c6)n5)cc4)c(-c4ccc5ccccc5c4)nc23)cc1 ; c1ccc(-c2cccn3c(-c4ccc(-c5nc(-c6cc7ccccc7c7ccccc67)cc(-c6cc7ccccc7c7ccccc67)n5)cc4)c(-c4ccc5ccccc5c4)nc23)cc1 ; c1ccc(-c2nc3c(-c4ccccc4)cccn3c2-c2ccc(-c3nc(-c4cc5ccccc5c5ccccc45)cc(-c4cc5ccccc5c5ccccc45)n3)cc2)cc1]

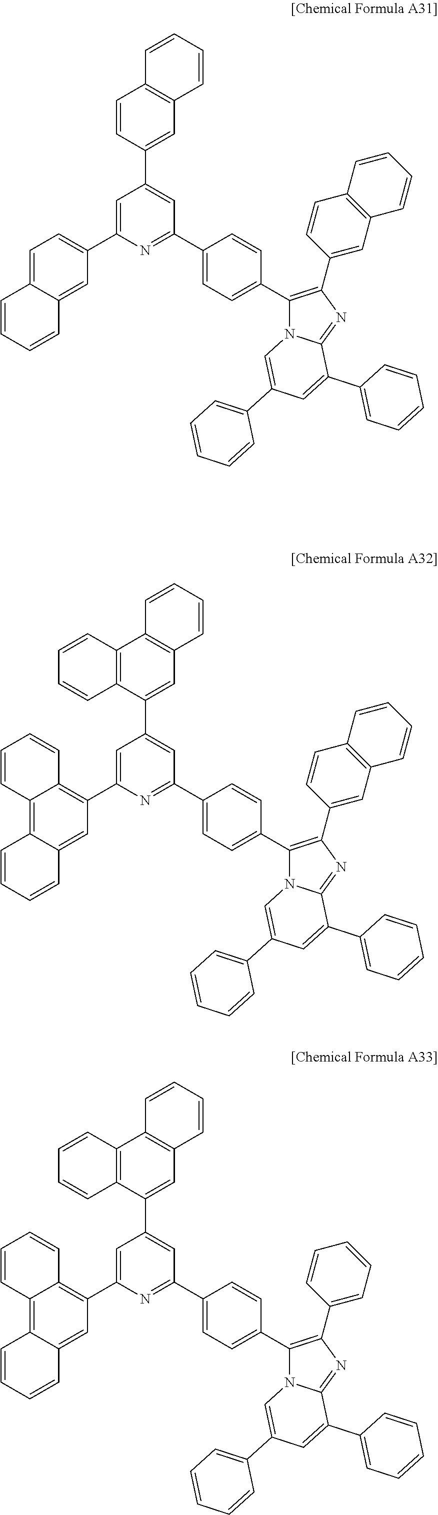 [SMILES: c1ccc(-c2cc(-c3ccccc3)c3nc(-c4ccc5ccccc5c4)c(-c4ccc(-c5cc(-c6ccc7ccccc7c6)cc(-c6ccc7ccccc7c6)n5)cc4)n3c2)cc1 ; c1ccc(-c2cc(-c3ccccc3)c3nc(-c4ccc5ccccc5c4)c(-c4ccc(-c5cc(-c6cc7ccccc7c7ccccc67)cc(-c6cc7ccccc7c7ccccc67)n5)cc4)n3c2)cc1 ; c1ccc(-c2cc(-c3ccccc3)c3nc(-c4ccccc4)c(-c4ccc(-c5cc(-c6cc7ccccc7c7ccccc67)cc(-c6cc7ccccc7c7ccccc67)n5)cc4)n3c2)cc1]

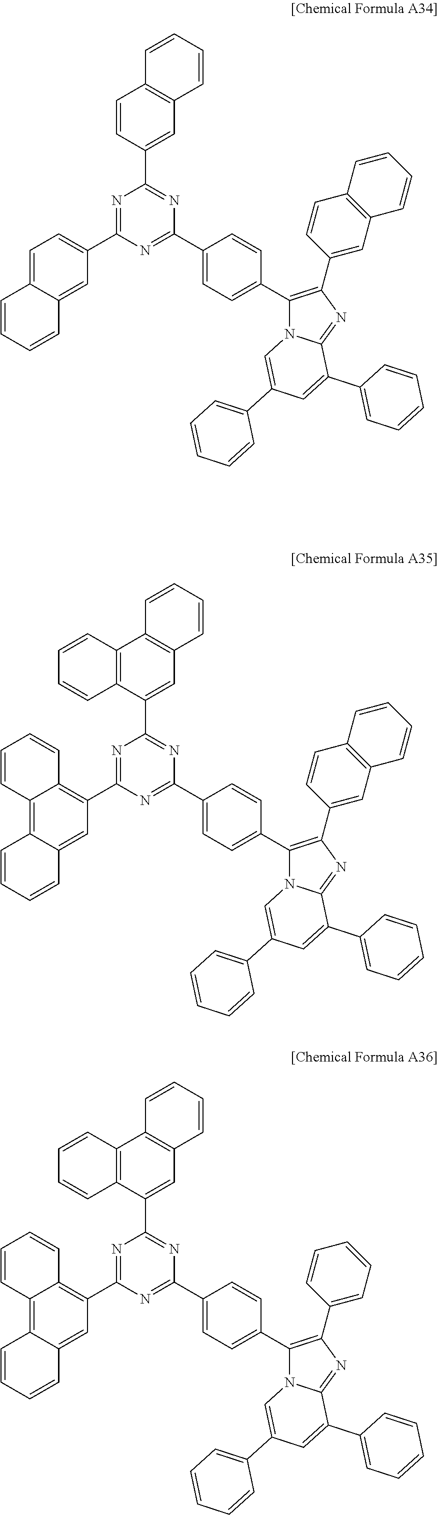 [SMILES: c1ccc(-c2cc(-c3ccccc3)c3nc(-c4ccc5ccccc5c4)c(-c4ccc(-c5nc(-c6ccc7ccccc7c6)nc(-c6ccc7ccccc7c6)n5)cc4)n3c2)cc1 ; c1ccc(-c2cc(-c3ccccc3)c3nc(-c4ccc5ccccc5c4)c(-c4ccc(-c5nc(-c6cc7ccccc7c7ccccc67)nc(-c6cc7ccccc7c7ccccc67)n5)cc4)n3c2)cc1 ; c1ccc(-c2cc(-c3ccccc3)c3nc(-c4ccccc4)c(-c4ccc(-c5nc(-c6cc7ccccc7c7ccccc67)nc(-c6cc7ccccc7c7ccccc67)n5)cc4)n3c2)cc1]

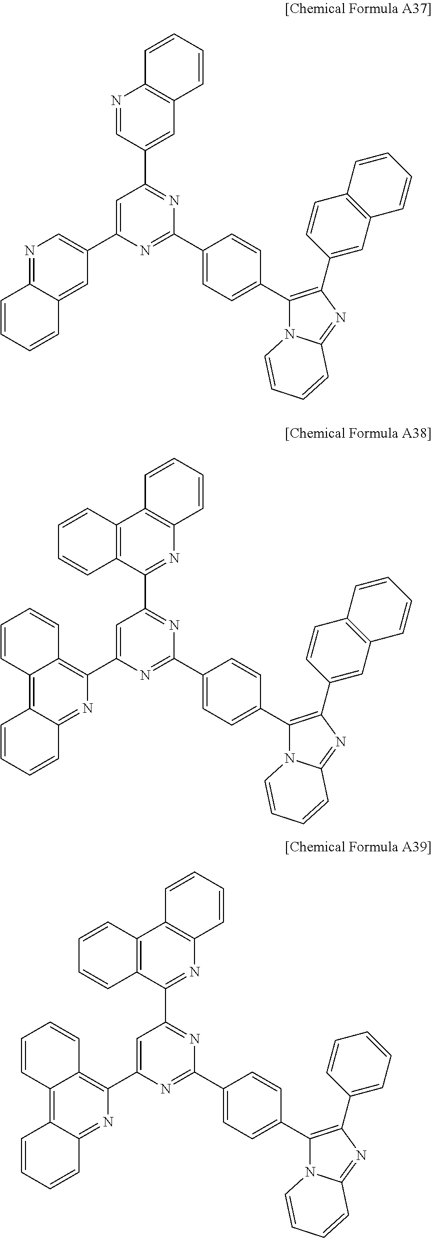 [SMILES: c1ccc2cc(-c3nc4ccccn4c3-c3ccc(-c4nc(-c5cnc6ccccc6c5)cc(-c5cnc6ccccc6c5)n4)cc3)ccc2c1 ; c1ccc2cc(-c3nc4ccccn4c3-c3ccc(-c4nc(-c5nc6ccccc6c6ccccc56)cc(-c5nc6ccccc6c6ccccc56)n4)cc3)ccc2c1 ; c1ccc(-c2nc3ccccn3c2-c2ccc(-c3nc(-c4nc5ccccc5c5ccccc45)cc(-c4nc5ccccc5c5ccccc45)n3)cc2)cc1]

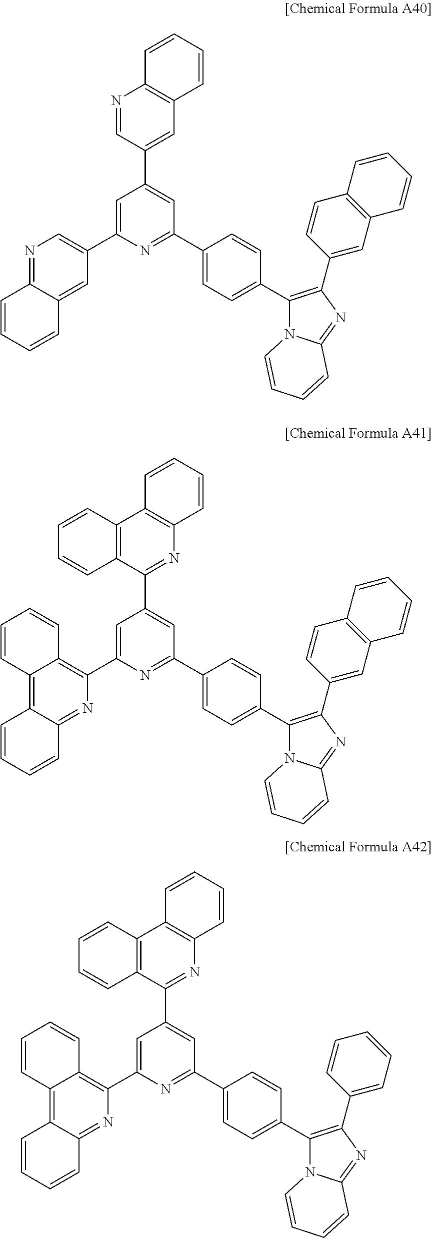 [SMILES: c1ccc2cc(-c3nc4ccccn4c3-c3ccc(-c4cc(-c5cnc6ccccc6c5)cc(-c5cnc6ccccc6c5)n4)cc3)ccc2c1 ; c1ccc2cc(-c3nc4ccccn4c3-c3ccc(-c4cc(-c5nc6ccccc6c6ccccc56)cc(-c5nc6ccccc6c6ccccc56)n4)cc3)ccc2c1 ; c1ccc(-c2nc3ccccn3c2-c2ccc(-c3cc(-c4nc5ccccc5c5ccccc45)cc(-c4nc5ccccc5c5ccccc45)n3)cc2)cc1]

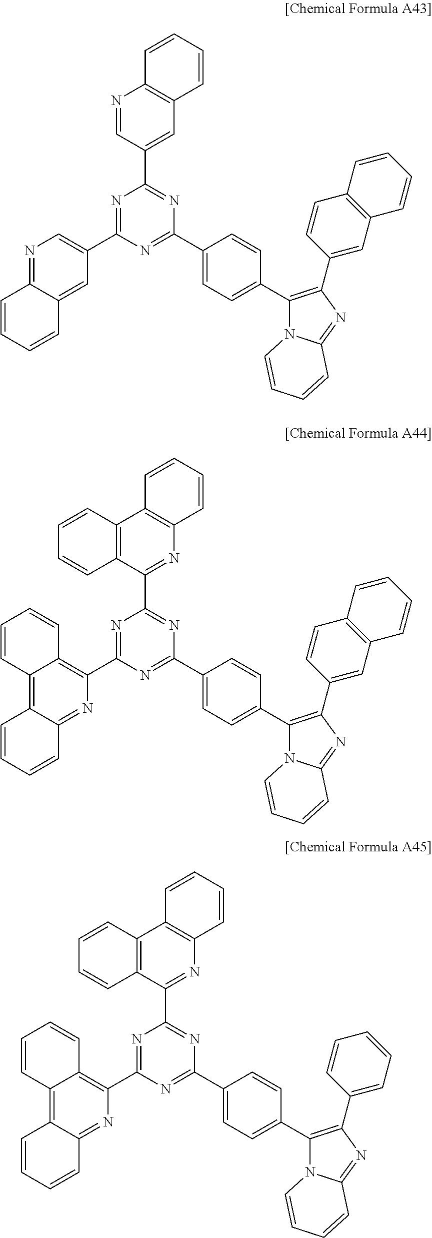 [SMILES: c1ccc2cc(-c3nc4ccccn4c3-c3ccc(-c4nc(-c5cnc6ccccc6c5)nc(-c5cnc6ccccc6c5)n4)cc3)ccc2c1 ; c1ccc2cc(-c3nc4ccccn4c3-c3ccc(-c4nc(-c5nc6ccccc6c6ccccc56)nc(-c5nc6ccccc6c6ccccc56)n4)cc3)ccc2c1 ; c1ccc(-c2nc3ccccn3c2-c2ccc(-c3nc(-c4nc5ccccc5c5ccccc45)nc(-c4nc5ccccc5c5ccccc45)n3)cc2)cc1]

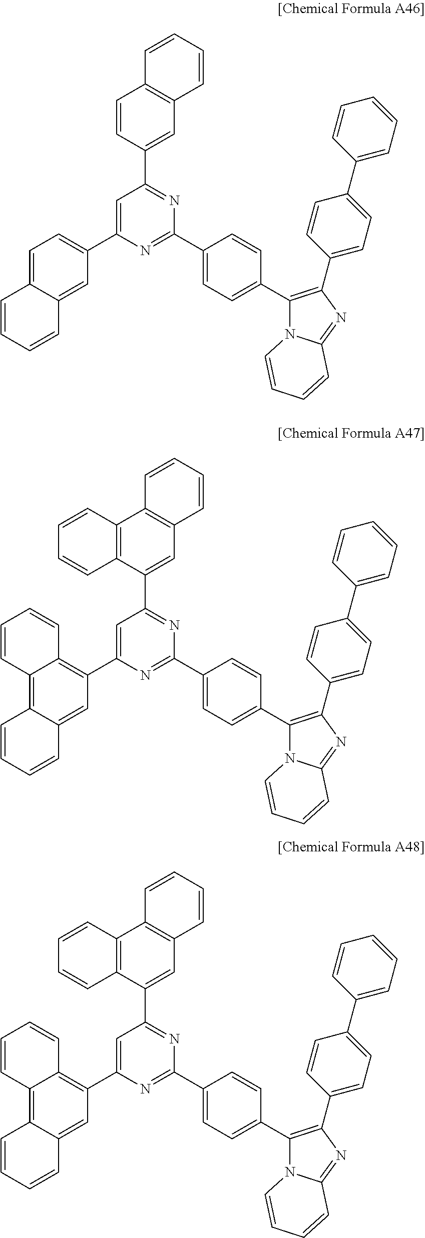 [SMILES: c1ccc(-c2ccc(-c3nc4ccccn4c3-c3ccc(-c4nc(-c5ccc6ccccc6c5)cc(-c5ccc6ccccc6c5)n4)cc3)cc2)cc1 ; c1ccc(-c2ccc(-c3nc4ccccn4c3-c3ccc(-c4nc(-c5cc6ccccc6c6ccccc56)cc(-c5cc6ccccc6c6ccccc56)n4)cc3)cc2)cc1 ; c1ccc(-c2ccc(-c3nc4ccccn4c3-c3ccc(-c4nc(-c5cc6ccccc6c6ccccc56)cc(-c5cc6ccccc6c6ccccc56)n4)cc3)cc2)cc1]

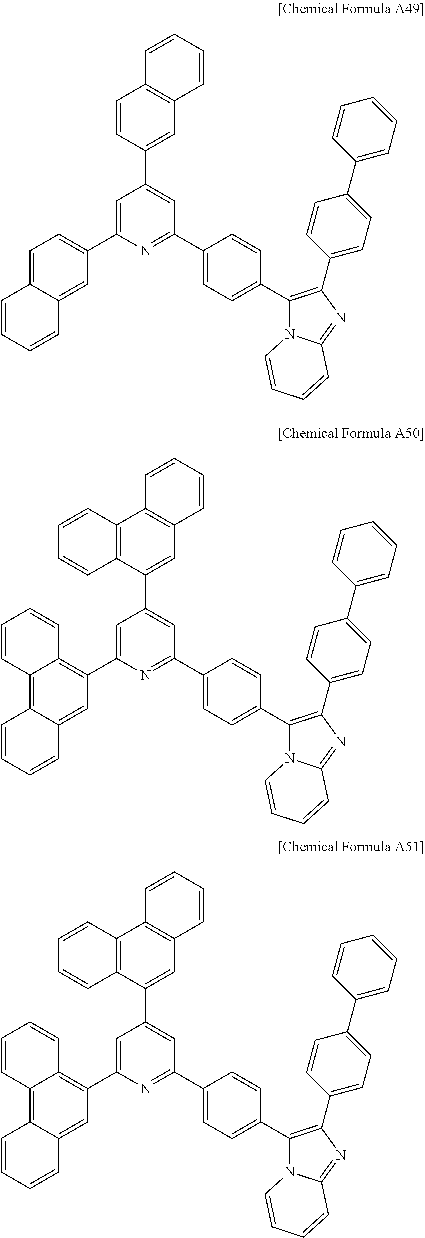 [SMILES: c1ccc(-c2ccc(-c3nc4ccccn4c3-c3ccc(-c4cc(-c5ccc6ccccc6c5)cc(-c5ccc6ccccc6c5)n4)cc3)cc2)cc1 ; c1ccc(-c2ccc(-c3nc4ccccn4c3-c3ccc(-c4cc(-c5cc6ccccc6c6ccccc56)cc(-c5cc6ccccc6c6ccccc56)n4)cc3)cc2)cc1 ; c1ccc(-c2ccc(-c3nc4ccccn4c3-c3ccc(-c4cc(-c5cc6ccccc6c6ccccc56)cc(-c5cc6ccccc6c6ccccc56)n4)cc3)cc2)cc1]

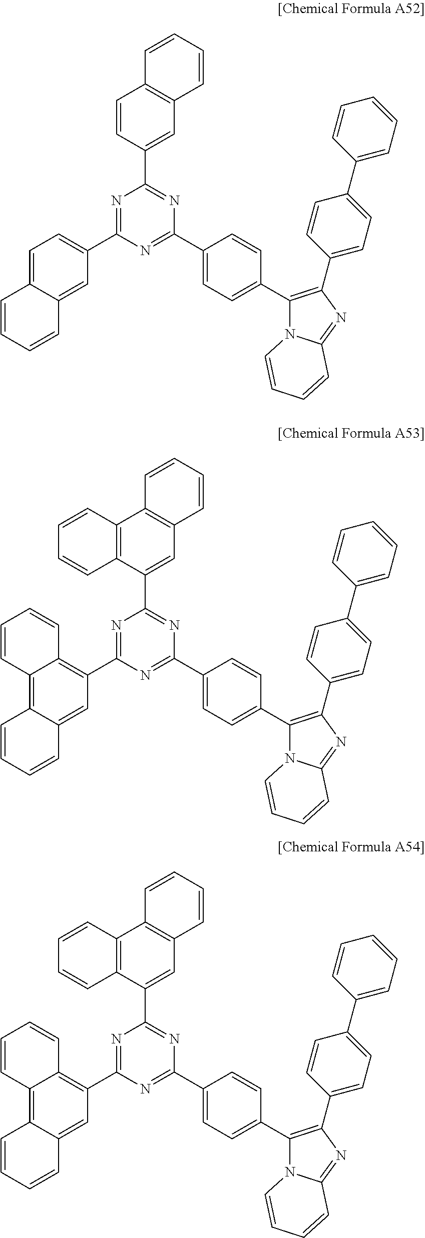 [SMILES: c1ccc(-c2ccc(-c3nc4ccccn4c3-c3ccc(-c4nc(-c5ccc6ccccc6c5)nc(-c5ccc6ccccc6c5)n4)cc3)cc2)cc1 ; c1ccc(-c2ccc(-c3nc4ccccn4c3-c3ccc(-c4nc(-c5cc6ccccc6c6ccccc56)nc(-c5cc6ccccc6c6ccccc56)n4)cc3)cc2)cc1 ; c1ccc(-c2ccc(-c3nc4ccccn4c3-c3ccc(-c4nc(-c5cc6ccccc6c6ccccc56)nc(-c5cc6ccccc6c6ccccc56)n4)cc3)cc2)cc1]

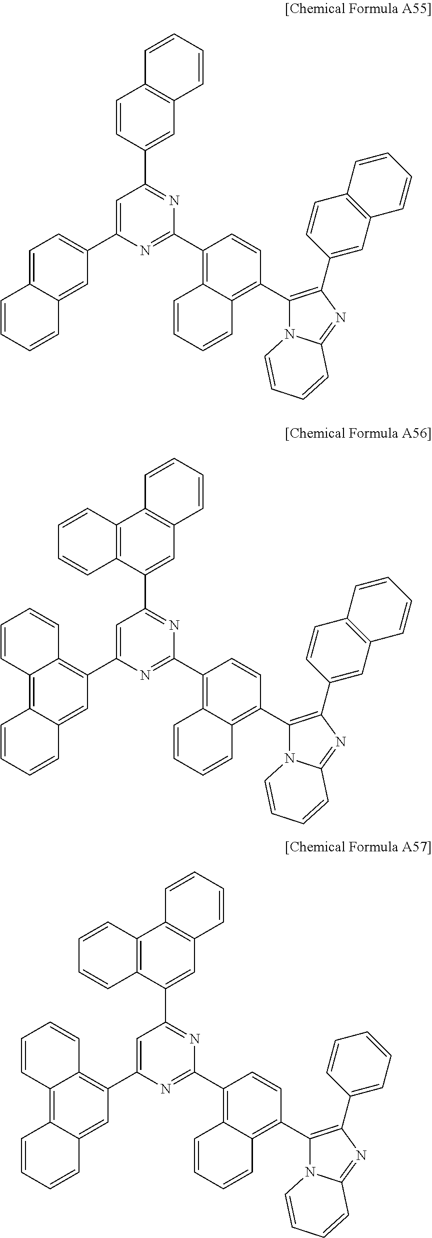 [SMILES: c1ccc2cc(-c3cc(-c4ccc5ccccc5c4)nc(-c4ccc(-c5c(-c6ccc7ccccc7c6)nc6ccccn56)c5ccccc45)n3)ccc2c1 ; c1ccc2cc(-c3nc4ccccn4c3-c3ccc(-c4nc(-c5cc6ccccc6c6ccccc56)cc(-c5cc6ccccc6c6ccccc56)n4)c4ccccc34)ccc2c1 ; c1ccc(-c2nc3ccccn3c2-c2ccc(-c3nc(-c4cc5ccccc5c5ccccc45)cc(-c4cc5ccccc5c5ccccc45)n3)c3ccccc23)cc1]

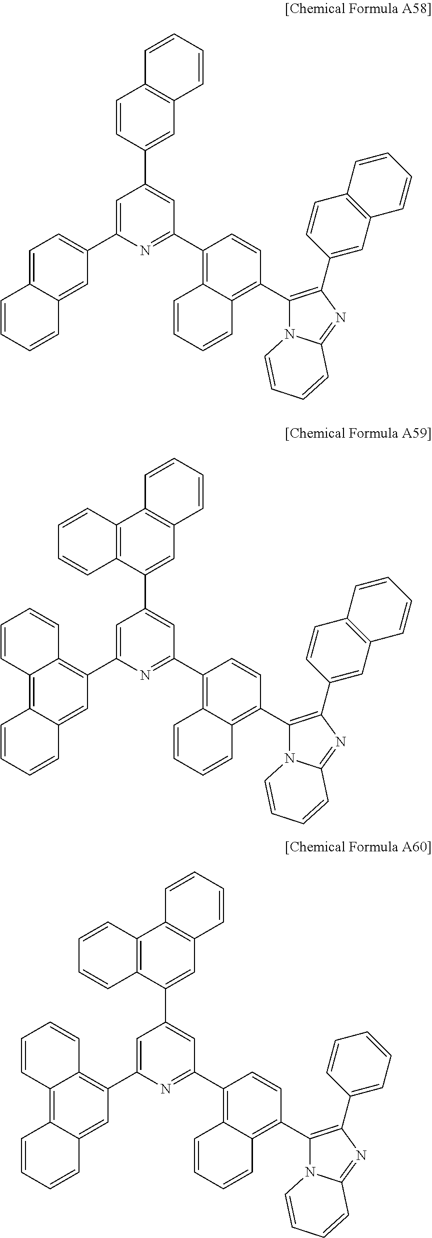 [SMILES: c1ccc2cc(-c3cc(-c4ccc5ccccc5c4)nc(-c4ccc(-c5c(-c6ccc7ccccc7c6)nc6ccccn56)c5ccccc45)c3)ccc2c1 ; c1ccc2cc(-c3nc4ccccn4c3-c3ccc(-c4cc(-c5cc6ccccc6c6ccccc56)cc(-c5cc6ccccc6c6ccccc56)n4)c4ccccc34)ccc2c1 ; c1ccc(-c2nc3ccccn3c2-c2ccc(-c3cc(-c4cc5ccccc5c5ccccc45)cc(-c4cc5ccccc5c5ccccc45)n3)c3ccccc23)cc1]

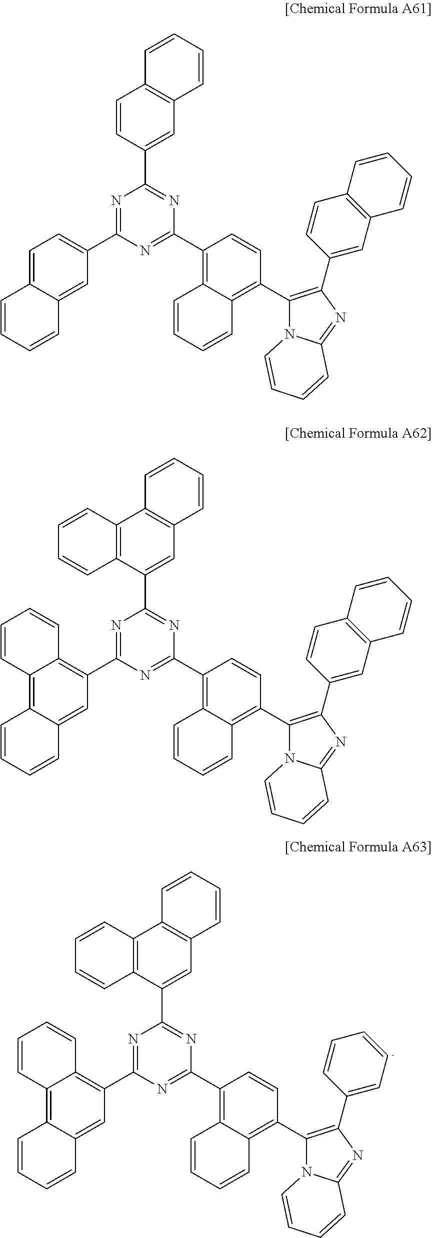 [SMILES: c1ccc2cc(-c3nc(-c4ccc5ccccc5c4)nc(-c4ccc(-c5c(-c6ccc7ccccc7c6)nc6ccccn56)c5ccccc45)n3)ccc2c1 ; c1ccc2cc(-c3nc4ccccn4c3-c3ccc(-c4nc(-c5cc6ccccc6c6ccccc56)nc(-c5cc6ccccc6c6ccccc56)n4)c4ccccc34)ccc2c1 ; c1ccc(-c2nc3ccccn3c2-c2ccc(-c3nc(-c4cc5ccccc5c5ccccc45)nc(-c4cc5ccccc5c5ccccc45)n3)c3ccccc23)cc1]

The compound may be represented by one of the following Chemical Formulae B1 to B72:

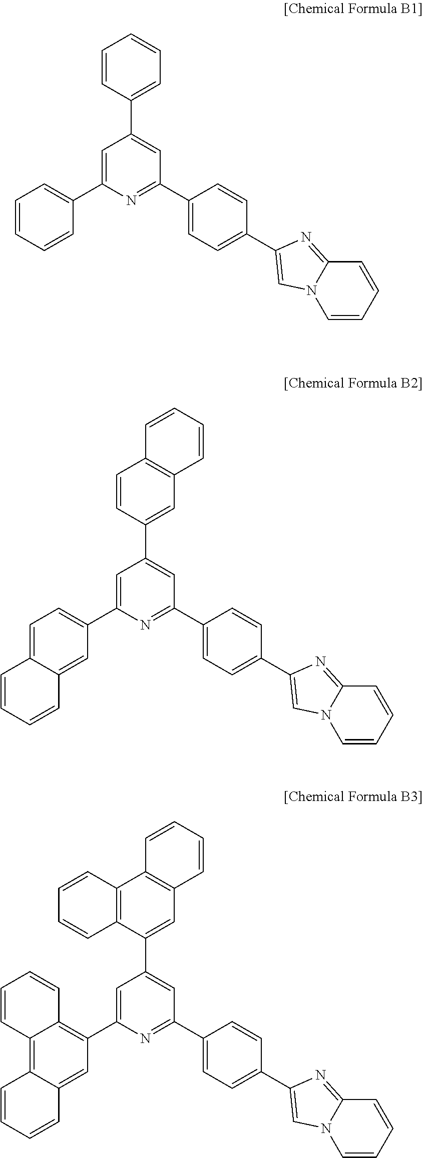 [SMILES: c1ccc(-c2cc(-c3ccccc3)nc(-c3ccc(-c4cn5ccccc5n4)cc3)c2)cc1 ; c1ccc2cc(-c3cc(-c4ccc(-c5cn6ccccc6n5)cc4)nc(-c4ccc5ccccc5c4)c3)ccc2c1 ; c1ccc2c(c1)cc(-c1cc(-c3ccc(-c4cn5ccccc5n4)cc3)nc(-c3cc4ccccc4c4ccccc34)c1)c1ccccc12]

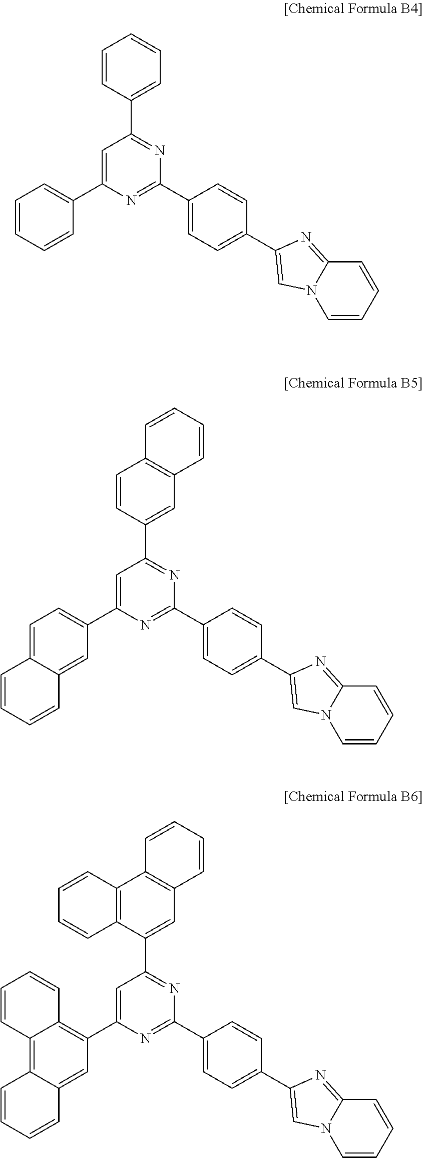 [SMILES: c1ccc(-c2cc(-c3ccccc3)nc(-c3ccc(-c4cn5ccccc5n4)cc3)n2)cc1 ; c1ccc2cc(-c3cc(-c4ccc5ccccc5c4)nc(-c4ccc(-c5cn6ccccc6n5)cc4)n3)ccc2c1 ; c1ccc2c(c1)cc(-c1cc(-c3cc4ccccc4c4ccccc34)nc(-c3ccc(-c4cn5ccccc5n4)cc3)n1)c1ccccc12]

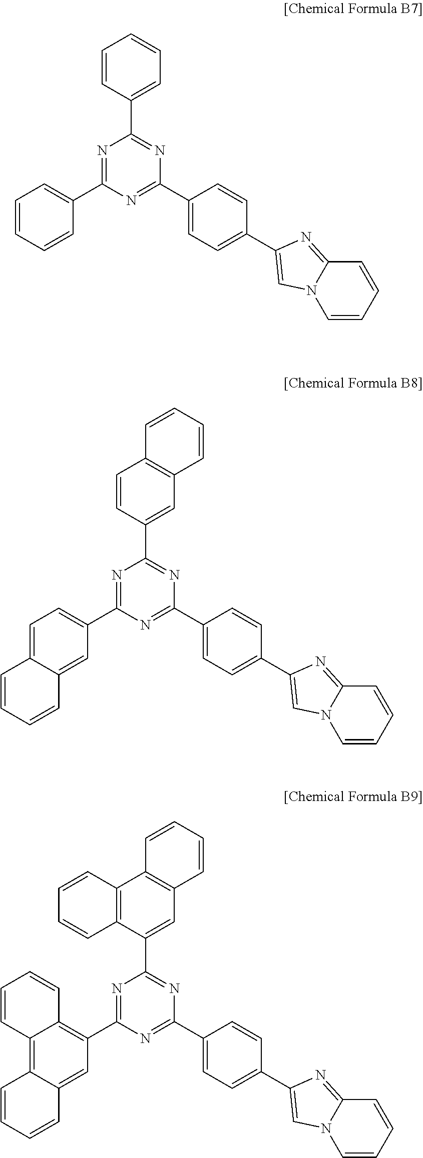 [SMILES: c1ccc(-c2nc(-c3ccccc3)nc(-c3ccc(-c4cn5ccccc5n4)cc3)n2)cc1 ; c1ccc2cc(-c3nc(-c4ccc(-c5cn6ccccc6n5)cc4)nc(-c4ccc5ccccc5c4)n3)ccc2c1 ; c1ccc2c(c1)cc(-c1nc(-c3ccc(-c4cn5ccccc5n4)cc3)nc(-c3cc4ccccc4c4ccccc34)n1)c1ccccc12]

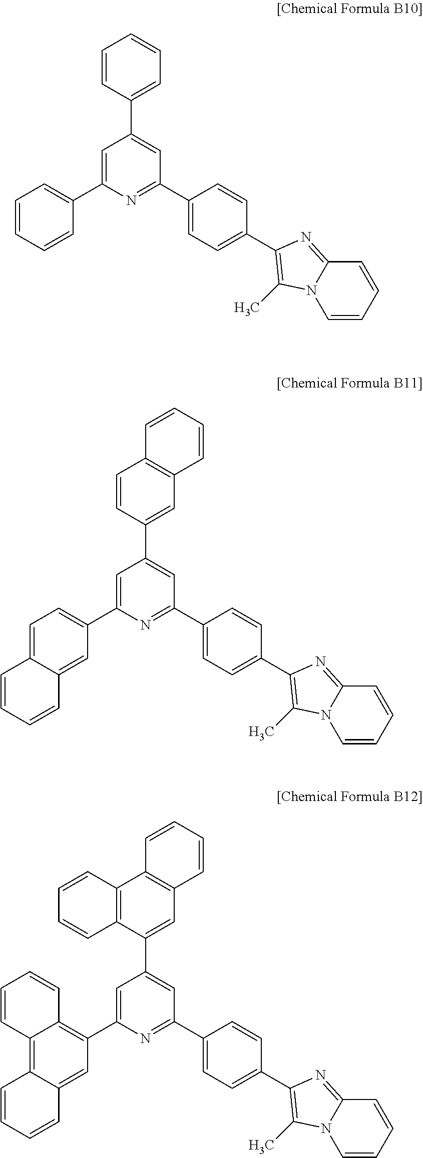 [SMILES: Cc1c(-c2ccc(-c3cc(-c4ccccc4)cc(-c4ccccc4)n3)cc2)nc2ccccn12 ; Cc1c(-c2ccc(-c3cc(-c4ccc5ccccc5c4)cc(-c4ccc5ccccc5c4)n3)cc2)nc2ccccn12 ; Cc1c(-c2ccc(-c3cc(-c4cc5ccccc5c5ccccc45)cc(-c4cc5ccccc5c5ccccc45)n3)cc2)nc2ccccn12]

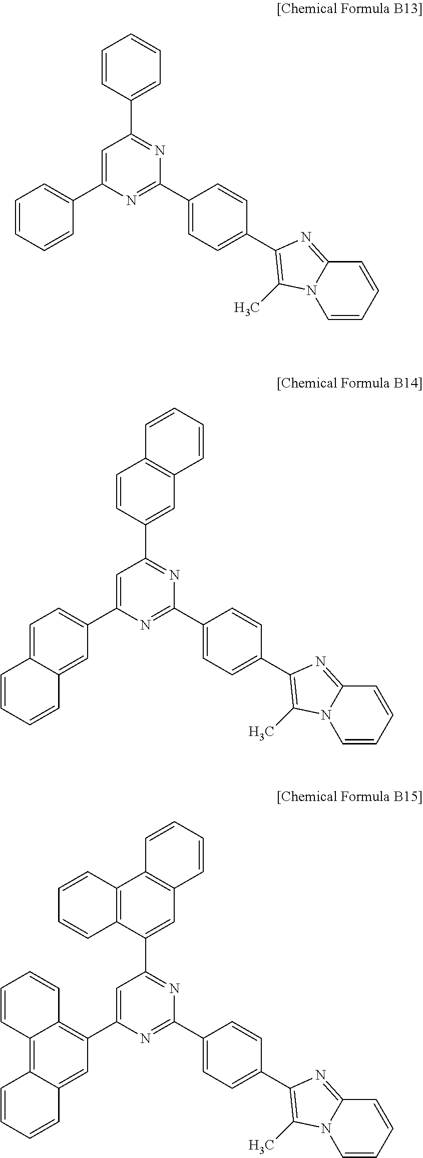 [SMILES: Cc1c(-c2ccc(-c3nc(-c4ccccc4)cc(-c4ccccc4)n3)cc2)nc2ccccn12 ; Cc1c(-c2ccc(-c3nc(-c4ccc5ccccc5c4)cc(-c4ccc5ccccc5c4)n3)cc2)nc2ccccn12 ; Cc1c(-c2ccc(-c3nc(-c4cc5ccccc5c5ccccc45)cc(-c4cc5ccccc5c5ccccc45)n3)cc2)nc2ccccn12]

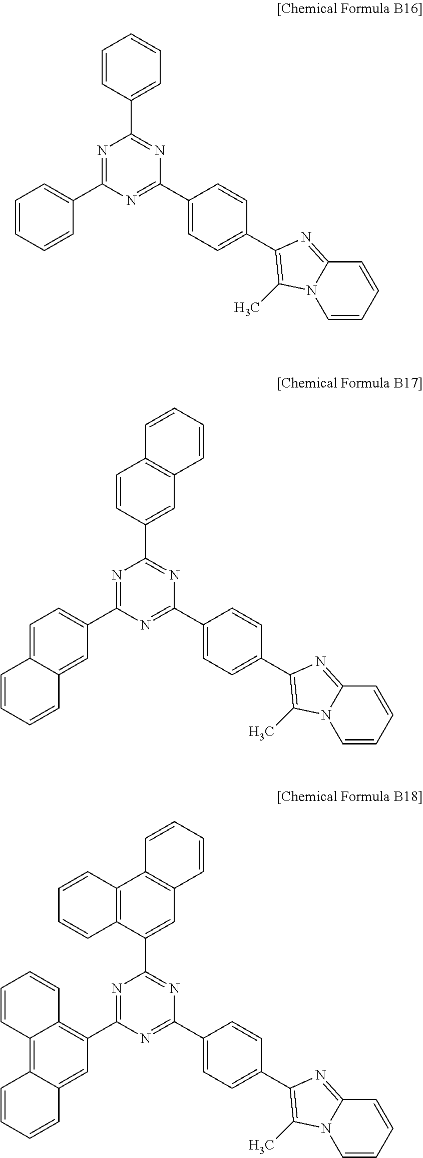 [SMILES: Cc1c(-c2ccc(-c3nc(-c4ccccc4)nc(-c4ccccc4)n3)cc2)nc2ccccn12 ; Cc1c(-c2ccc(-c3nc(-c4ccc5ccccc5c4)nc(-c4ccc5ccccc5c4)n3)cc2)nc2ccccn12 ; Cc1c(-c2ccc(-c3nc(-c4cc5ccccc5c5ccccc45)nc(-c4cc5ccccc5c5ccccc45)n3)cc2)nc2ccccn12]

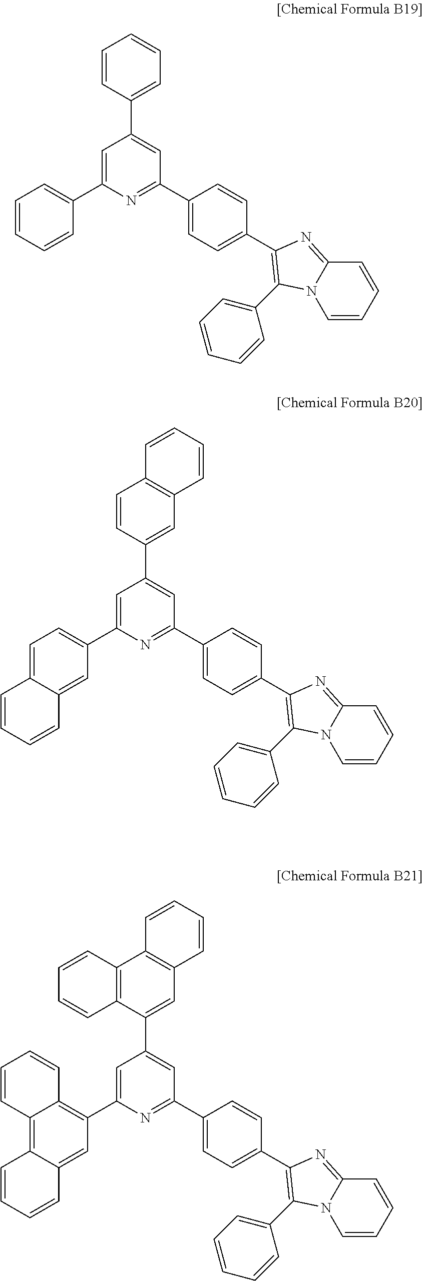 [SMILES: c1ccc(-c2cc(-c3ccccc3)nc(-c3ccc(-c4nc5ccccn5c4-c4ccccc4)cc3)c2)cc1 ; c1ccc(-c2c(-c3ccc(-c4cc(-c5ccc6ccccc6c5)cc(-c5ccc6ccccc6c5)n4)cc3)nc3ccccn23)cc1 ; c1ccc(-c2c(-c3ccc(-c4cc(-c5cc6ccccc6c6ccccc56)cc(-c5cc6ccccc6c6ccccc56)n4)cc3)nc3ccccn23)cc1]

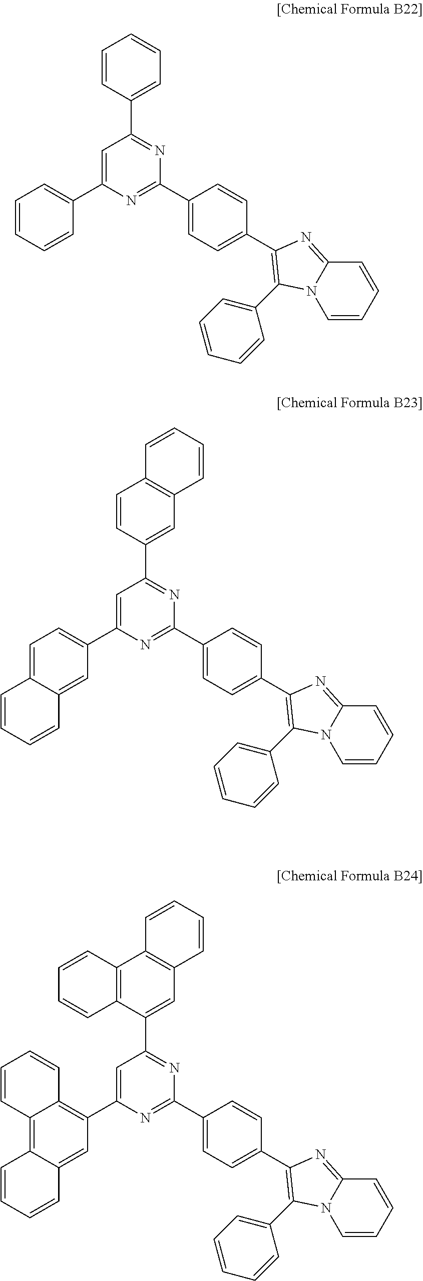 [SMILES: c1ccc(-c2cc(-c3ccccc3)nc(-c3ccc(-c4nc5ccccn5c4-c4ccccc4)cc3)n2)cc1 ; c1ccc(-c2c(-c3ccc(-c4nc(-c5ccc6ccccc6c5)cc(-c5ccc6ccccc6c5)n4)cc3)nc3ccccn23)cc1 ; c1ccc(-c2c(-c3ccc(-c4nc(-c5cc6ccccc6c6ccccc56)cc(-c5cc6ccccc6c6ccccc56)n4)cc3)nc3ccccn23)cc1]

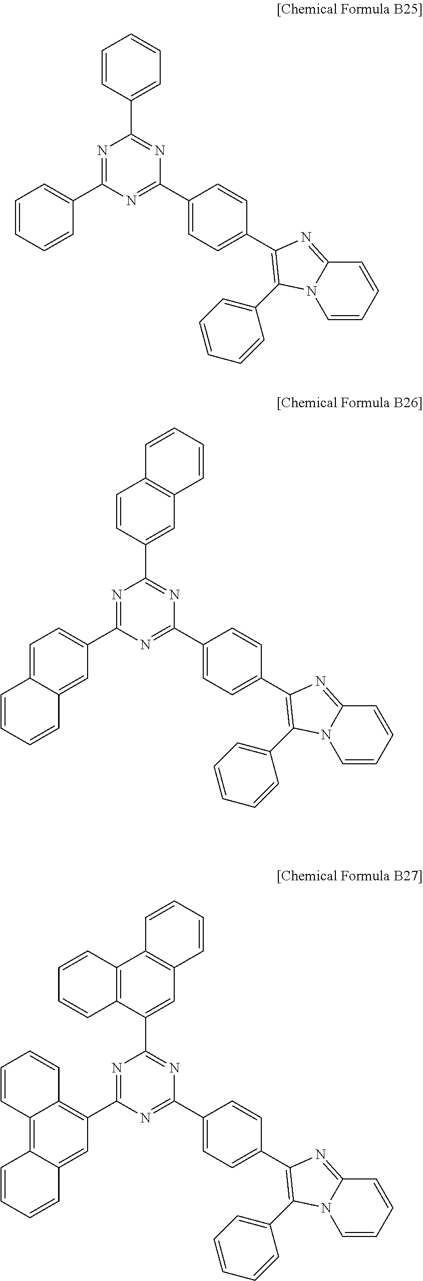 [SMILES: c1ccc(-c2nc(-c3ccccc3)nc(-c3ccc(-c4nc5ccccn5c4-c4ccccc4)cc3)n2)cc1 ; c1ccc(-c2c(-c3ccc(-c4nc(-c5ccc6ccccc6c5)nc(-c5ccc6ccccc6c5)n4)cc3)nc3ccccn23)cc1 ; c1ccc(-c2c(-c3ccc(-c4nc(-c5cc6ccccc6c6ccccc56)nc(-c5cc6ccccc6c6ccccc56)n4)cc3)nc3ccccn23)cc1]

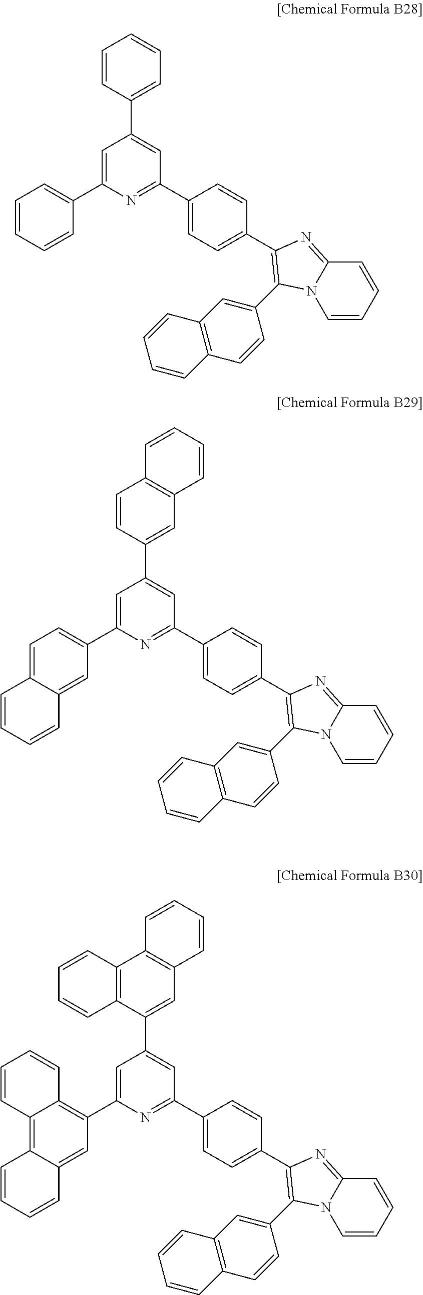 [SMILES: c1ccc(-c2cc(-c3ccccc3)nc(-c3ccc(-c4nc5ccccn5c4-c4ccc5ccccc5c4)cc3)c2)cc1 ; c1ccc2cc(-c3cc(-c4ccc(-c5nc6ccccn6c5-c5ccc6ccccc6c5)cc4)nc(-c4ccc5ccccc5c4)c3)ccc2c1 ; c1ccc2cc(-c3c(-c4ccc(-c5cc(-c6cc7ccccc7c7ccccc67)cc(-c6cc7ccccc7c7ccccc67)n5)cc4)nc4ccccn34)ccc2c1]

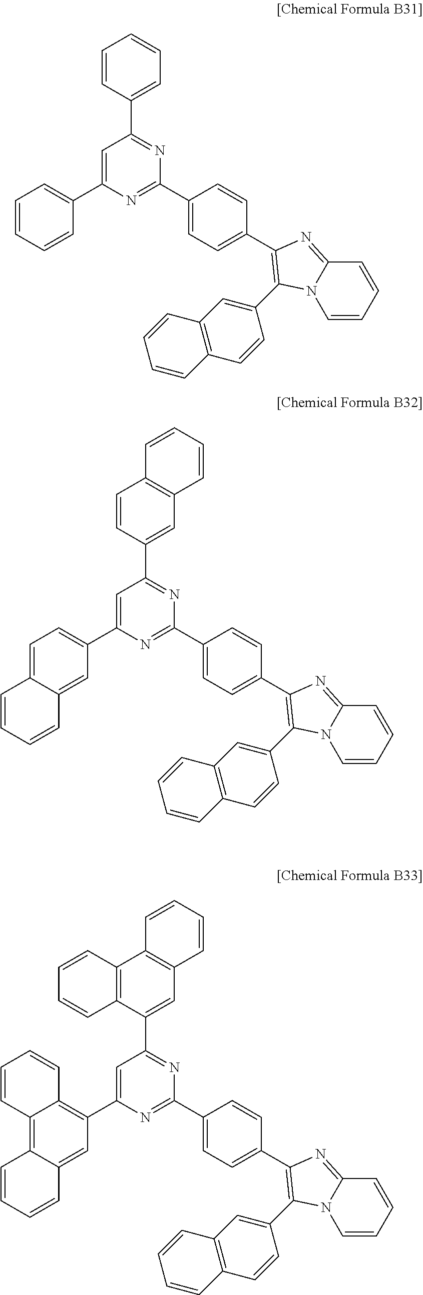 [SMILES: c1ccc(-c2cc(-c3ccccc3)nc(-c3ccc(-c4nc5ccccn5c4-c4ccc5ccccc5c4)cc3)n2)cc1 ; c1ccc2cc(-c3cc(-c4ccc5ccccc5c4)nc(-c4ccc(-c5nc6ccccn6c5-c5ccc6ccccc6c5)cc4)n3)ccc2c1 ; c1ccc2cc(-c3c(-c4ccc(-c5nc(-c6cc7ccccc7c7ccccc67)cc(-c6cc7ccccc7c7ccccc67)n5)cc4)nc4ccccn34)ccc2c1]

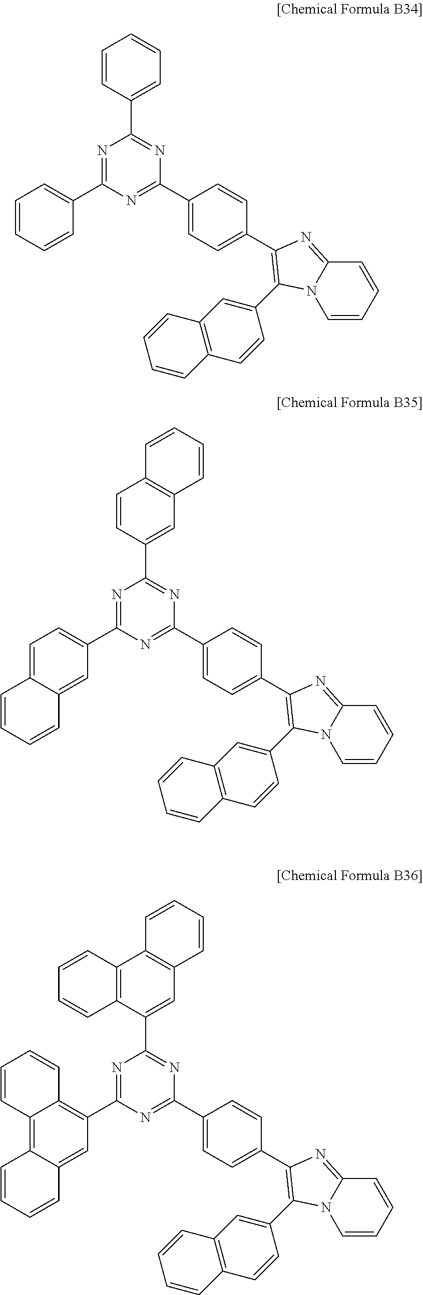 [SMILES: c1ccc(-c2nc(-c3ccccc3)nc(-c3ccc(-c4nc5ccccn5c4-c4ccc5ccccc5c4)cc3)n2)cc1 ; c1ccc2cc(-c3nc(-c4ccc(-c5nc6ccccn6c5-c5ccc6ccccc6c5)cc4)nc(-c4ccc5ccccc5c4)n3)ccc2c1 ; c1ccc2cc(-c3c(-c4ccc(-c5nc(-c6cc7ccccc7c7ccccc67)nc(-c6cc7ccccc7c7ccccc67)n5)cc4)nc4ccccn34)ccc2c1]

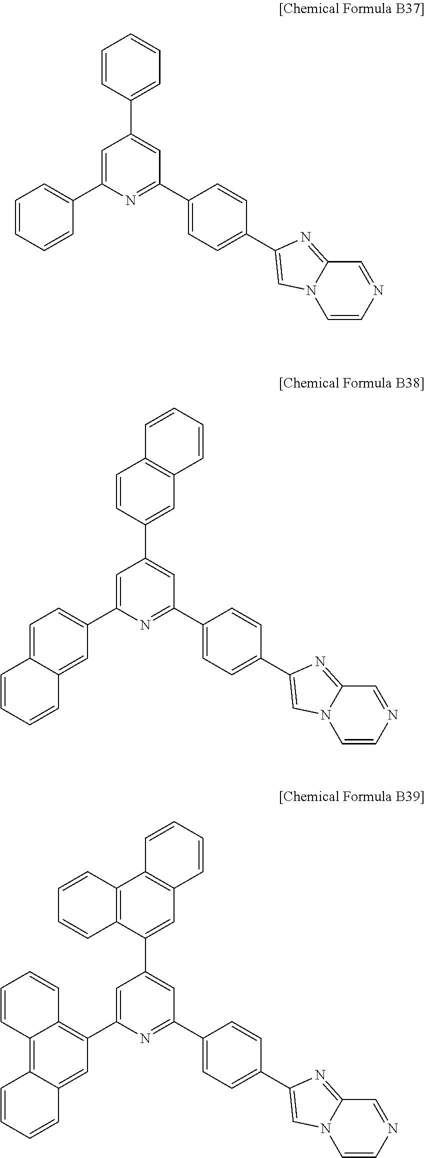 [SMILES: c1ccc(-c2cc(-c3ccccc3)nc(-c3ccc(-c4cn5ccncc5n4)cc3)c2)cc1 ; c1ccc2cc(-c3cc(-c4ccc(-c5cn6ccncc6n5)cc4)nc(-c4ccc5ccccc5c4)c3)ccc2c1 ; c1ccc2c(c1)cc(-c1cc(-c3ccc(-c4cn5ccncc5n4)cc3)nc(-c3cc4ccccc4c4ccccc34)c1)c1ccccc12]

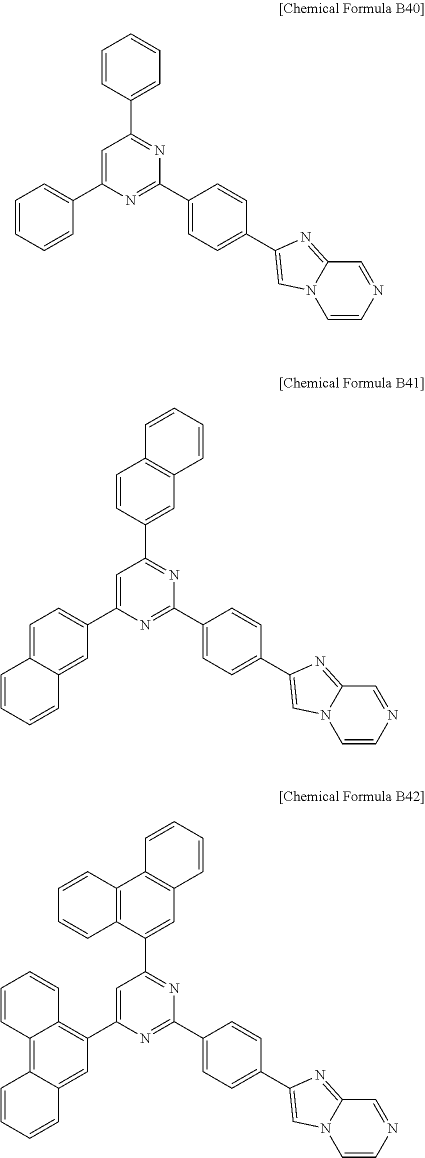 [SMILES: c1ccc(-c2cc(-c3ccccc3)nc(-c3ccc(-c4cn5ccncc5n4)cc3)n2)cc1 ; c1ccc2cc(-c3cc(-c4ccc5ccccc5c4)nc(-c4ccc(-c5cn6ccncc6n5)cc4)n3)ccc2c1 ; c1ccc2c(c1)cc(-c1cc(-c3cc4ccccc4c4ccccc34)nc(-c3ccc(-c4cn5ccncc5n4)cc3)n1)c1ccccc12]

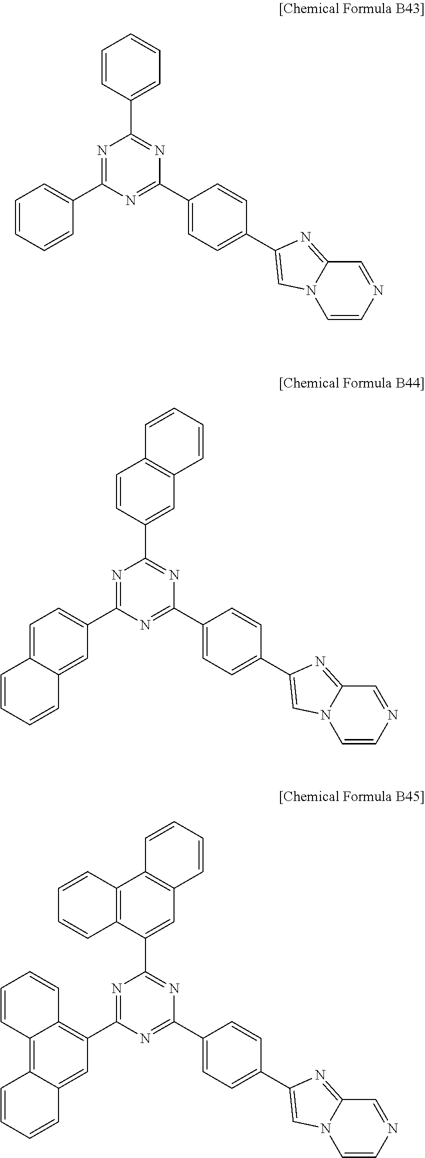 [SMILES: c1ccc(-c2nc(-c3ccccc3)nc(-c3ccc(-c4cn5ccncc5n4)cc3)n2)cc1 ; c1ccc2cc(-c3nc(-c4ccc(-c5cn6ccncc6n5)cc4)nc(-c4ccc5ccccc5c4)n3)ccc2c1 ; c1ccc2c(c1)cc(-c1nc(-c3ccc(-c4cn5ccncc5n4)cc3)nc(-c3cc4ccccc4c4ccccc34)n1)c1ccccc12]

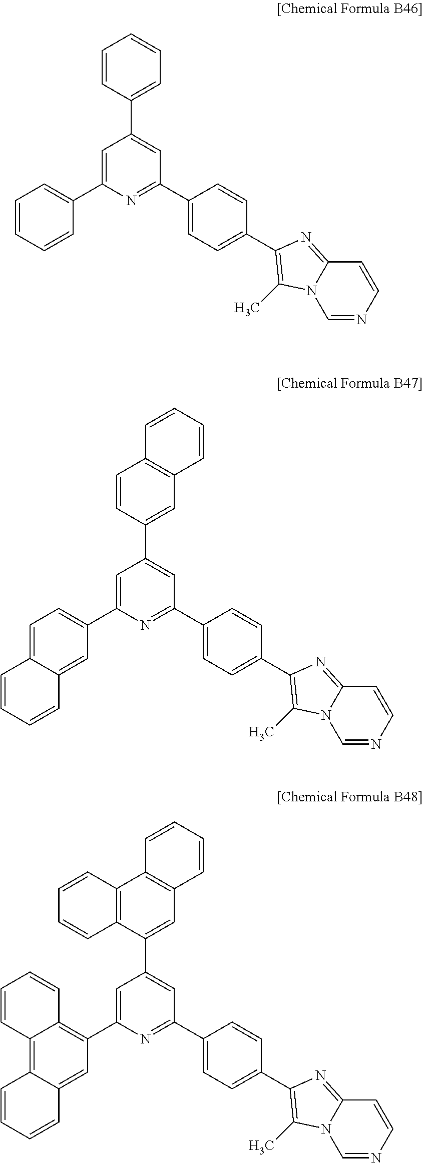 [SMILES: Cc1c(-c2ccc(-c3cc(-c4ccccc4)cc(-c4ccccc4)n3)cc2)nc2ccncn12 ; Cc1c(-c2ccc(-c3cc(-c4ccc5ccccc5c4)cc(-c4ccc5ccccc5c4)n3)cc2)nc2ccncn12 ; Cc1c(-c2ccc(-c3cc(-c4cc5ccccc5c5ccccc45)cc(-c4cc5ccccc5c5ccccc45)n3)cc2)nc2ccncn12]

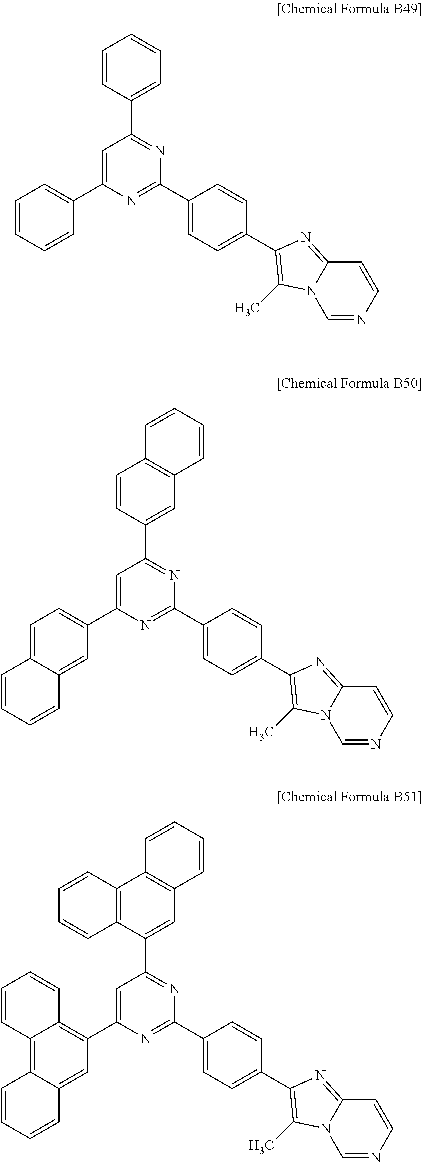 [SMILES: Cc1c(-c2ccc(-c3nc(-c4ccccc4)cc(-c4ccccc4)n3)cc2)nc2ccncn12 ; Cc1c(-c2ccc(-c3nc(-c4ccc5ccccc5c4)cc(-c4ccc5ccccc5c4)n3)cc2)nc2ccncn12 ; Cc1c(-c2ccc(-c3nc(-c4cc5ccccc5c5ccccc45)cc(-c4cc5ccccc5c5ccccc45)n3)cc2)nc2ccncn12]

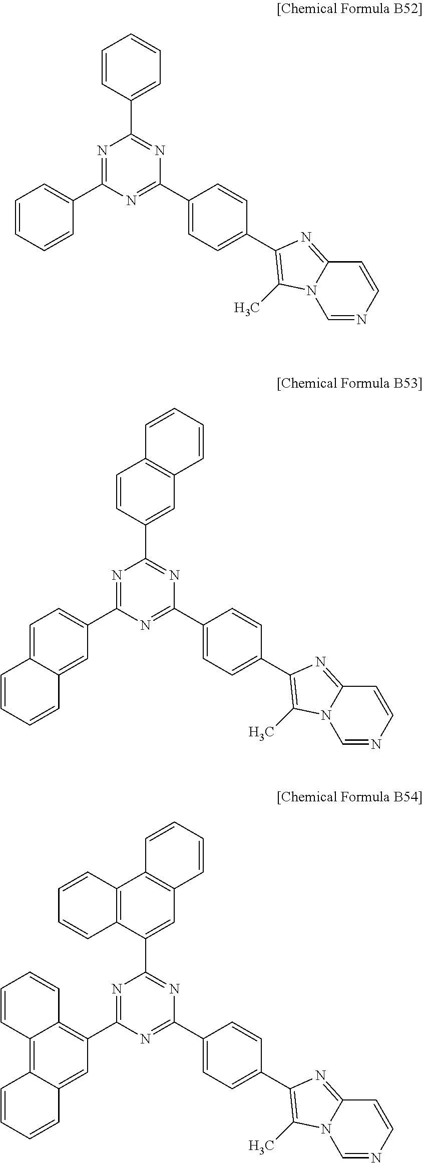 [SMILES: Cc1c(-c2ccc(-c3nc(-c4ccccc4)nc(-c4ccccc4)n3)cc2)nc2ccncn12 ; Cc1c(-c2ccc(-c3nc(-c4ccc5ccccc5c4)nc(-c4ccc5ccccc5c4)n3)cc2)nc2ccncn12 ; Cc1c(-c2ccc(-c3nc(-c4cc5ccccc5c5ccccc45)nc(-c4cc5ccccc5c5ccccc45)n3)cc2)nc2ccncn12]

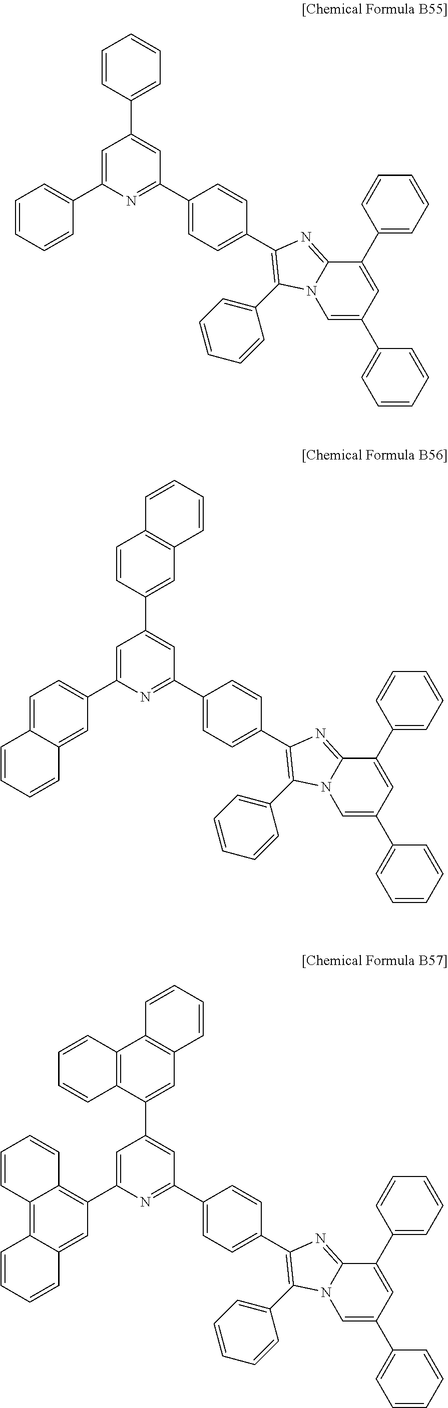 [SMILES: c1ccc(-c2cc(-c3ccccc3)nc(-c3ccc(-c4nc5c(-c6ccccc6)cc(-c6ccccc6)cn5c4-c4ccccc4)cc3)c2)cc1 ; c1ccc(-c2cc(-c3ccccc3)c3nc(-c4ccc(-c5cc(-c6ccc7ccccc7c6)cc(-c6ccc7ccccc7c6)n5)cc4)c(-c4ccccc4)n3c2)cc1 ; c1ccc(-c2cc(-c3ccccc3)c3nc(-c4ccc(-c5cc(-c6cc7ccccc7c7ccccc67)cc(-c6cc7ccccc7c7ccccc67)n5)cc4)c(-c4ccccc4)n3c2)cc1]

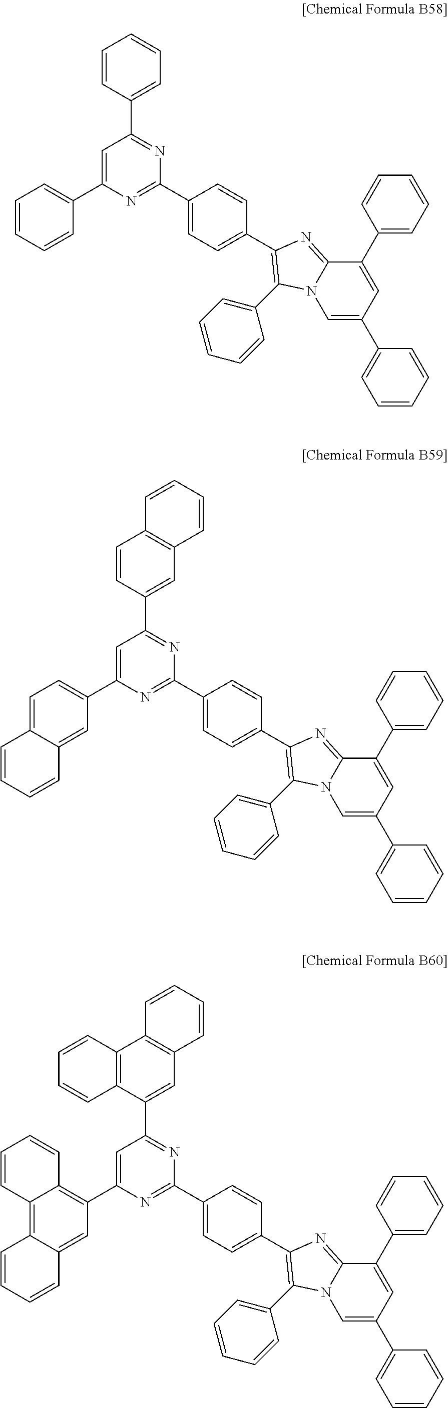 [SMILES: c1ccc(-c2cc(-c3ccccc3)c3nc(-c4ccc(-c5nc(-c6ccccc6)cc(-c6ccccc6)n5)cc4)c(-c4ccccc4)n3c2)cc1 ; c1ccc(-c2cc(-c3ccccc3)c3nc(-c4ccc(-c5nc(-c6ccc7ccccc7c6)cc(-c6ccc7ccccc7c6)n5)cc4)c(-c4ccccc4)n3c2)cc1 ; c1ccc(-c2cc(-c3ccccc3)c3nc(-c4ccc(-c5nc(-c6cc7ccccc7c7ccccc67)cc(-c6cc7ccccc7c7ccccc67)n5)cc4)c(-c4ccccc4)n3c2)cc1]

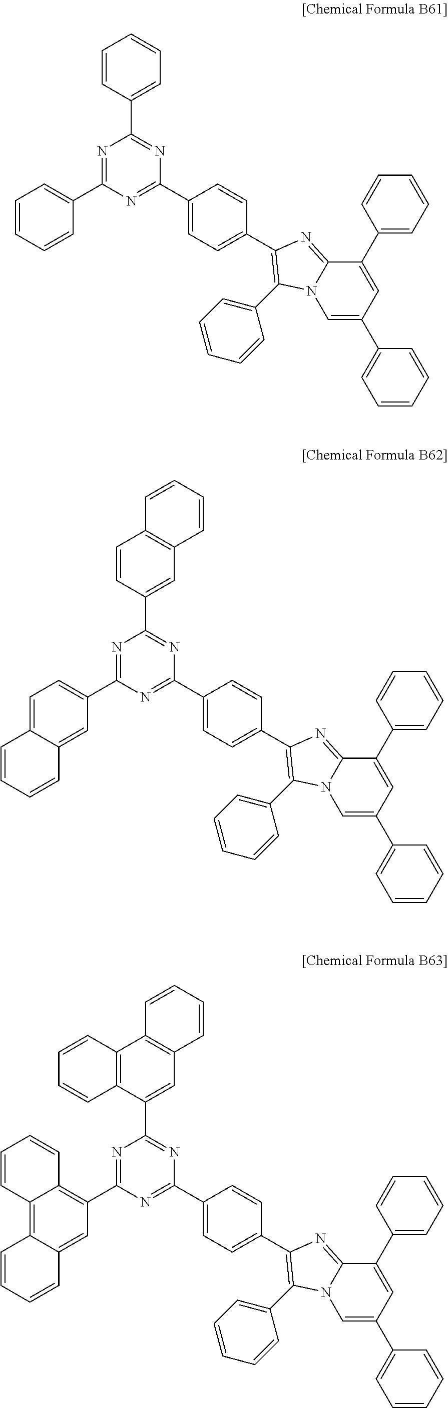 [SMILES: c1ccc(-c2cc(-c3ccccc3)c3nc(-c4ccc(-c5nc(-c6ccccc6)nc(-c6ccccc6)n5)cc4)c(-c4ccccc4)n3c2)cc1 ; c1ccc(-c2cc(-c3ccccc3)c3nc(-c4ccc(-c5nc(-c6ccc7ccccc7c6)nc(-c6ccc7ccccc7c6)n5)cc4)c(-c4ccccc4)n3c2)cc1 ; c1ccc(-c2cc(-c3ccccc3)c3nc(-c4ccc(-c5nc(-c6cc7ccccc7c7ccccc67)nc(-c6cc7ccccc7c7ccccc67)n5)cc4)c(-c4ccccc4)n3c2)cc1]

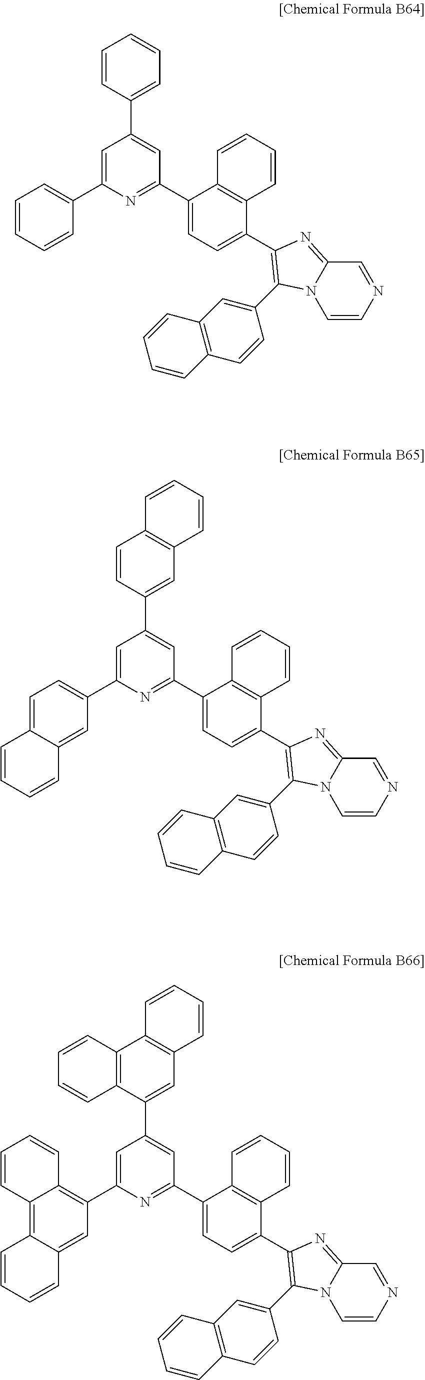 [SMILES: c1ccc(-c2cc(-c3ccccc3)nc(-c3ccc(-c4nc5cnccn5c4-c4ccc5ccccc5c4)c4ccccc34)c2)cc1 ; c1ccc2cc(-c3cc(-c4ccc5ccccc5c4)nc(-c4ccc(-c5nc6cnccn6c5-c5ccc6ccccc6c5)c5ccccc45)c3)ccc2c1 ; c1ccc2cc(-c3c(-c4ccc(-c5cc(-c6cc7ccccc7c7ccccc67)cc(-c6cc7ccccc7c7ccccc67)n5)c5ccccc45)nc4cnccn34)ccc2c1]

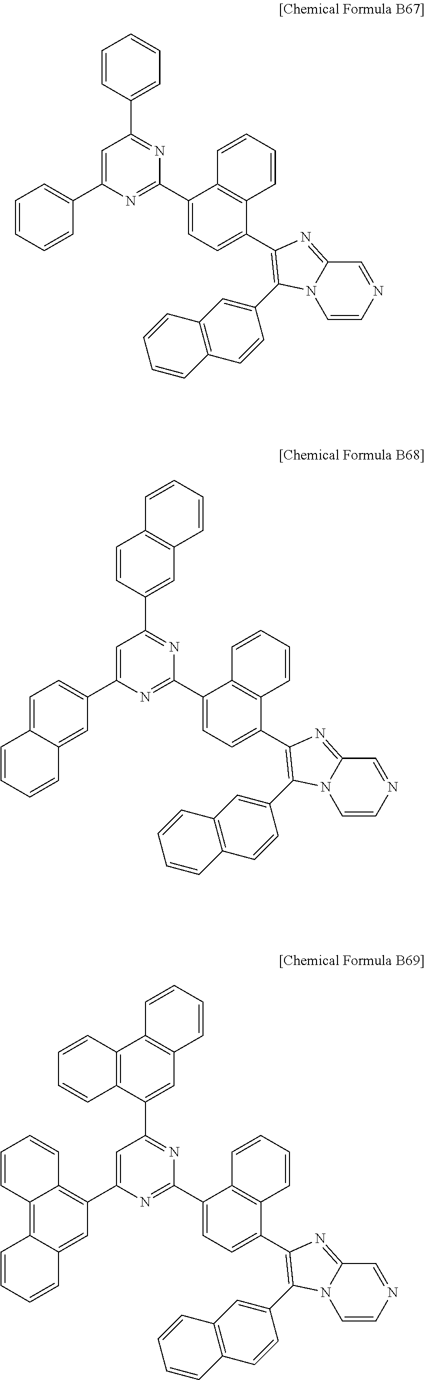 [SMILES: c1ccc(-c2cc(-c3ccccc3)nc(-c3ccc(-c4nc5cnccn5c4-c4ccc5ccccc5c4)c4ccccc34)n2)cc1 ; c1ccc2cc(-c3cc(-c4ccc5ccccc5c4)nc(-c4ccc(-c5nc6cnccn6c5-c5ccc6ccccc6c5)c5ccccc45)n3)ccc2c1 ; c1ccc2cc(-c3c(-c4ccc(-c5nc(-c6cc7ccccc7c7ccccc67)cc(-c6cc7ccccc7c7ccccc67)n5)c5ccccc45)nc4cnccn34)ccc2c1]

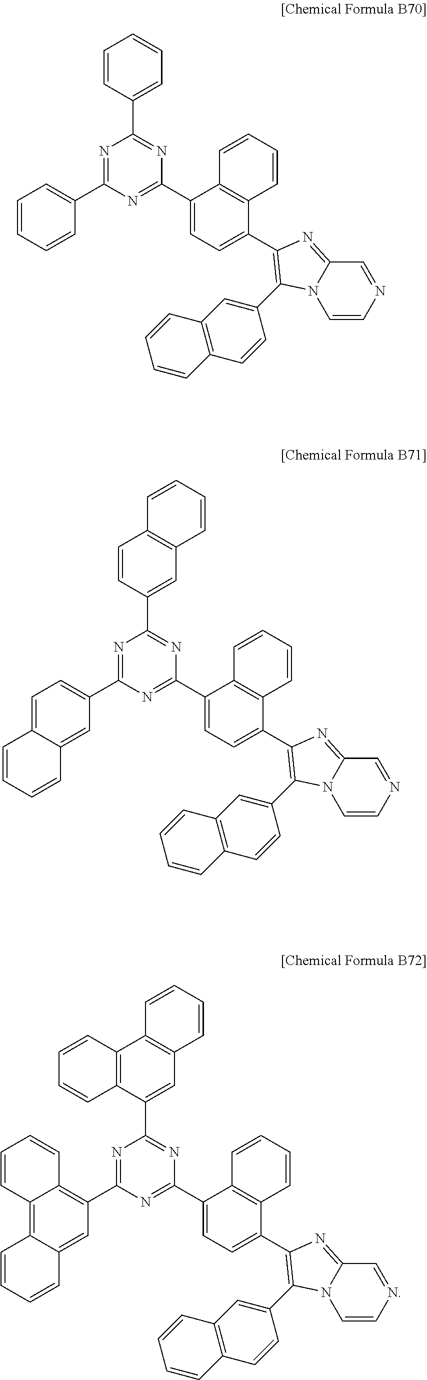 [SMILES: c1ccc(-c2nc(-c3ccccc3)nc(-c3ccc(-c4nc5cnccn5c4-c4ccc5ccccc5c4)c4ccccc34)n2)cc1 ; c1ccc2cc(-c3nc(-c4ccc5ccccc5c4)nc(-c4ccc(-c5nc6cnccn6c5-c5ccc6ccccc6c5)c5ccccc45)n3)ccc2c1 ; c1ccc2cc(-c3c(-c4ccc(-c5nc(-c6cc7ccccc7c7ccccc67)nc(-c6cc7ccccc7c7ccccc67)n5)c5ccccc45)nc4cnccn34)ccc2c1]

The organic optoelectronic device may be selected from the group of an organic light emitting diode, an organic solar cell, an organic transistor, an organic photo-conductor drum, and an organic memory device.

The embodiments may also be realized by providing an organic light emitting diode including an anode; a cathode; and at least one organic thin layer between the anode and cathode, wherein the at least one organic thin layer includes the compound for an organic optoelectronic device according to an embodiment.

The the at least one organic thin layer may include one selected from the group of an emission layer, a hole transport layer (HTL), a hole injection layer (HIL), an electron transport layer (ETL), an electron injection layer (EIL), a hole blocking layer, and a combination thereof.

The at least one organic thin layer may include an electron transport layer (ETL) or an electron injection layer (EIL), and the compound for an organic optoelectronic device may be included in the electron transport layer (ETL) or the electron injection layer (EIL).

The at least one organic thin layer may include an emission layer, and the compound for an organic optoelectronic device may be included in the emission layer.

The at least one organic thin layer may include an emission layer, and the compound for an organic optoelectronic device may be a phosphorescent or fluorescent host material in the emission layer.

The at least one organic thin layer may include an emission layer, and the compound for an organic optoelectronic device may be a fluorescent blue dopant material in the emission layer.

The embodiments may also be realized by providing a display device comprising the organic light emitting diode according to an embodiment.

### BRIEF DESCRIPTION OF THE DRAWINGS

Features will become apparent to those of skill in the art by describing in detail exemplary embodiments with reference to the attached drawings in which:

FIGS. 1 to 5 illustrate cross-sectional views showing organic light emitting diodes according to various embodiments.

FIG. 6 illustrates a graph showing changes in current density depending on a voltage of devices according to Examples 3 and 4 and Comparative Example 1.

FIG. 7 illustrates a graph showing changes in current density depending on a voltage of devices according to Examples 5 and 6 and Comparative Example 2.

FIG. 8 illustrates a graph showing changes in luminance depending on a voltage of devices according to Examples 3 and 4 and Comparative Example 1.

FIG. 9 illustrates a graph showing changes in luminance depending on a voltage of devices according to Examples 5 and 6 and Comparative Example 2.

FIG. 10 illustrates a graph showing changes in luminous efficiency depending on luminance of devices according to Examples 3 and 4 and Comparative Example 1.

FIG. 11 illustrates a graph showing changes in luminous efficiency depending on luminance of devices according to Examples 5 and 6 and Comparative Example 2.

FIG. 12 illustrates a graph showing changes in electric power efficiency depending on luminance of devices according to Examples 3 and 4 and Comparative Example 1.

FIG. 13 illustrates a graph showing changes in electric power efficiency depending on luminance of devices according to Examples 5 and 6 and Comparative Example 2.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. Like reference numerals refer to like elements throughout.

As used herein, when specific definition is not otherwise provided, the term “substituted” may refer to one substituted with a C1 to C30 alkyl group, a C1 to C10 alkylsilyl group, a C3 to C30 cycloalkyl group, a C6 to C30 aryl group, a C1 to C10 alkoxy group, a fluoro group, C1 to C10 trifluoroalkyl group such as a trifluoromethyl group, and the like, or a cyano group.

As used herein, when specific definition is not otherwise provided, the term “hetero” may refer to one including 1 to 3 hetero atoms selected from the group of N, O, S, and P, and remaining carbons in one functional group.

As used herein, when a definition is not otherwise provided, the term “combination thereof” may refer to at least two substituents bound to each other by a linker, or at least two substituents condensed to each other.

In the specification, when a definition is not otherwise provided, the term “alkyl group” may refer to an aliphatic hydrocarbon group. The alkyl group may be to a saturated group without any alkene group or alkyne group.

The alkyl group may be branched, linear, or cyclic regardless of being saturated or unsaturated.

The alkyl group may be a C1 to C20 alkyl group. The alkyl group may be a C1 to C10 medium-sized alkyl group. The alkyl group may be a C1 to C6 lower alkyl group.

For example, a C1 to C4 alkyl group may have 1 to 4 carbon atoms and may be selected from the group consisting of methyl, ethyl, propyl, iso-propyl, n-butyl, iso-butyl, sec-butyl, and t-butyl.

Typical examples of an alkyl group may be individually and independently selected from a methyl group, an ethyl group, a propyl group, an isopropyl group, a butyl group, an isobutyl group, a t-butyl group, a pentyl group, a hexyl group, a cyclopropyl group, a cyclobutyl group, a cyclopentyl group, a cyclohexyl group, and the like or a functional group substituted with one or more foregoing groups.

The “alkene group” may refer to a substituent of at least one carbon-carbon double bond of at least two carbons, and the “alkyne group” may refer to a substituent of at least one carbon-carbon triple bond of at least two carbons.

The “aromatic group” may refer to a substituent including all element of the cycle having p-orbitals which form conjugation. Examples may include an aryl group and a heteroaryl group.

The “aryl group” may refer to a monocyclic or fused ring polycyclic (i.e., rings sharing adjacent pairs of carbon atoms) substituent.

The “heteroaryl group” may refer to an aryl group including 1 to 3 hetero atoms selected from the group consisting of N, O, S, and P, and remaining carbons in one functional group.

“Spiro structure” may refer to a plurality of cyclic structures having a contact point of one carbon. The Spiro structure may include a compound having a spiro structure or a substituent having a spiro structure.

An embodiment provides a compound for an organic optoelectronic device represented by the following Chemical Formula 1.

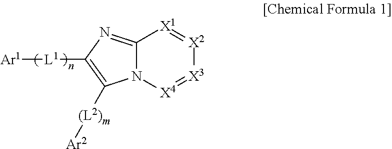

In Chemical Formula 1, X¹ to X⁴ may each independently be —N—, —CR¹—, —CR²—, —CR³— or —CR⁴—, R¹ to R⁴ may each independently be a hydrogen, deuterium, substituted or unsubstituted C1 to C20 alkyl group, substituted or unsubstituted C6 to C30 aryl group, substituted or unsubstituted C3 to C30 heteroaryl group, or a combination thereof, L¹ and L² may each independently be a single bond, substituted or unsubstituted C2 to C6 alkenyl group, substituted or unsubstituted C2 to C6 alkynyl group, substituted or unsubstituted C6 to C30 arylene group, substituted or unsubstituted C3 to C30 heteroarylene group, or a combination thereof, n and m may each independently be 1 or 2, Ar¹ and Ar² may each independently be hydrogen, deuterium, a substituted or unsubstituted C1 to C20 alkyl group, substituted or unsubstituted C6 to C30 aryl group, a substituted or unsubstituted C3 to C30 heteroaryl group, or a combination thereof.

In an implementation, at least one of Ar¹ or Ar² may be a substituted or unsubstituted C3 to C30 heteroaryl group having electronic properties. The electronic properties may refer to electron injection and/or transport properties.

The compound for an organic optoelectronic device represented by the above Chemical Formula 1 may have a structure including a substituent having electronic properties on a fused ring core including at least two nitrogen atoms.

Characteristics of the entire compound may be controlled by introducing an appropriate substituent (onto the core structure) having excellent electronic properties.

The compound for an organic optoelectronic device may include a core part and various substituents for substituting the core part. Thus, the compound may have various energy band gaps. The compound may be used in an electron injection layer (EIL) and an electron transport layer (ETL), or an emission layer.

The compound may have an appropriate energy level, depending on the substituents. Thus, the compound may fortify electron transport capability of an organic photoelectric device and may bring about excellent effects on efficiency and driving voltage and also, may have excellent electrochemical and thermal stability. Thus, life-span characteristic during the operation of the organic photoelectric device may be improved.

As noted above, the electronic properties may refer to a characteristic in which an electron formed in the cathode is easily injected into the emission layer and transported in the emission layer due to conductive properties according to LUMO level. For example, the electronic properties may refer to an electron injection or transport properties.

Hole properties may refer to characteristics in which a hole formed in the anode is easily injected into the emission layer and transported in the emission layer due to conductive characteristic according to HOMO level.

The structure of the compound may have an asymmetric bipolar characteristic by appropriately blending or selecting a substituent. For example, the structure of asymmetric bipolar characteristic may help improve electron transport properties, so it may be expected that the luminous efficiency and the performance of the device using the same may be improved.

Examples of the compound represented by the above Chemical Formula 1 may be represented by one of the following Chemical Formula 2 or 3.

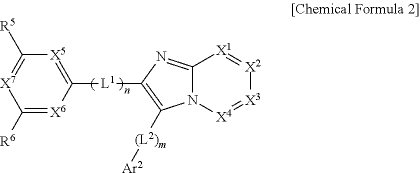

In Chemical Formula 2, X¹ to X⁴ may each independently be —N—, —CR¹—, —CR²—, —CR³— or —CR⁴—, R¹ to R⁶ may each independently be a hydrogen, deuterium, substituted or unsubstituted C1 to C20 alkyl group, substituted or unsubstituted C6 to C30 aryl group, substituted or unsubstituted C3 to C30 heteroaryl group, or a combination thereof, L¹ and L² may each independently be a single bond, substituted or unsubstituted C2 to C6 alkenyl group, substituted or unsubstituted C2 to C6 alkynyl group, substituted or unsubstituted C6 to C30 arylene group, substituted or unsubstituted C3 to C30 heteroarylene group, or a combination thereof, n and m may each independently be 1 or 2, Ar² may be hydrogen, deuterium, a substituted or unsubstituted C1 to C20 alkyl group, a substituted or unsubstituted C6 to C30 aryl group, a substituted or unsubstituted C3 to C30 heteroaryl group, or a combination thereof, X⁵ to X⁷ may each independently be —N— or —CR′—, in which R′ may be hydrogen or deuterium, and at least one of X⁵ to X⁷ may be —N—.

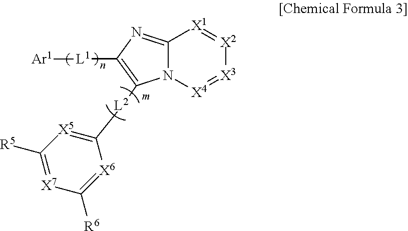

In Chemical Formula 3, X¹ to X⁴ may each independently be —N—, —CR¹—, —CR²—, —CR³— or —CR⁴—, R¹ to R⁶ may each independently be a hydrogen, deuterium, substituted or unsubstituted C1 to C20 alkyl group, substituted or unsubstituted C6 to C30 aryl group, substituted or unsubstituted C3 to C30 heteroaryl group, or a combination thereof, L¹ and L² may each independently be a single bond, substituted or unsubstituted C2 to C6 alkenyl group, substituted or unsubstituted C2 to C6 alkynyl group, substituted or unsubstituted C6 to C30 arylene group, substituted or unsubstituted C3 to C30 heteroarylene group, or a combination thereof, n and m may each independently be 1 or 2, Ar¹ may be hydrogen, deuterium, a substituted or unsubstituted C1 to C20 alkyl group, a substituted or unsubstituted C6 to C30 aryl group, a substituted or unsubstituted C3 to C30 heteroaryl group, or a combination thereof, X⁵ to X⁷ may each independently be —N— or —CR′—, wherein R′ is hydrogen or deuterium, and at least one of X⁵ to X⁷ may be —N—.

Compounds of the above Chemical Formulae 2 and 3 may have a structure where, in the above Chemical Formula 1, one of Ar¹ or Ar² is a heteroaryl group including at least one nitrogen atom.

The difference between structures of Chemical Formulae 2 and 3 may be the position of a substituent bound to the hetero fused ring core.

When having the bonding position as in Chemical Formula 2, thermal properties of the compound may be enforced by introducing the rigid molecular structure.

When having the bonding position as in Chemical Formula 3, amorphous characteristics of the compound may be enforced to thereby help suppress the crystallinity, so the device using the same may have a prolonged life span.

In an implementation, Ar² (or Ar¹) may be a substituted or unsubstituted naphthyl group, a substituted or unsubstituted anthracenyl group, a substituted or unsubstituted phenanthrenyl group, a substituted or unsubstituted triphenylenyl group, a substituted or unsubstituted pyrenyl group, a substituted or unsubstituted chrysenyl group, or a combination thereof. When having the substituent, the core may be more asymmetric to thereby help decrease the crystallinity of the compound. Thus, when the organic photoelectric device is fabricated using the compound having low crystallinity, the life-span of device may be improved.

In an implementation, the substituted or unsubstituted C3 to C30 heteroaryl group having the electronic properties may be or may include, e.g., a substituted or unsubstituted imidazolyl group, a substituted or unsubstituted triazolyl group, a substituted or unsubstituted tetrazolyl group, a substituted or unsubstituted carbazolyl group, a substituted or unsubstituted oxadiazolyl group, a substituted or unsubstituted oxatriazolyl group, a substituted or unsubstituted thiatriazolyl group, a substituted or unsubstituted benzimidazolyl group, a substituted or unsubstituted benzotriazolyl group, a substituted or unsubstituted pyridinyl group, a substituted or unsubstituted pyrimidinyl group, a substituted or unsubstituted triazinyl group, a substituted or unsubstituted pyrazinyl group, a substituted or unsubstituted pyridazinyl group, a substituted or unsubstituted purinyl group, a substituted or unsubstituted quinolinyl group, a substituted or unsubstituted isoquinolinyl group, a substituted or unsubstituted phthalazinyl group, a substituted or unsubstituted naphpyridinyl group, a substituted or unsubstituted quinoxalinyl group, a substituted or unsubstituted quinazolinyl group, a substituted or unsubstituted acridinyl group, a substituted or unsubstituted phenanthrolinyl group, a substituted or unsubstituted phenazinyl group, or a combination thereof.

In an implementation, L¹ and L² may each independently be, e.g., a substituted or unsubstituted ethenylene, a substituted or unsubstituted ethynylene, a substituted or unsubstituted phenylene, a substituted or unsubstituted biphenylene, a substituted or unsubstituted naphthalene, a substituted or unsubstituted pyridinylene, a substituted or unsubstituted pyrimidinylene, a substituted or unsubstituted triazinylene, substituted or unsubstituted quinolinylene, substituted or unsubstituted quinoxalinylene, and the like.

As may be seen above, the substituent may have a π bond. Thus, the substituent may help increase a triplet energy band gap by adjusting entire π-conjugation length of the compound, so it may be usefully applied for an emission layer of organic photoelectric device as a phosphorescent host. In an implementation, n and/or m may be 0, and the linking groups L¹ and/or L² may not be present in the compound.

In an implementation, the compound for an organic optoelectronic device may be represented by one of the following Chemical Formulae A1 to A63.

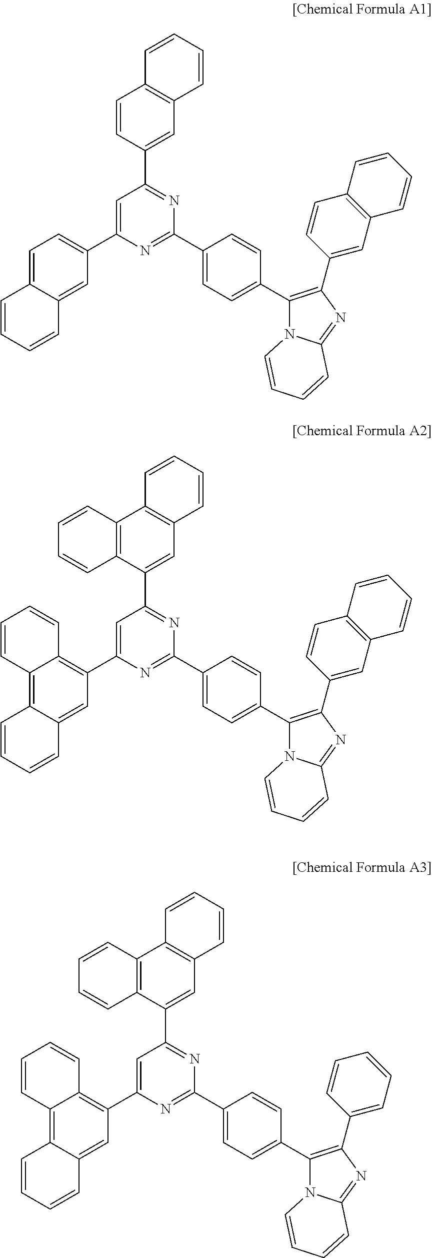 [SMILES: c1ccc2cc(-c3cc(-c4ccc5ccccc5c4)nc(-c4ccc(-c5c(-c6ccc7ccccc7c6)nc6ccccn56)cc4)n3)ccc2c1 ; c1ccc2cc(-c3nc4ccccn4c3-c3ccc(-c4nc(-c5cc6ccccc6c6ccccc56)cc(-c5cc6ccccc6c6ccccc56)n4)cc3)ccc2c1 ; c1ccc(-c2nc3ccccn3c2-c2ccc(-c3nc(-c4cc5ccccc5c5ccccc45)cc(-c4cc5ccccc5c5ccccc45)n3)cc2)cc1]

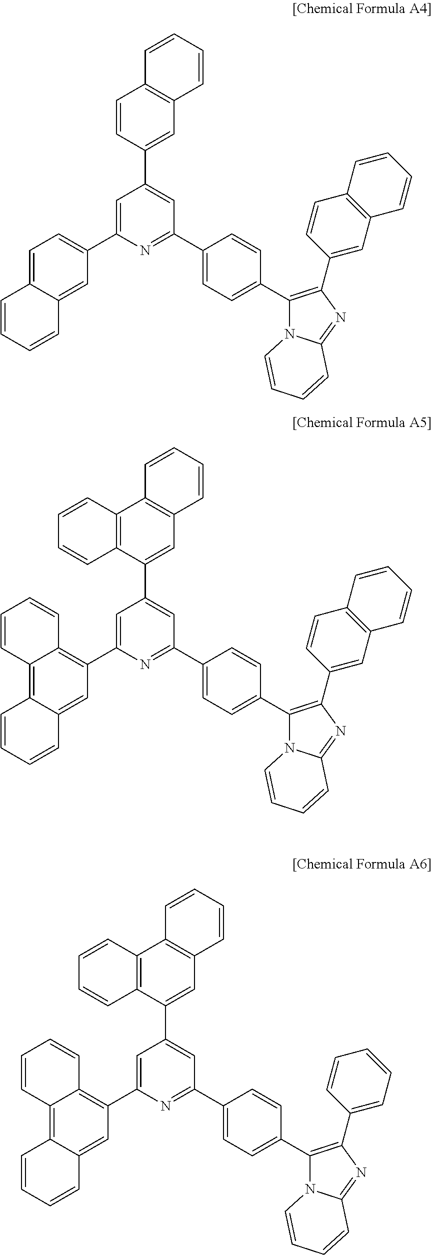 [SMILES: c1ccc2cc(-c3cc(-c4ccc(-c5c(-c6ccc7ccccc7c6)nc6ccccn56)cc4)nc(-c4ccc5ccccc5c4)c3)ccc2c1 ; c1ccc2cc(-c3nc4ccccn4c3-c3ccc(-c4cc(-c5cc6ccccc6c6ccccc56)cc(-c5cc6ccccc6c6ccccc56)n4)cc3)ccc2c1 ; c1ccc(-c2nc3ccccn3c2-c2ccc(-c3cc(-c4cc5ccccc5c5ccccc45)cc(-c4cc5ccccc5c5ccccc45)n3)cc2)cc1]

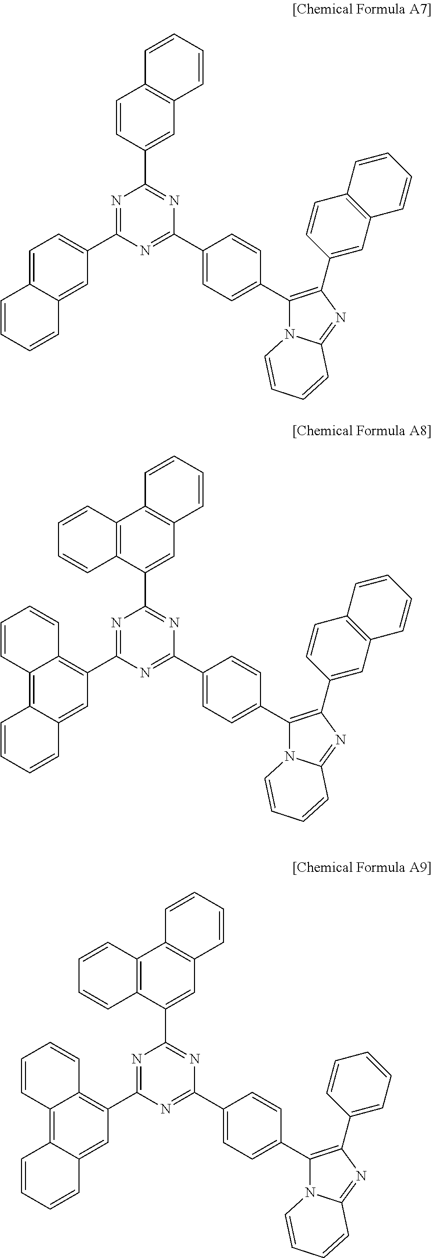 [SMILES: c1ccc2cc(-c3nc(-c4ccc(-c5c(-c6ccc7ccccc7c6)nc6ccccn56)cc4)nc(-c4ccc5ccccc5c4)n3)ccc2c1 ; c1ccc2cc(-c3nc4ccccn4c3-c3ccc(-c4nc(-c5cc6ccccc6c6ccccc56)nc(-c5cc6ccccc6c6ccccc56)n4)cc3)ccc2c1 ; c1ccc(-c2nc3ccccn3c2-c2ccc(-c3nc(-c4cc5ccccc5c5ccccc45)nc(-c4cc5ccccc5c5ccccc45)n3)cc2)cc1]

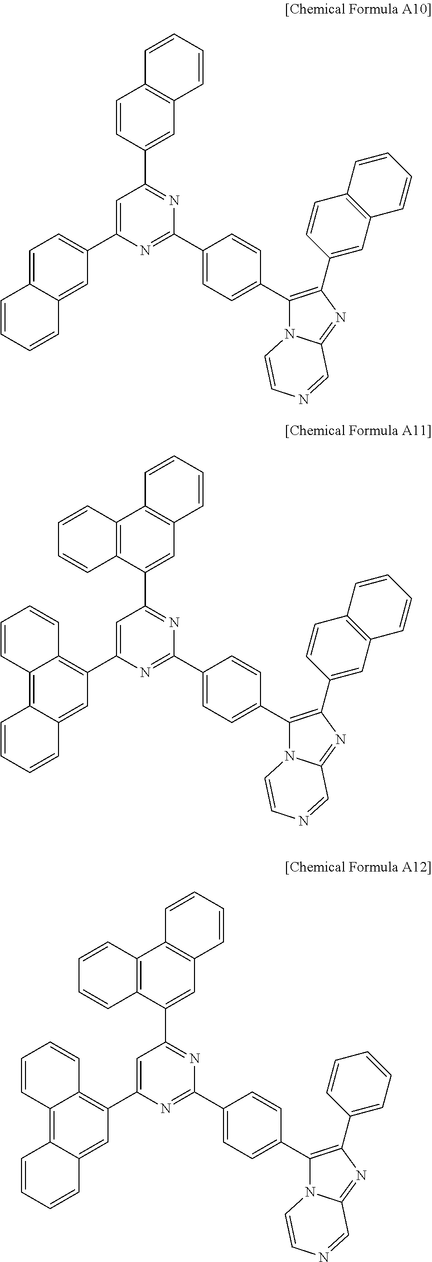 [SMILES: c1ccc2cc(-c3cc(-c4ccc5ccccc5c4)nc(-c4ccc(-c5c(-c6ccc7ccccc7c6)nc6cnccn56)cc4)n3)ccc2c1 ; c1ccc2cc(-c3nc4cnccn4c3-c3ccc(-c4nc(-c5cc6ccccc6c6ccccc56)cc(-c5cc6ccccc6c6ccccc56)n4)cc3)ccc2c1 ; c1ccc(-c2nc3cnccn3c2-c2ccc(-c3nc(-c4cc5ccccc5c5ccccc45)cc(-c4cc5ccccc5c5ccccc45)n3)cc2)cc1]

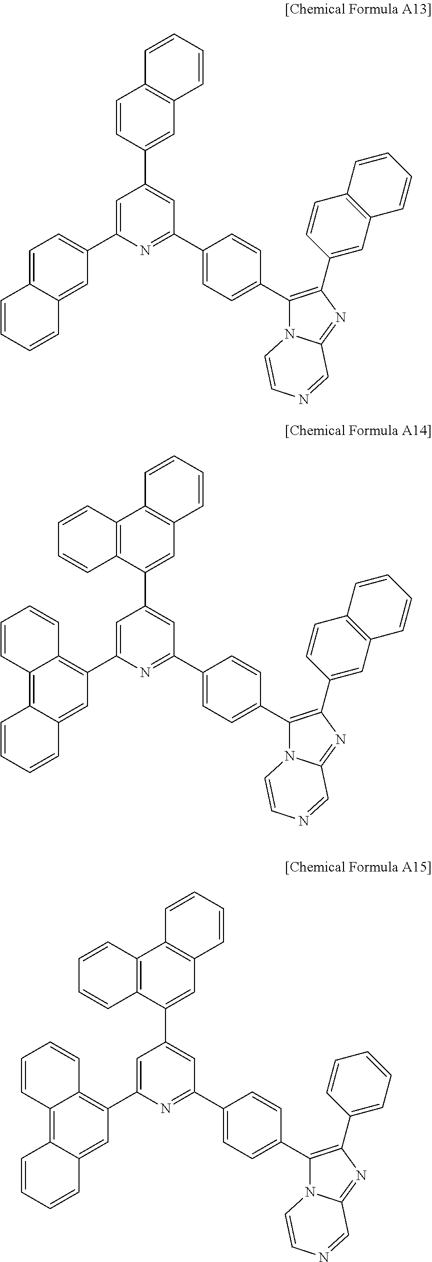 [SMILES: c1ccc2cc(-c3cc(-c4ccc(-c5c(-c6ccc7ccccc7c6)nc6cnccn56)cc4)nc(-c4ccc5ccccc5c4)c3)ccc2c1 ; c1ccc2cc(-c3nc4cnccn4c3-c3ccc(-c4cc(-c5cc6ccccc6c6ccccc56)cc(-c5cc6ccccc6c6ccccc56)n4)cc3)ccc2c1 ; c1ccc(-c2nc3cnccn3c2-c2ccc(-c3cc(-c4cc5ccccc5c5ccccc45)cc(-c4cc5ccccc5c5ccccc45)n3)cc2)cc1]

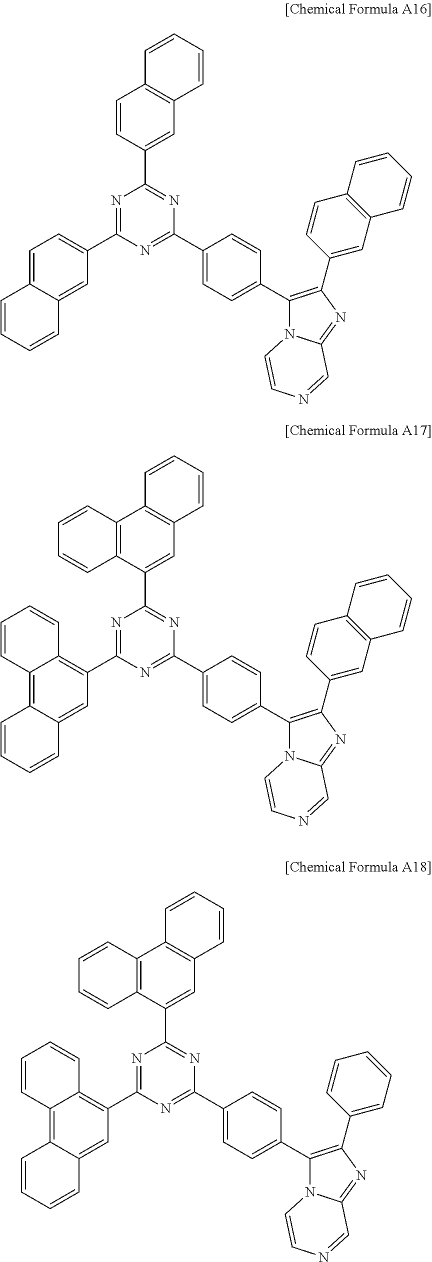 [SMILES: c1ccc2cc(-c3nc(-c4ccc(-c5c(-c6ccc7ccccc7c6)nc6cnccn56)cc4)nc(-c4ccc5ccccc5c4)n3)ccc2c1 ; c1ccc2cc(-c3nc4cnccn4c3-c3ccc(-c4nc(-c5cc6ccccc6c6ccccc56)nc(-c5cc6ccccc6c6ccccc56)n4)cc3)ccc2c1 ; c1ccc(-c2nc3cnccn3c2-c2ccc(-c3nc(-c4cc5ccccc5c5ccccc45)nc(-c4cc5ccccc5c5ccccc45)n3)cc2)cc1]

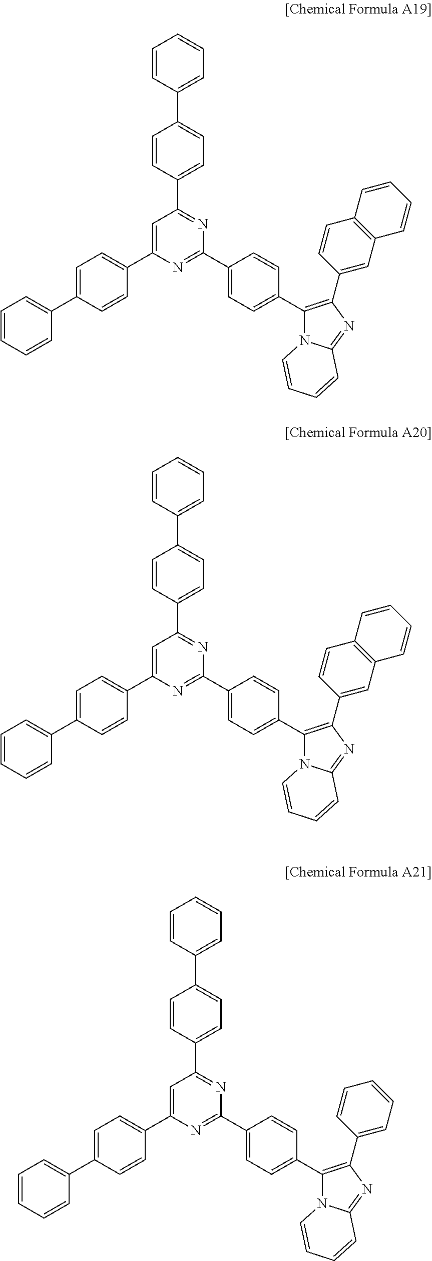 [SMILES: c1ccc(-c2ccc(-c3cc(-c4ccc(-c5ccccc5)cc4)nc(-c4ccc(-c5c(-c6ccc7ccccc7c6)nc6ccccn56)cc4)n3)cc2)cc1 ; c1ccc(-c2ccc(-c3cc(-c4ccc(-c5ccccc5)cc4)nc(-c4ccc(-c5c(-c6ccc7ccccc7c6)nc6ccccn56)cc4)n3)cc2)cc1 ; c1ccc(-c2ccc(-c3cc(-c4ccc(-c5ccccc5)cc4)nc(-c4ccc(-c5c(-c6ccccc6)nc6ccccn56)cc4)n3)cc2)cc1]

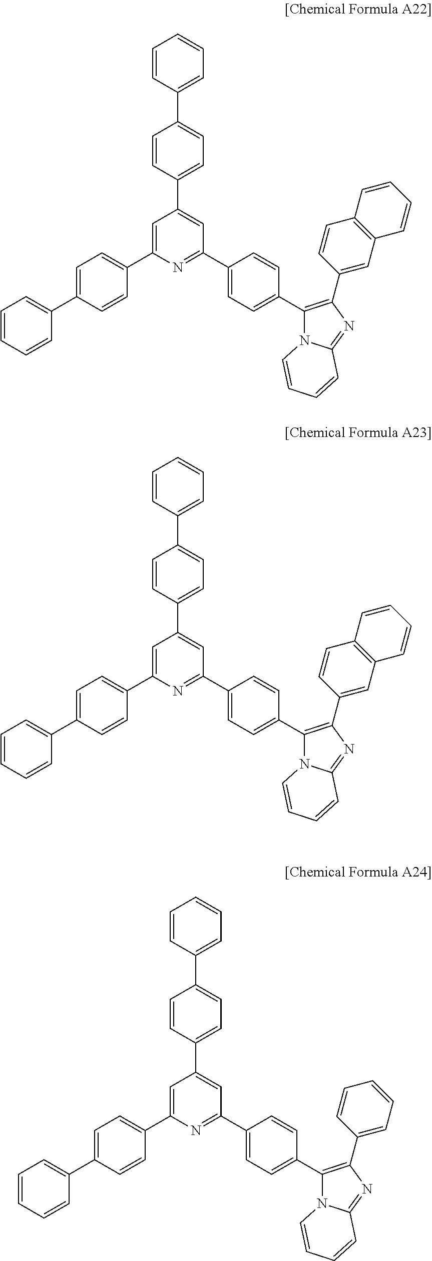 [SMILES: c1ccc(-c2ccc(-c3cc(-c4ccc(-c5ccccc5)cc4)nc(-c4ccc(-c5c(-c6ccc7ccccc7c6)nc6ccccn56)cc4)c3)cc2)cc1 ; c1ccc(-c2ccc(-c3cc(-c4ccc(-c5ccccc5)cc4)nc(-c4ccc(-c5c(-c6ccc7ccccc7c6)nc6ccccn56)cc4)c3)cc2)cc1 ; c1ccc(-c2ccc(-c3cc(-c4ccc(-c5ccccc5)cc4)nc(-c4ccc(-c5c(-c6ccccc6)nc6ccccn56)cc4)c3)cc2)cc1]

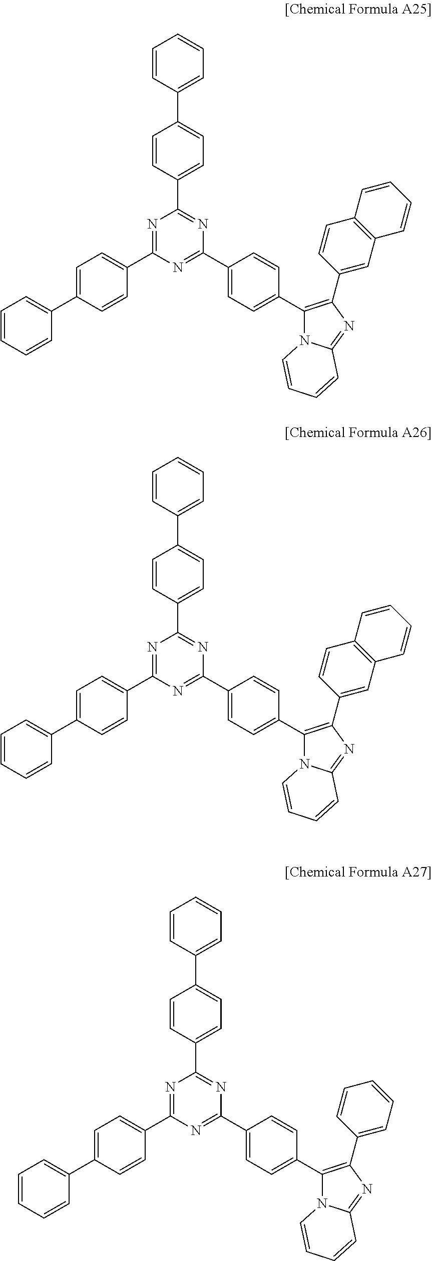 [SMILES: c1ccc(-c2ccc(-c3nc(-c4ccc(-c5ccccc5)cc4)nc(-c4ccc(-c5c(-c6ccc7ccccc7c6)nc6ccccn56)cc4)n3)cc2)cc1 ; c1ccc(-c2ccc(-c3nc(-c4ccc(-c5ccccc5)cc4)nc(-c4ccc(-c5c(-c6ccc7ccccc7c6)nc6ccccn56)cc4)n3)cc2)cc1 ; c1ccc(-c2ccc(-c3nc(-c4ccc(-c5ccccc5)cc4)nc(-c4ccc(-c5c(-c6ccccc6)nc6ccccn56)cc4)n3)cc2)cc1]

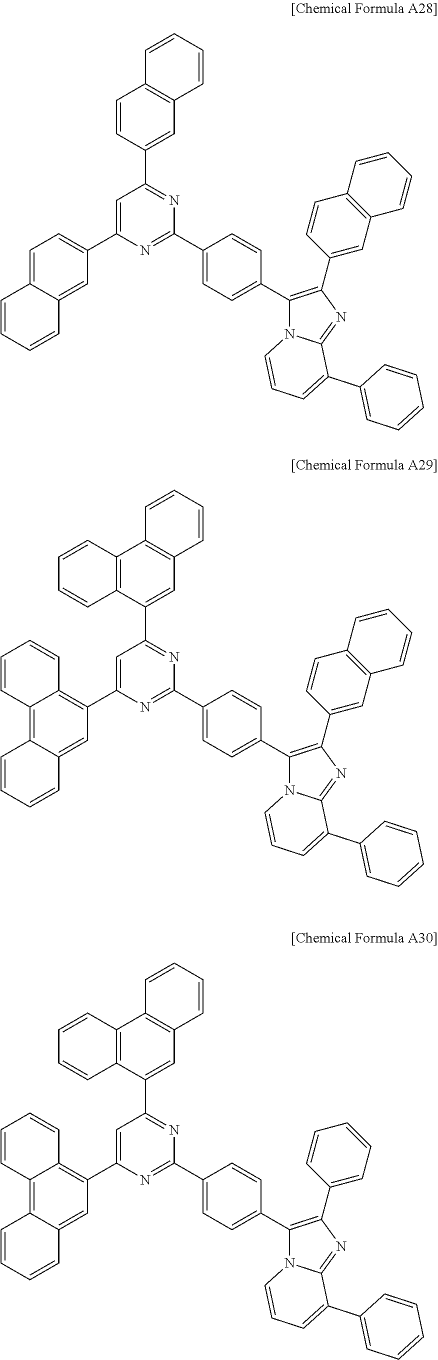 [SMILES: c1ccc(-c2cccn3c(-c4ccc(-c5nc(-c6ccc7ccccc7c6)cc(-c6ccc7ccccc7c6)n5)cc4)c(-c4ccc5ccccc5c4)nc23)cc1 ; c1ccc(-c2cccn3c(-c4ccc(-c5nc(-c6cc7ccccc7c7ccccc67)cc(-c6cc7ccccc7c7ccccc67)n5)cc4)c(-c4ccc5ccccc5c4)nc23)cc1 ; c1ccc(-c2nc3c(-c4ccccc4)cccn3c2-c2ccc(-c3nc(-c4cc5ccccc5c5ccccc45)cc(-c4cc5ccccc5c5ccccc45)n3)cc2)cc1]

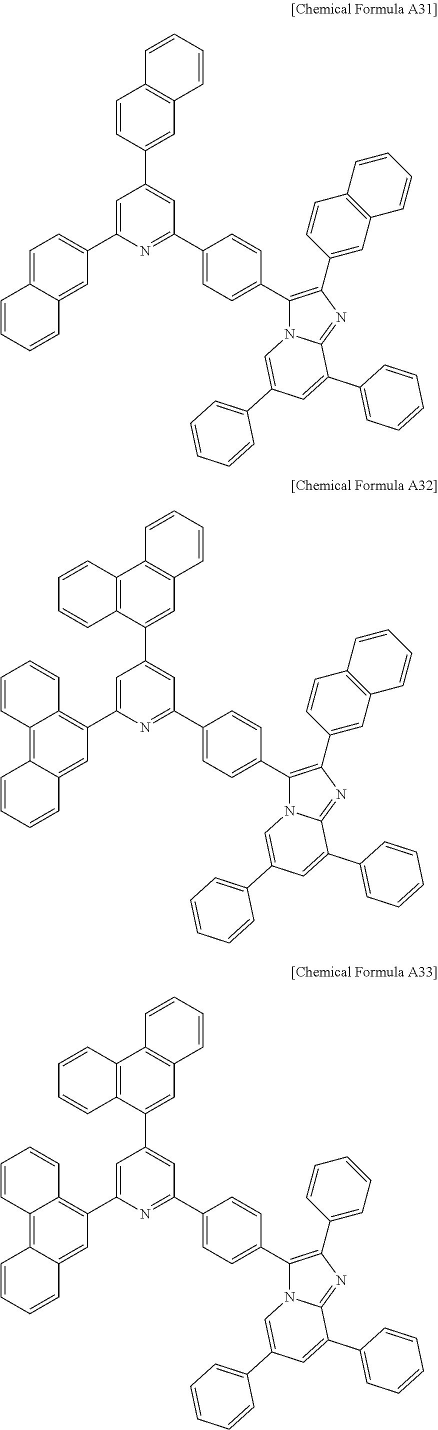 [SMILES: c1ccc(-c2cc(-c3ccccc3)c3nc(-c4ccc5ccccc5c4)c(-c4ccc(-c5cc(-c6ccc7ccccc7c6)cc(-c6ccc7ccccc7c6)n5)cc4)n3c2)cc1 ; c1ccc(-c2cc(-c3ccccc3)c3nc(-c4ccc5ccccc5c4)c(-c4ccc(-c5cc(-c6cc7ccccc7c7ccccc67)cc(-c6cc7ccccc7c7ccccc67)n5)cc4)n3c2)cc1 ; c1ccc(-c2cc(-c3ccccc3)c3nc(-c4ccccc4)c(-c4ccc(-c5cc(-c6cc7ccccc7c7ccccc67)cc(-c6cc7ccccc7c7ccccc67)n5)cc4)n3c2)cc1]

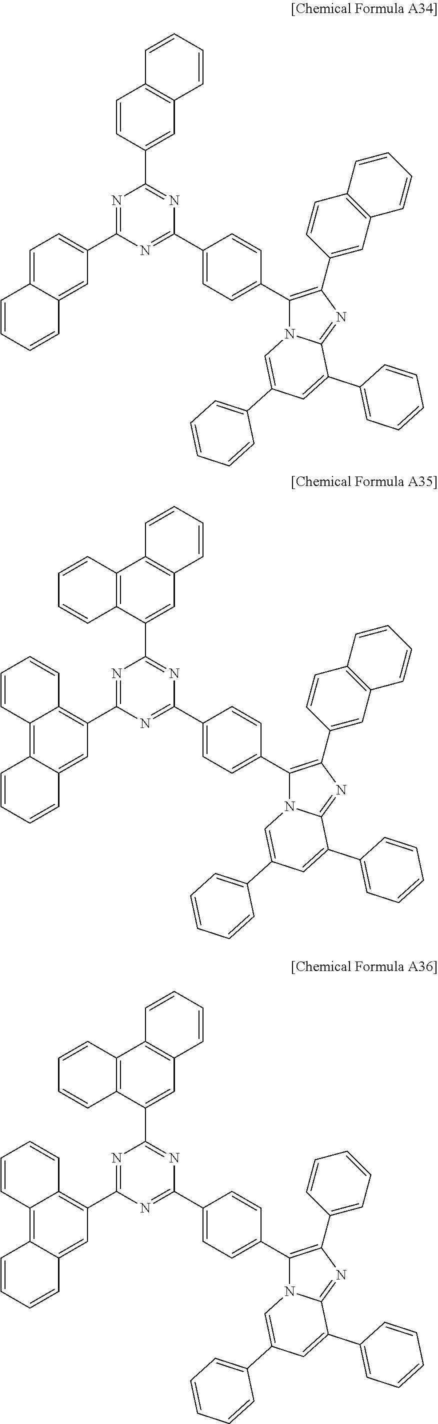 [SMILES: c1ccc(-c2cc(-c3ccccc3)c3nc(-c4ccc5ccccc5c4)c(-c4ccc(-c5nc(-c6ccc7ccccc7c6)nc(-c6ccc7ccccc7c6)n5)cc4)n3c2)cc1 ; c1ccc(-c2cc(-c3ccccc3)c3nc(-c4ccc5ccccc5c4)c(-c4ccc(-c5nc(-c6cc7ccccc7c7ccccc67)nc(-c6cc7ccccc7c7ccccc67)n5)cc4)n3c2)cc1 ; c1ccc(-c2cc(-c3ccccc3)c3nc(-c4ccccc4)c(-c4ccc(-c5nc(-c6cc7ccccc7c7ccccc67)nc(-c6cc7ccccc7c7ccccc67)n5)cc4)n3c2)cc1]

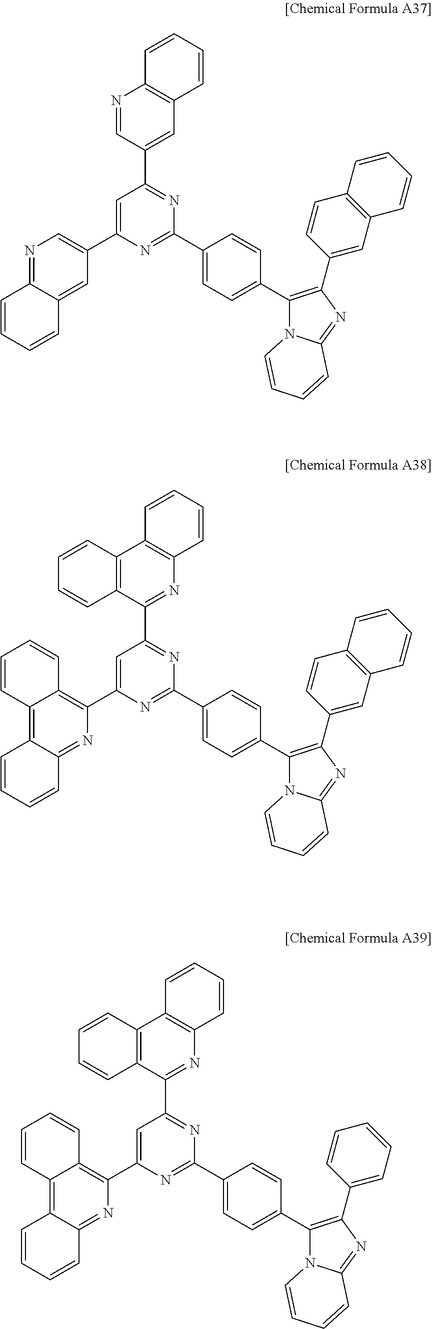 [SMILES: c1ccc2cc(-c3nc4ccccn4c3-c3ccc(-c4nc(-c5cnc6ccccc6c5)cc(-c5cnc6ccccc6c5)n4)cc3)ccc2c1 ; c1ccc2cc(-c3nc4ccccn4c3-c3ccc(-c4nc(-c5nc6ccccc6c6ccccc56)cc(-c5nc6ccccc6c6ccccc56)n4)cc3)ccc2c1 ; c1ccc(-c2nc3ccccn3c2-c2ccc(-c3nc(-c4nc5ccccc5c5ccccc45)cc(-c4nc5ccccc5c5ccccc45)n3)cc2)cc1]

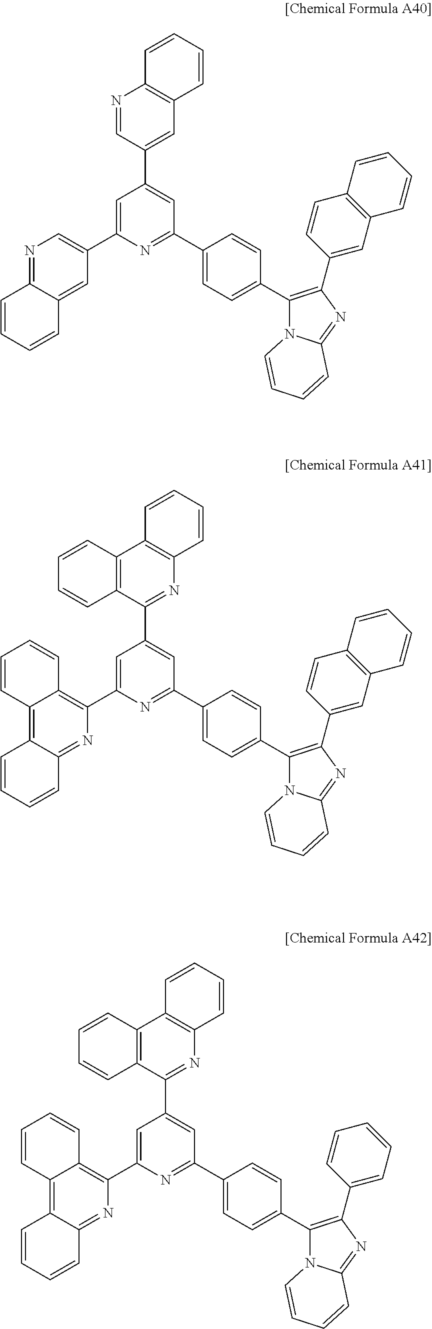 [SMILES: c1ccc2cc(-c3nc4ccccn4c3-c3ccc(-c4cc(-c5cnc6ccccc6c5)cc(-c5cnc6ccccc6c5)n4)cc3)ccc2c1 ; c1ccc2cc(-c3nc4ccccn4c3-c3ccc(-c4cc(-c5nc6ccccc6c6ccccc56)cc(-c5nc6ccccc6c6ccccc56)n4)cc3)ccc2c1 ; c1ccc(-c2nc3ccccn3c2-c2ccc(-c3cc(-c4nc5ccccc5c5ccccc45)cc(-c4nc5ccccc5c5ccccc45)n3)cc2)cc1]

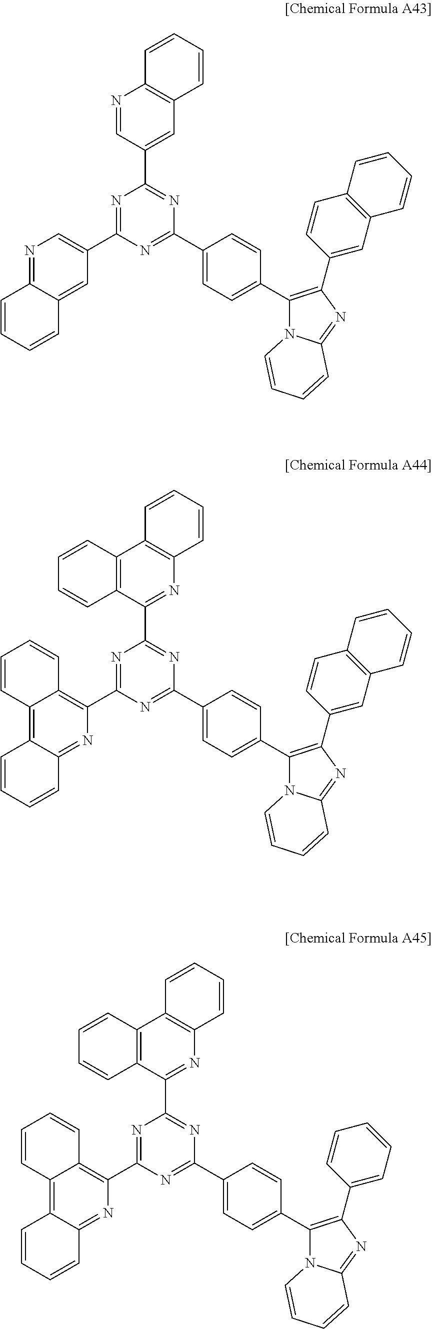 [SMILES: c1ccc2cc(-c3nc4ccccn4c3-c3ccc(-c4nc(-c5cnc6ccccc6c5)nc(-c5cnc6ccccc6c5)n4)cc3)ccc2c1 ; c1ccc2cc(-c3nc4ccccn4c3-c3ccc(-c4nc(-c5nc6ccccc6c6ccccc56)nc(-c5nc6ccccc6c6ccccc56)n4)cc3)ccc2c1 ; c1ccc(-c2nc3ccccn3c2-c2ccc(-c3nc(-c4nc5ccccc5c5ccccc45)nc(-c4nc5ccccc5c5ccccc45)n3)cc2)cc1]

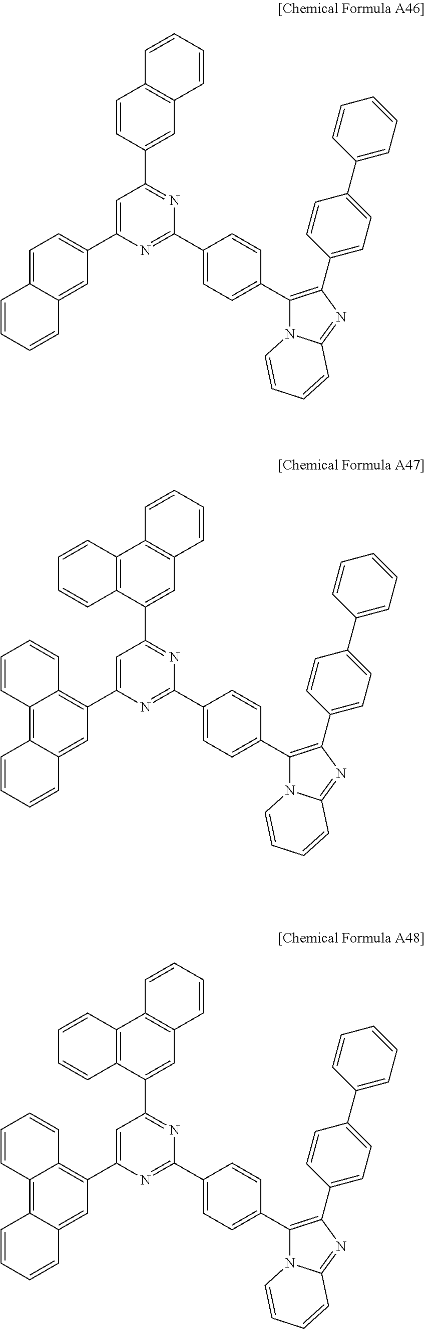 [SMILES: c1ccc(-c2ccc(-c3nc4ccccn4c3-c3ccc(-c4nc(-c5ccc6ccccc6c5)cc(-c5ccc6ccccc6c5)n4)cc3)cc2)cc1 ; c1ccc(-c2ccc(-c3nc4ccccn4c3-c3ccc(-c4nc(-c5cc6ccccc6c6ccccc56)cc(-c5cc6ccccc6c6ccccc56)n4)cc3)cc2)cc1 ; c1ccc(-c2ccc(-c3nc4ccccn4c3-c3ccc(-c4nc(-c5cc6ccccc6c6ccccc56)cc(-c5cc6ccccc6c6ccccc56)n4)cc3)cc2)cc1]

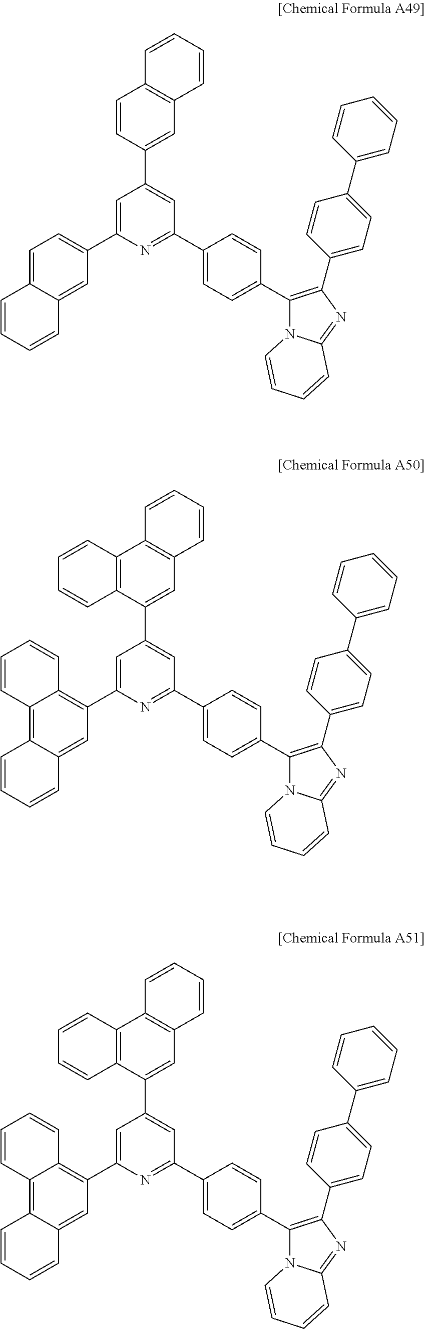 [SMILES: c1ccc(-c2ccc(-c3nc4ccccn4c3-c3ccc(-c4cc(-c5ccc6ccccc6c5)cc(-c5ccc6ccccc6c5)n4)cc3)cc2)cc1 ; c1ccc(-c2ccc(-c3nc4ccccn4c3-c3ccc(-c4cc(-c5cc6ccccc6c6ccccc56)cc(-c5cc6ccccc6c6ccccc56)n4)cc3)cc2)cc1 ; c1ccc(-c2ccc(-c3nc4ccccn4c3-c3ccc(-c4cc(-c5cc6ccccc6c6ccccc56)cc(-c5cc6ccccc6c6ccccc56)n4)cc3)cc2)cc1]

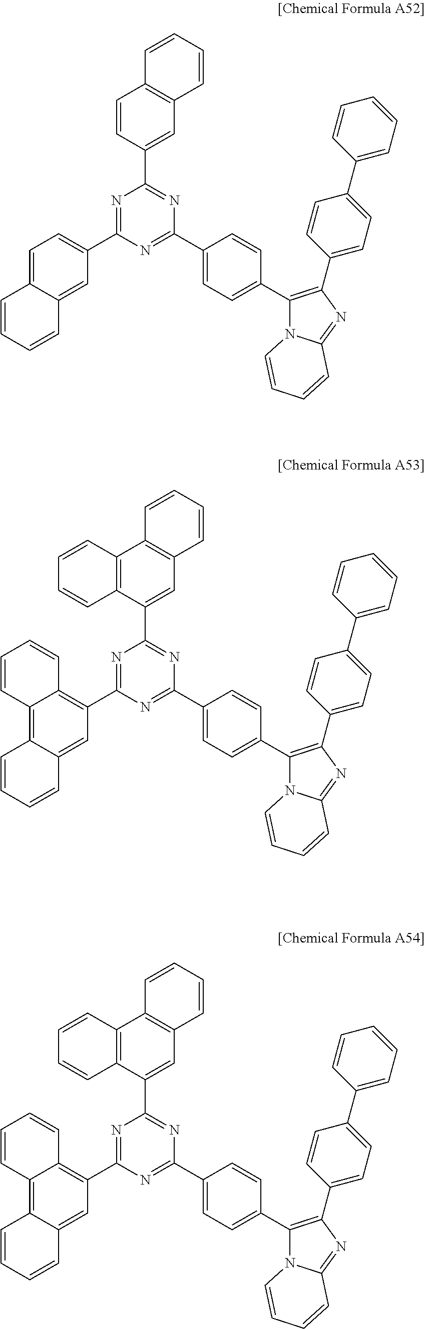 [SMILES: c1ccc(-c2ccc(-c3nc4ccccn4c3-c3ccc(-c4nc(-c5ccc6ccccc6c5)nc(-c5ccc6ccccc6c5)n4)cc3)cc2)cc1 ; c1ccc(-c2ccc(-c3nc4ccccn4c3-c3ccc(-c4nc(-c5cc6ccccc6c6ccccc56)nc(-c5cc6ccccc6c6ccccc56)n4)cc3)cc2)cc1 ; c1ccc(-c2ccc(-c3nc4ccccn4c3-c3ccc(-c4nc(-c5cc6ccccc6c6ccccc56)nc(-c5cc6ccccc6c6ccccc56)n4)cc3)cc2)cc1]

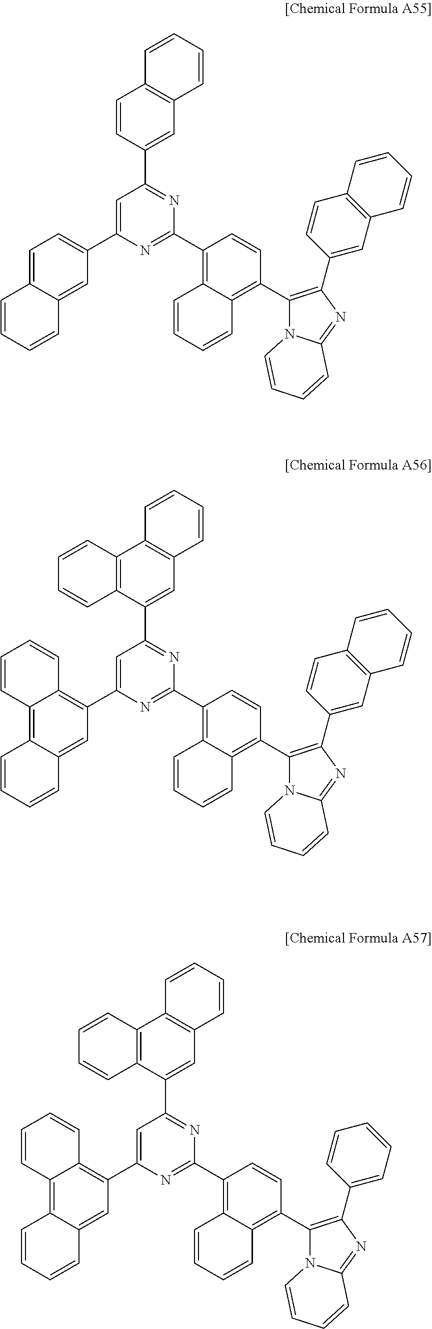 [SMILES: c1ccc2cc(-c3cc(-c4ccc5ccccc5c4)nc(-c4ccc(-c5c(-c6ccc7ccccc7c6)nc6ccccn56)c5ccccc45)n3)ccc2c1 ; c1ccc2cc(-c3nc4ccccn4c3-c3ccc(-c4nc(-c5cc6ccccc6c6ccccc56)cc(-c5cc6ccccc6c6ccccc56)n4)c4ccccc34)ccc2c1 ; c1ccc(-c2nc3ccccn3c2-c2ccc(-c3nc(-c4cc5ccccc5c5ccccc45)cc(-c4cc5ccccc5c5ccccc45)n3)c3ccccc23)cc1]

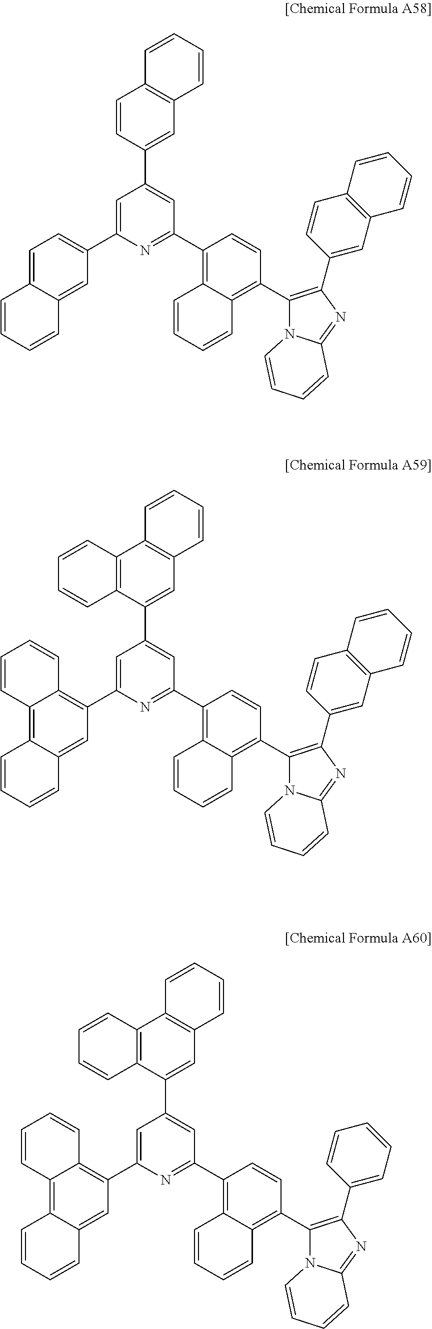 [SMILES: c1ccc2cc(-c3cc(-c4ccc5ccccc5c4)nc(-c4ccc(-c5c(-c6ccc7ccccc7c6)nc6ccccn56)c5ccccc45)c3)ccc2c1 ; c1ccc2cc(-c3nc4ccccn4c3-c3ccc(-c4cc(-c5cc6ccccc6c6ccccc56)cc(-c5cc6ccccc6c6ccccc56)n4)c4ccccc34)ccc2c1 ; c1ccc(-c2nc3ccccn3c2-c2ccc(-c3cc(-c4cc5ccccc5c5ccccc45)cc(-c4cc5ccccc5c5ccccc45)n3)c3ccccc23)cc1]

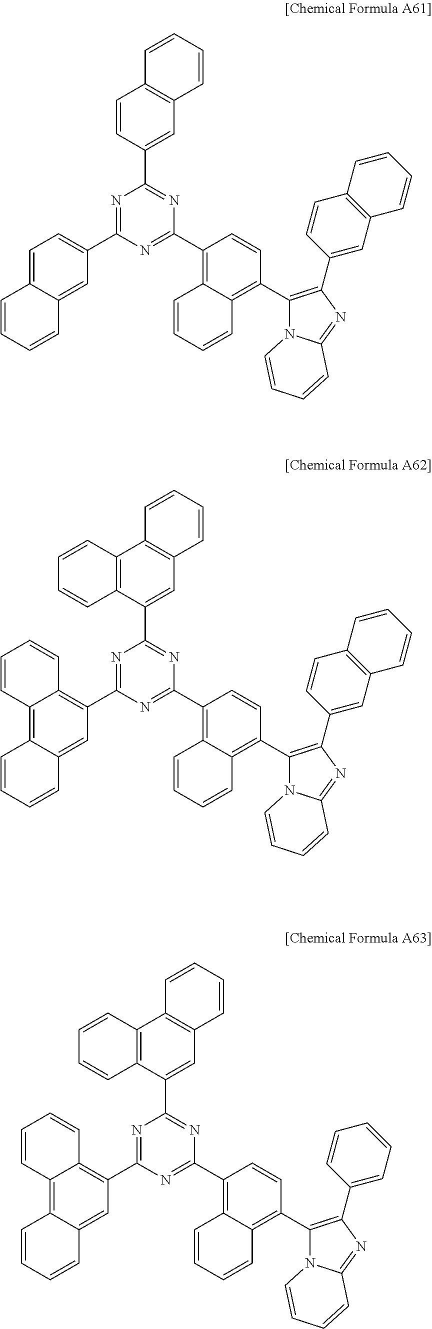 [SMILES: c1ccc2cc(-c3nc(-c4ccc5ccccc5c4)nc(-c4ccc(-c5c(-c6ccc7ccccc7c6)nc6ccccn56)c5ccccc45)n3)ccc2c1 ; c1ccc2cc(-c3nc4ccccn4c3-c3ccc(-c4nc(-c5cc6ccccc6c6ccccc56)nc(-c5cc6ccccc6c6ccccc56)n4)c4ccccc34)ccc2c1 ; c1ccc(-c2nc3ccccn3c2-c2ccc(-c3nc(-c4cc5ccccc5c5ccccc45)nc(-c4cc5ccccc5c5ccccc45)n3)c3ccccc23)cc1]

In an implementation, the compound for an organic optoelectronic device may be represented by one of the following Chemical Formulae B1 to B72.

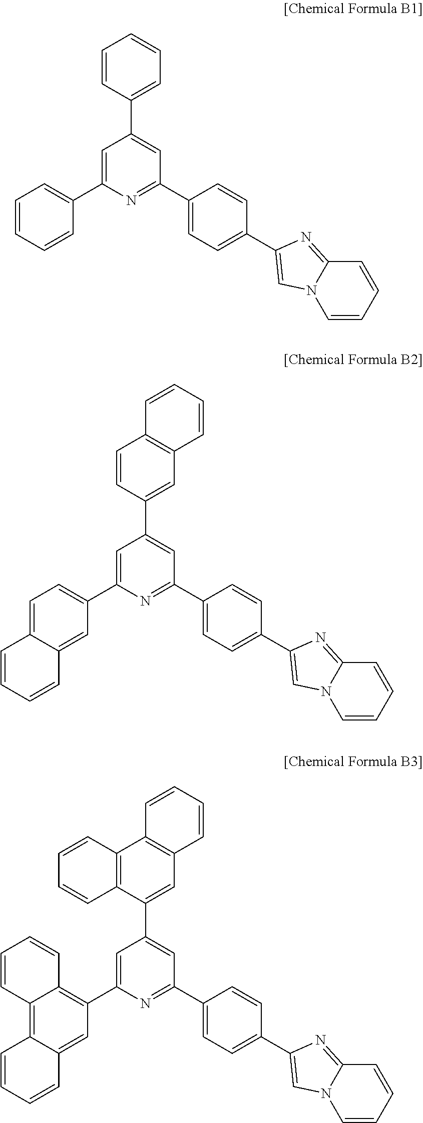 [SMILES: c1ccc(-c2cc(-c3ccccc3)nc(-c3ccc(-c4cn5ccccc5n4)cc3)c2)cc1 ; c1ccc2cc(-c3cc(-c4ccc(-c5cn6ccccc6n5)cc4)nc(-c4ccc5ccccc5c4)c3)ccc2c1 ; c1ccc2c(c1)cc(-c1cc(-c3ccc(-c4cn5ccccc5n4)cc3)nc(-c3cc4ccccc4c4ccccc34)c1)c1ccccc12]

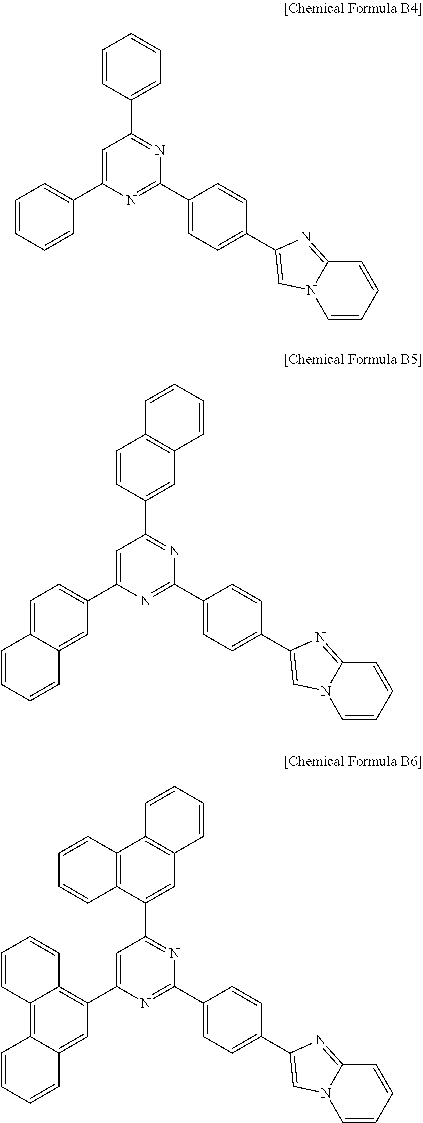 [SMILES: c1ccc(-c2cc(-c3ccccc3)nc(-c3ccc(-c4cn5ccccc5n4)cc3)n2)cc1 ; c1ccc2cc(-c3cc(-c4ccc5ccccc5c4)nc(-c4ccc(-c5cn6ccccc6n5)cc4)n3)ccc2c1 ; c1ccc2c(c1)cc(-c1cc(-c3cc4ccccc4c4ccccc34)nc(-c3ccc(-c4cn5ccccc5n4)cc3)n1)c1ccccc12]

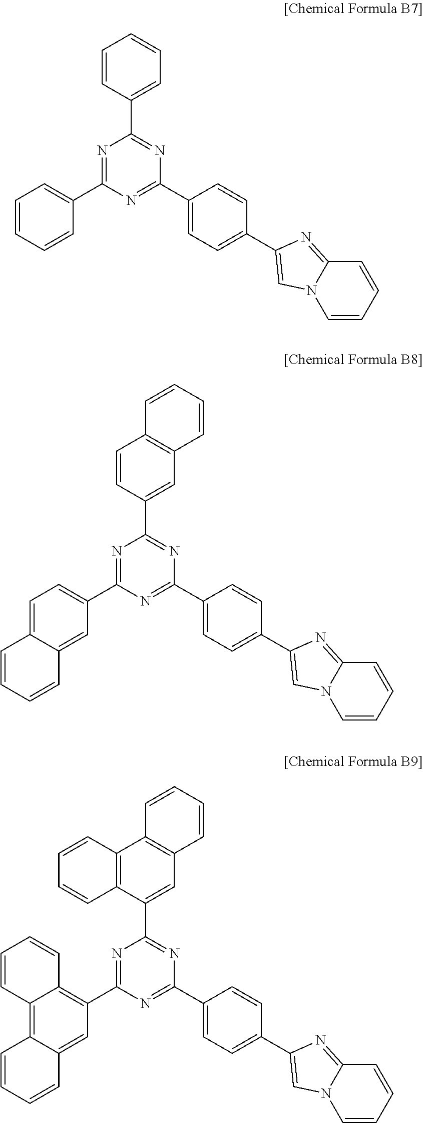 [SMILES: c1ccc(-c2nc(-c3ccccc3)nc(-c3ccc(-c4cn5ccccc5n4)cc3)n2)cc1 ; c1ccc2cc(-c3nc(-c4ccc(-c5cn6ccccc6n5)cc4)nc(-c4ccc5ccccc5c4)n3)ccc2c1 ; c1ccc2c(c1)cc(-c1nc(-c3ccc(-c4cn5ccccc5n4)cc3)nc(-c3cc4ccccc4c4ccccc34)n1)c1ccccc12]

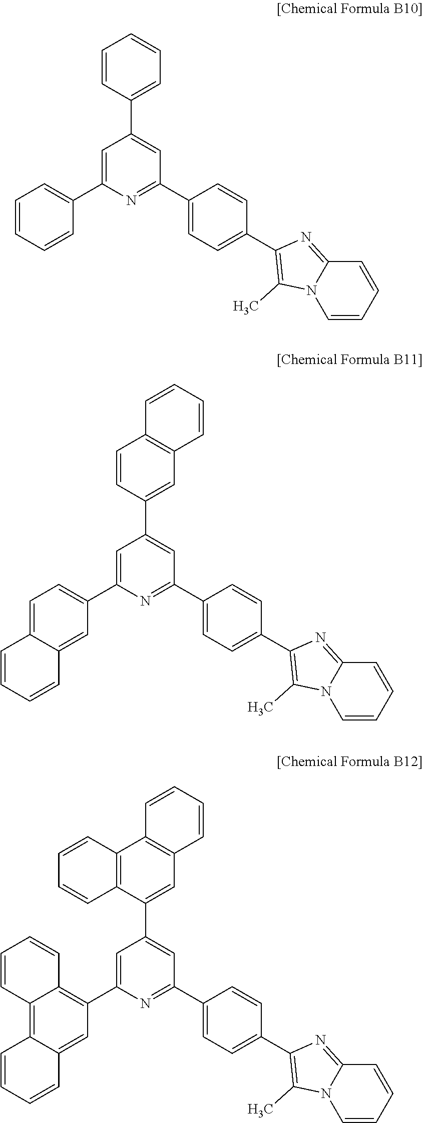 [SMILES: Cc1c(-c2ccc(-c3cc(-c4ccccc4)cc(-c4ccccc4)n3)cc2)nc2ccccn12 ; Cc1c(-c2ccc(-c3cc(-c4ccc5ccccc5c4)cc(-c4ccc5ccccc5c4)n3)cc2)nc2ccccn12 ; Cc1c(-c2ccc(-c3cc(-c4cc5ccccc5c5ccccc45)cc(-c4cc5ccccc5c5ccccc45)n3)cc2)nc2ccccn12]

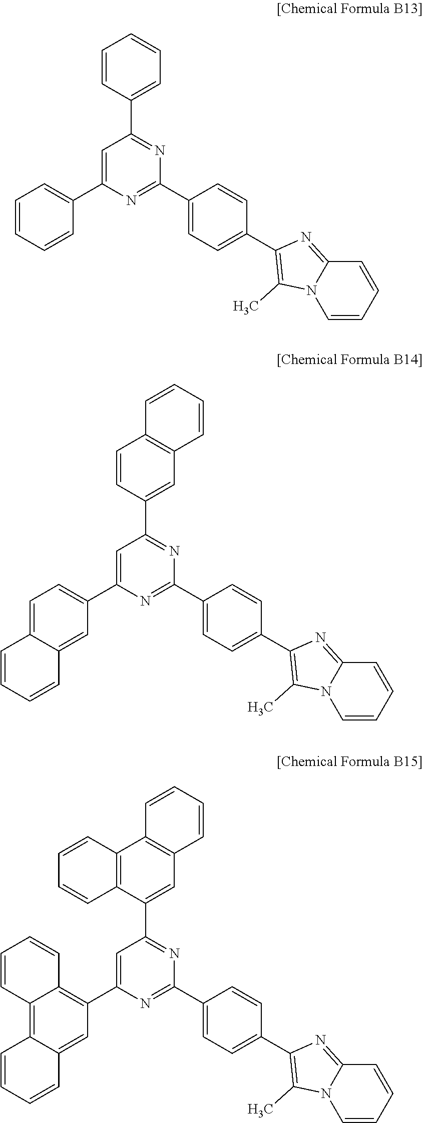 [SMILES: Cc1c(-c2ccc(-c3nc(-c4ccccc4)cc(-c4ccccc4)n3)cc2)nc2ccccn12 ; Cc1c(-c2ccc(-c3nc(-c4ccc5ccccc5c4)cc(-c4ccc5ccccc5c4)n3)cc2)nc2ccccn12 ; Cc1c(-c2ccc(-c3nc(-c4cc5ccccc5c5ccccc45)cc(-c4cc5ccccc5c5ccccc45)n3)cc2)nc2ccccn12]

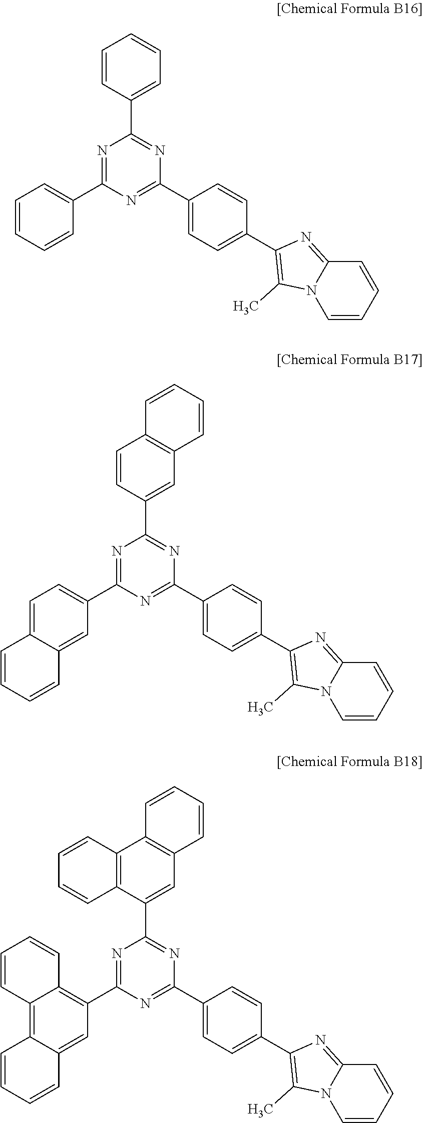 [SMILES: Cc1c(-c2ccc(-c3nc(-c4ccccc4)nc(-c4ccccc4)n3)cc2)nc2ccccn12 ; Cc1c(-c2ccc(-c3nc(-c4ccc5ccccc5c4)nc(-c4ccc5ccccc5c4)n3)cc2)nc2ccccn12 ; Cc1c(-c2ccc(-c3nc(-c4cc5ccccc5c5ccccc45)nc(-c4cc5ccccc5c5ccccc45)n3)cc2)nc2ccccn12]

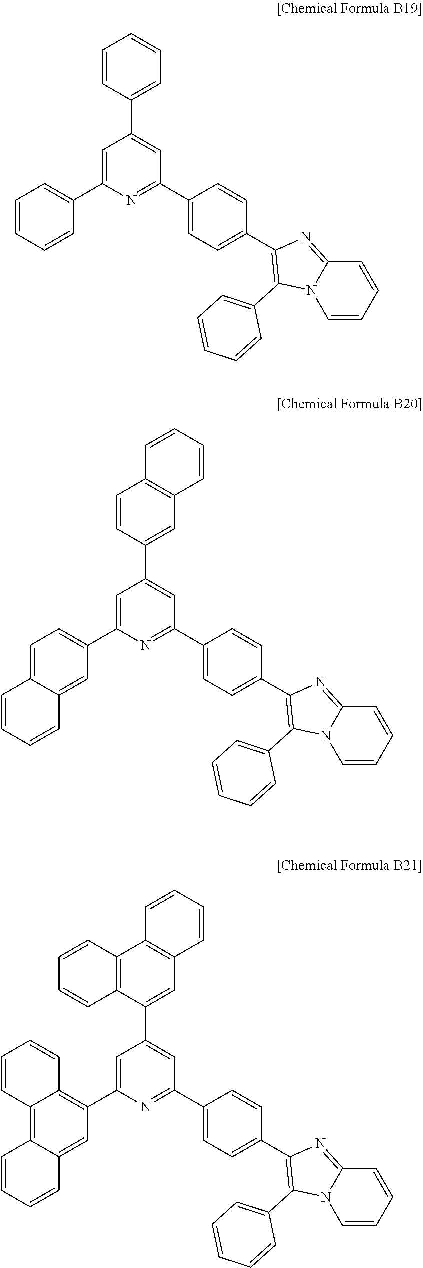 [SMILES: c1ccc(-c2cc(-c3ccccc3)nc(-c3ccc(-c4nc5ccccn5c4-c4ccccc4)cc3)c2)cc1 ; c1ccc(-c2c(-c3ccc(-c4cc(-c5ccc6ccccc6c5)cc(-c5ccc6ccccc6c5)n4)cc3)nc3ccccn23)cc1 ; c1ccc(-c2c(-c3ccc(-c4cc(-c5cc6ccccc6c6ccccc56)cc(-c5cc6ccccc6c6ccccc56)n4)cc3)nc3ccccn23)cc1]

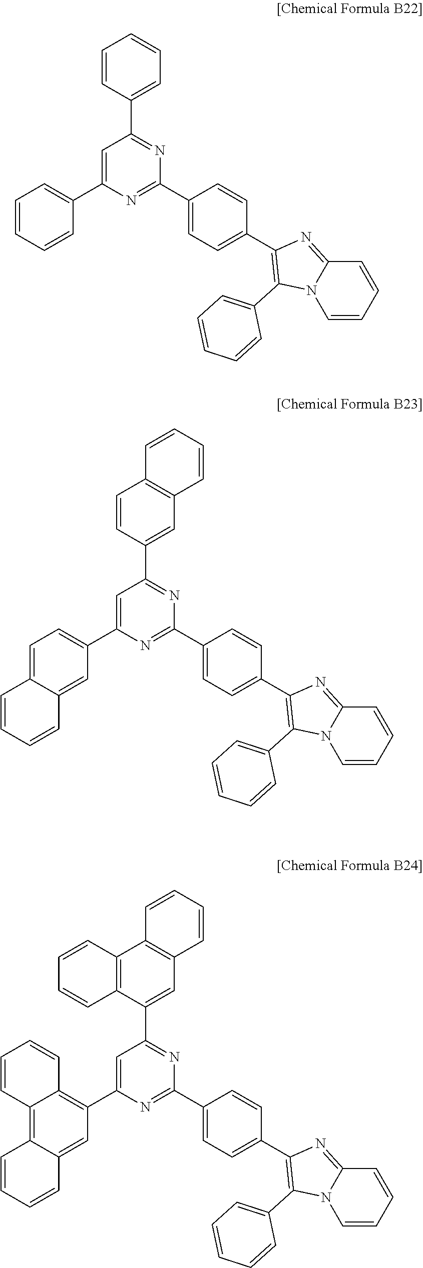 [SMILES: c1ccc(-c2cc(-c3ccccc3)nc(-c3ccc(-c4nc5ccccn5c4-c4ccccc4)cc3)n2)cc1 ; c1ccc(-c2c(-c3ccc(-c4nc(-c5ccc6ccccc6c5)cc(-c5ccc6ccccc6c5)n4)cc3)nc3ccccn23)cc1 ; c1ccc(-c2c(-c3ccc(-c4nc(-c5cc6ccccc6c6ccccc56)cc(-c5cc6ccccc6c6ccccc56)n4)cc3)nc3ccccn23)cc1]

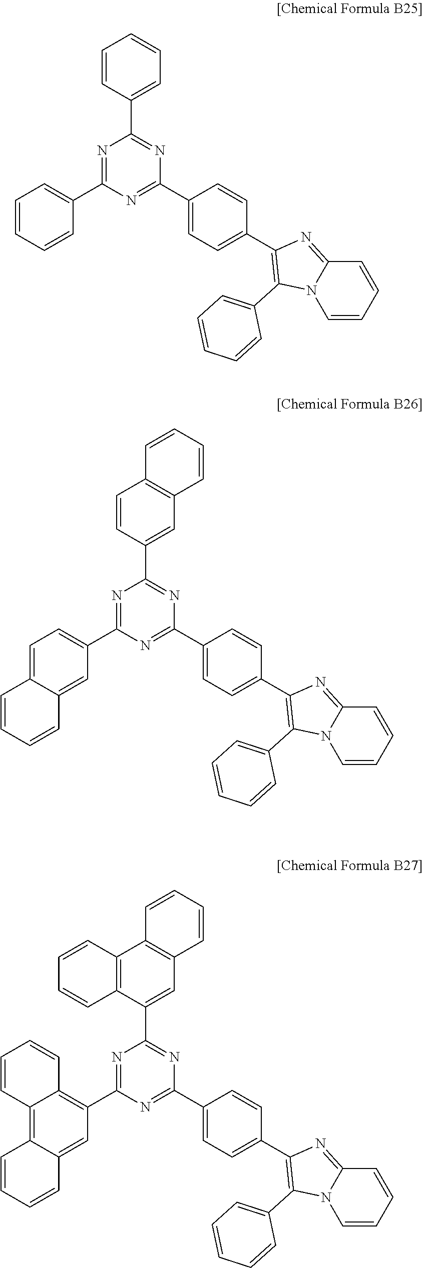 [SMILES: c1ccc(-c2nc(-c3ccccc3)nc(-c3ccc(-c4nc5ccccn5c4-c4ccccc4)cc3)n2)cc1 ; c1ccc(-c2c(-c3ccc(-c4nc(-c5ccc6ccccc6c5)nc(-c5ccc6ccccc6c5)n4)cc3)nc3ccccn23)cc1 ; c1ccc(-c2c(-c3ccc(-c4nc(-c5cc6ccccc6c6ccccc56)nc(-c5cc6ccccc6c6ccccc56)n4)cc3)nc3ccccn23)cc1]

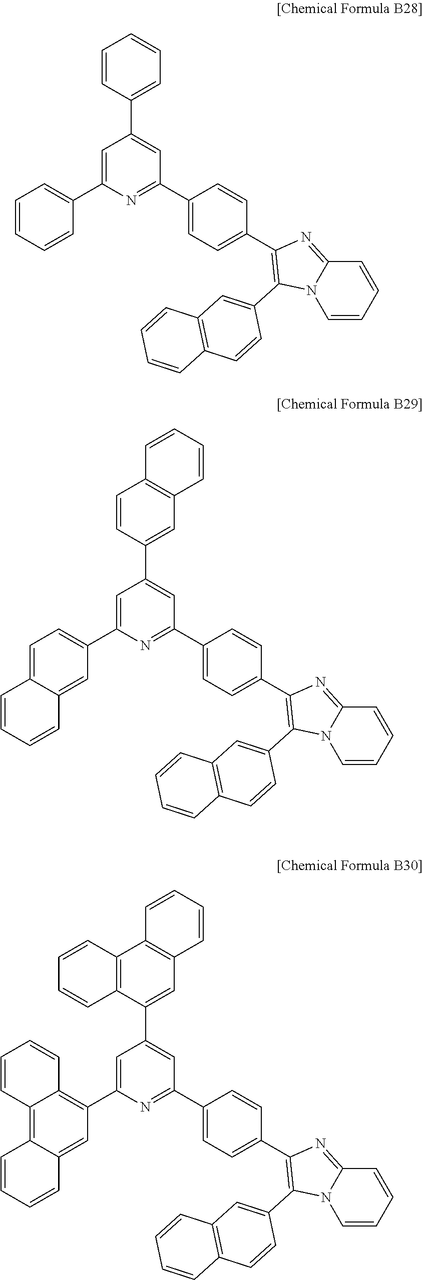 [SMILES: c1ccc(-c2cc(-c3ccccc3)nc(-c3ccc(-c4nc5ccccn5c4-c4ccc5ccccc5c4)cc3)c2)cc1 ; c1ccc2cc(-c3cc(-c4ccc(-c5nc6ccccn6c5-c5ccc6ccccc6c5)cc4)nc(-c4ccc5ccccc5c4)c3)ccc2c1 ; c1ccc2cc(-c3c(-c4ccc(-c5cc(-c6cc7ccccc7c7ccccc67)cc(-c6cc7ccccc7c7ccccc67)n5)cc4)nc4ccccn34)ccc2c1]

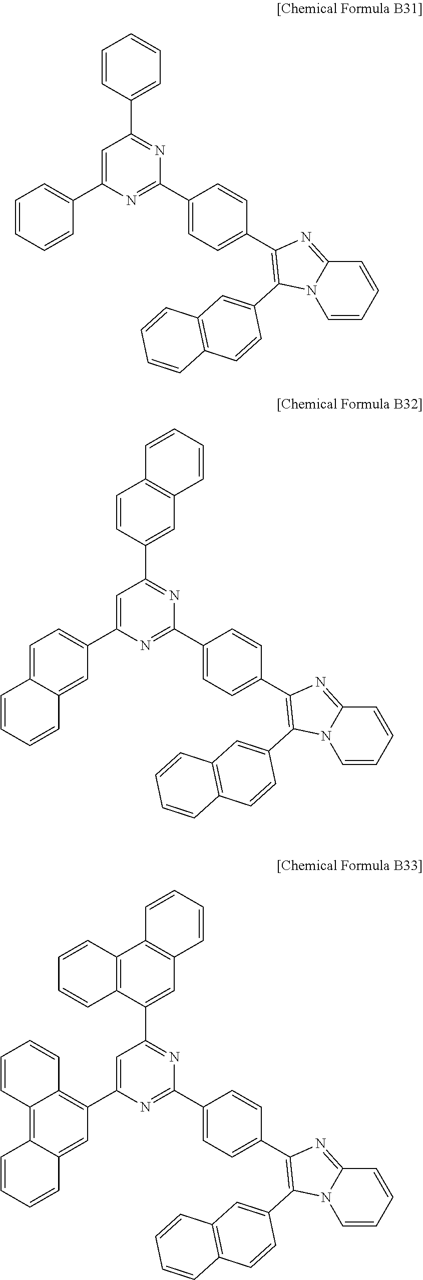 [SMILES: c1ccc(-c2cc(-c3ccccc3)nc(-c3ccc(-c4nc5ccccn5c4-c4ccc5ccccc5c4)cc3)n2)cc1 ; c1ccc2cc(-c3cc(-c4ccc5ccccc5c4)nc(-c4ccc(-c5nc6ccccn6c5-c5ccc6ccccc6c5)cc4)n3)ccc2c1 ; c1ccc2cc(-c3c(-c4ccc(-c5nc(-c6cc7ccccc7c7ccccc67)cc(-c6cc7ccccc7c7ccccc67)n5)cc4)nc4ccccn34)ccc2c1]

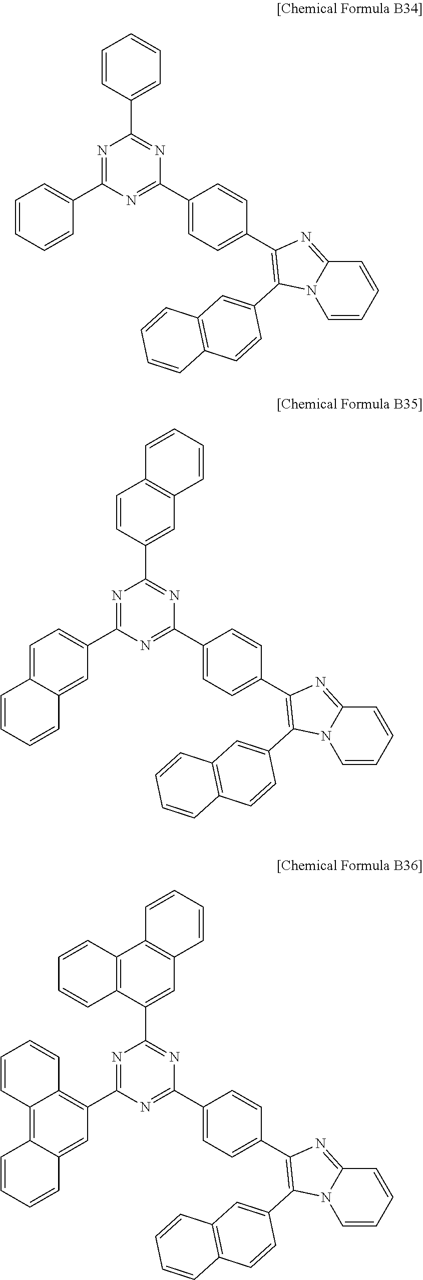 [SMILES: c1ccc(-c2nc(-c3ccccc3)nc(-c3ccc(-c4nc5ccccn5c4-c4ccc5ccccc5c4)cc3)n2)cc1 ; c1ccc2cc(-c3nc(-c4ccc(-c5nc6ccccn6c5-c5ccc6ccccc6c5)cc4)nc(-c4ccc5ccccc5c4)n3)ccc2c1 ; c1ccc2cc(-c3c(-c4ccc(-c5nc(-c6cc7ccccc7c7ccccc67)nc(-c6cc7ccccc7c7ccccc67)n5)cc4)nc4ccccn34)ccc2c1]

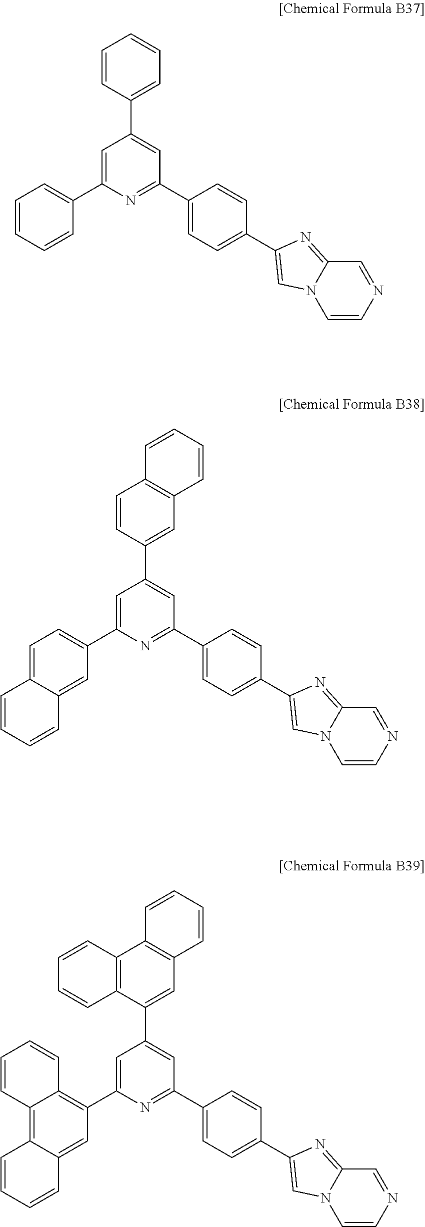 [SMILES: c1ccc(-c2cc(-c3ccccc3)nc(-c3ccc(-c4cn5ccncc5n4)cc3)c2)cc1 ; c1ccc2cc(-c3cc(-c4ccc(-c5cn6ccncc6n5)cc4)nc(-c4ccc5ccccc5c4)c3)ccc2c1 ; c1ccc2c(c1)cc(-c1cc(-c3ccc(-c4cn5ccncc5n4)cc3)nc(-c3cc4ccccc4c4ccccc34)c1)c1ccccc12]

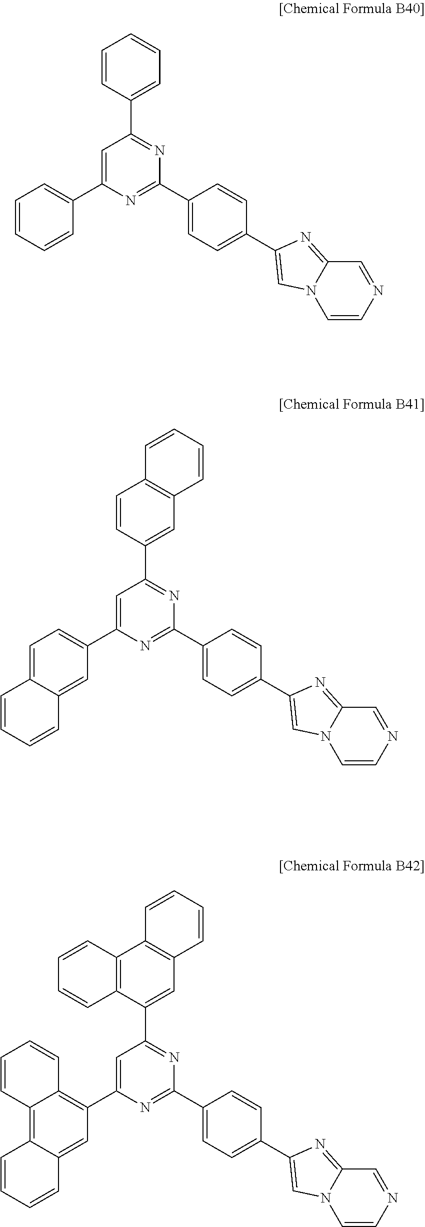 [SMILES: c1ccc(-c2cc(-c3ccccc3)nc(-c3ccc(-c4cn5ccncc5n4)cc3)n2)cc1 ; c1ccc2cc(-c3cc(-c4ccc5ccccc5c4)nc(-c4ccc(-c5cn6ccncc6n5)cc4)n3)ccc2c1 ; c1ccc2c(c1)cc(-c1cc(-c3cc4ccccc4c4ccccc34)nc(-c3ccc(-c4cn5ccncc5n4)cc3)n1)c1ccccc12]

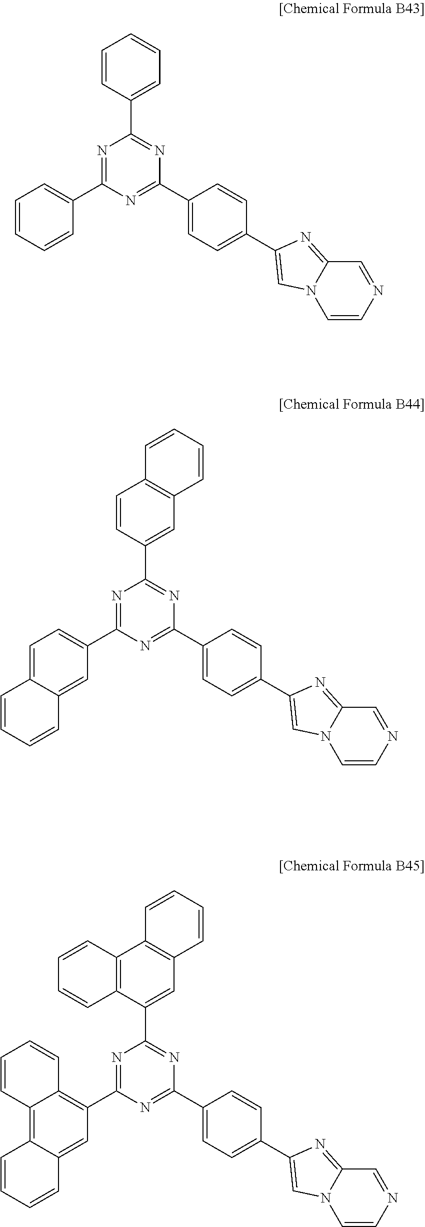 [SMILES: c1ccc(-c2nc(-c3ccccc3)nc(-c3ccc(-c4cn5ccncc5n4)cc3)n2)cc1 ; c1ccc2cc(-c3nc(-c4ccc(-c5cn6ccncc6n5)cc4)nc(-c4ccc5ccccc5c4)n3)ccc2c1 ; c1ccc2c(c1)cc(-c1nc(-c3ccc(-c4cn5ccncc5n4)cc3)nc(-c3cc4ccccc4c4ccccc34)n1)c1ccccc12]

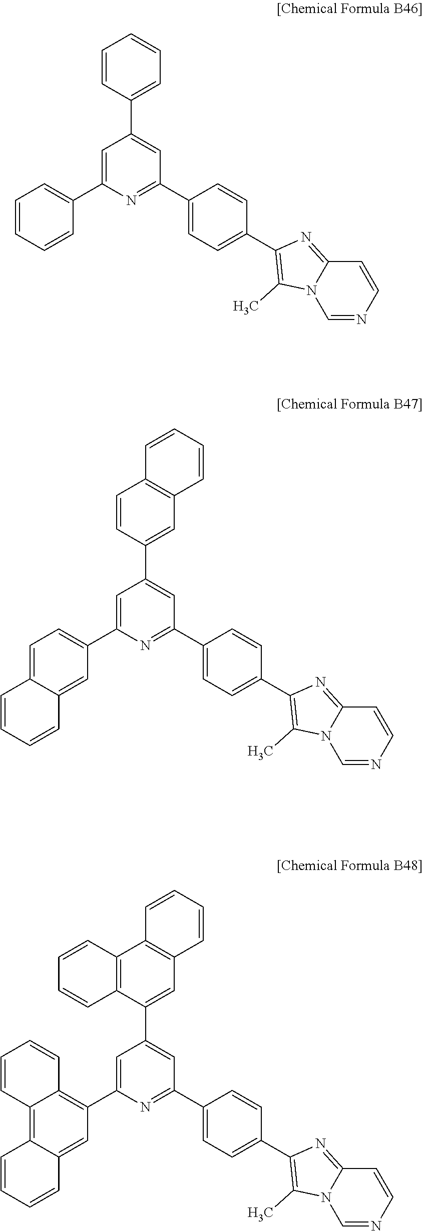 [SMILES: Cc1c(-c2ccc(-c3cc(-c4ccccc4)cc(-c4ccccc4)n3)cc2)nc2ccncn12 ; Cc1c(-c2ccc(-c3cc(-c4ccc5ccccc5c4)cc(-c4ccc5ccccc5c4)n3)cc2)nc2ccncn12 ; Cc1c(-c2ccc(-c3cc(-c4cc5ccccc5c5ccccc45)cc(-c4cc5ccccc5c5ccccc45)n3)cc2)nc2ccncn12]

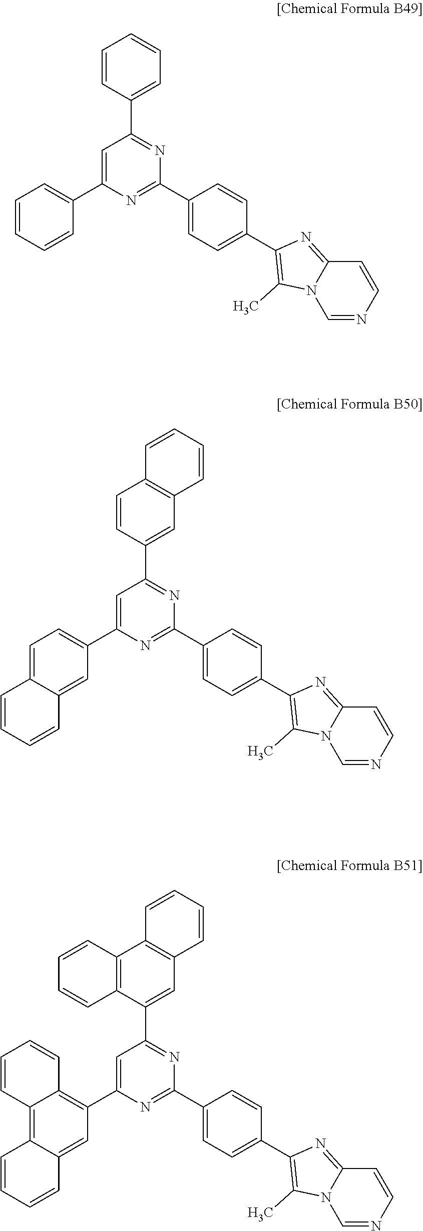 [SMILES: Cc1c(-c2ccc(-c3nc(-c4ccccc4)cc(-c4ccccc4)n3)cc2)nc2ccncn12 ; Cc1c(-c2ccc(-c3nc(-c4ccc5ccccc5c4)cc(-c4ccc5ccccc5c4)n3)cc2)nc2ccncn12 ; Cc1c(-c2ccc(-c3nc(-c4cc5ccccc5c5ccccc45)cc(-c4cc5ccccc5c5ccccc45)n3)cc2)nc2ccncn12]

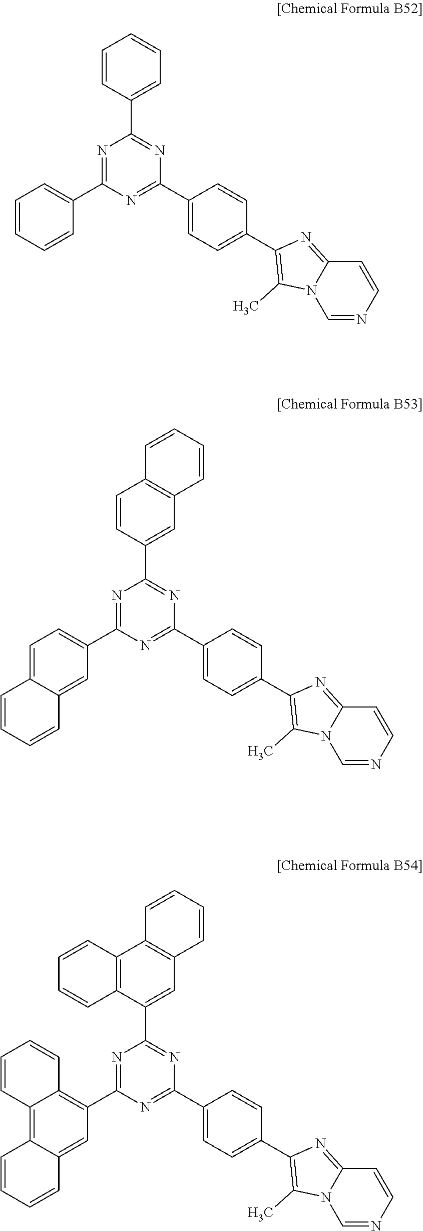 [SMILES: Cc1c(-c2ccc(-c3nc(-c4ccccc4)nc(-c4ccccc4)n3)cc2)nc2ccncn12 ; Cc1c(-c2ccc(-c3nc(-c4ccc5ccccc5c4)nc(-c4ccc5ccccc5c4)n3)cc2)nc2ccncn12 ; Cc1c(-c2ccc(-c3nc(-c4cc5ccccc5c5ccccc45)nc(-c4cc5ccccc5c5ccccc45)n3)cc2)nc2ccncn12]

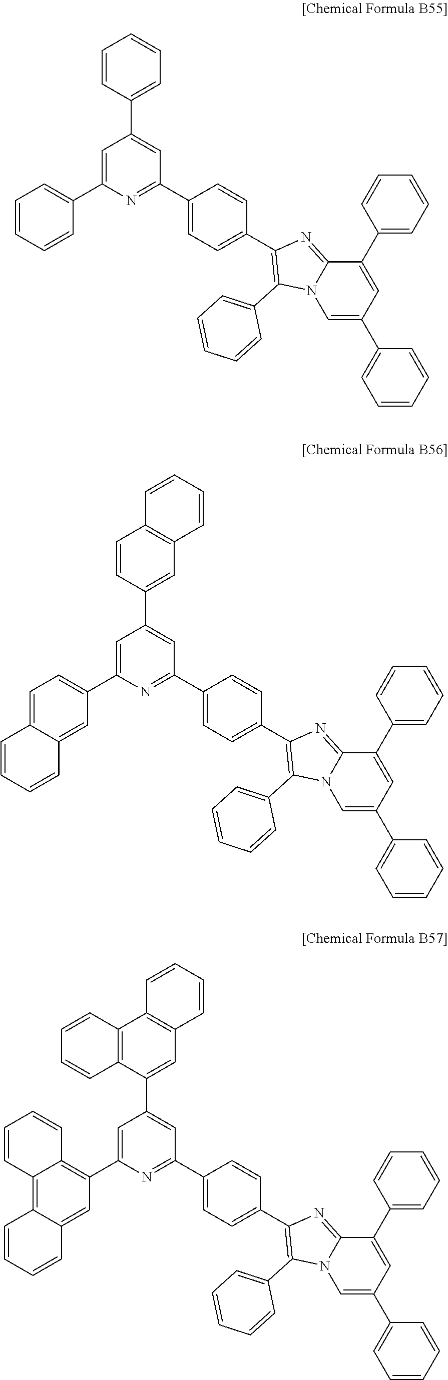 [SMILES: c1ccc(-c2cc(-c3ccccc3)nc(-c3ccc(-c4nc5c(-c6ccccc6)cc(-c6ccccc6)cn5c4-c4ccccc4)cc3)c2)cc1 ; c1ccc(-c2cc(-c3ccccc3)c3nc(-c4ccc(-c5cc(-c6ccc7ccccc7c6)cc(-c6ccc7ccccc7c6)n5)cc4)c(-c4ccccc4)n3c2)cc1 ; c1ccc(-c2cc(-c3ccccc3)c3nc(-c4ccc(-c5cc(-c6cc7ccccc7c7ccccc67)cc(-c6cc7ccccc7c7ccccc67)n5)cc4)c(-c4ccccc4)n3c2)cc1]

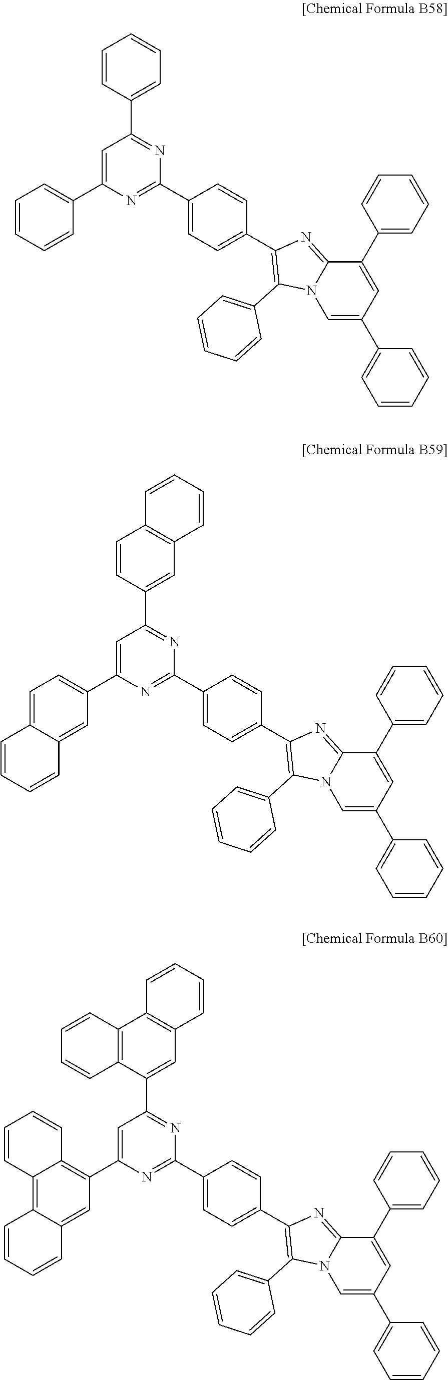 [SMILES: c1ccc(-c2cc(-c3ccccc3)c3nc(-c4ccc(-c5nc(-c6ccccc6)cc(-c6ccccc6)n5)cc4)c(-c4ccccc4)n3c2)cc1 ; c1ccc(-c2cc(-c3ccccc3)c3nc(-c4ccc(-c5nc(-c6ccc7ccccc7c6)cc(-c6ccc7ccccc7c6)n5)cc4)c(-c4ccccc4)n3c2)cc1 ; c1ccc(-c2cc(-c3ccccc3)c3nc(-c4ccc(-c5nc(-c6cc7ccccc7c7ccccc67)cc(-c6cc7ccccc7c7ccccc67)n5)cc4)c(-c4ccccc4)n3c2)cc1]

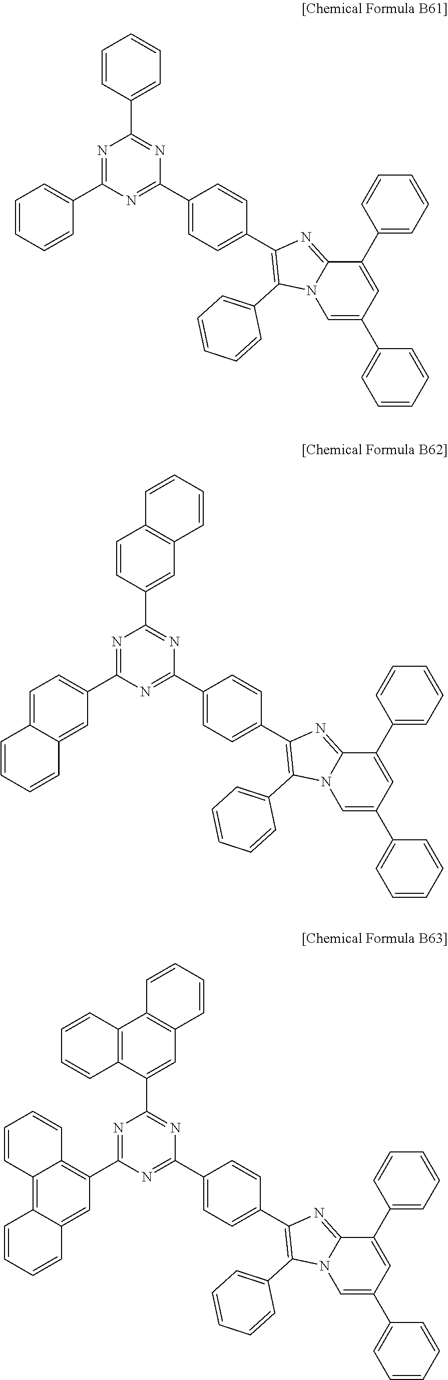 [SMILES: c1ccc(-c2cc(-c3ccccc3)c3nc(-c4ccc(-c5nc(-c6ccccc6)nc(-c6ccccc6)n5)cc4)c(-c4ccccc4)n3c2)cc1 ; c1ccc(-c2cc(-c3ccccc3)c3nc(-c4ccc(-c5nc(-c6ccc7ccccc7c6)nc(-c6ccc7ccccc7c6)n5)cc4)c(-c4ccccc4)n3c2)cc1 ; c1ccc(-c2cc(-c3ccccc3)c3nc(-c4ccc(-c5nc(-c6cc7ccccc7c7ccccc67)nc(-c6cc7ccccc7c7ccccc67)n5)cc4)c(-c4ccccc4)n3c2)cc1]

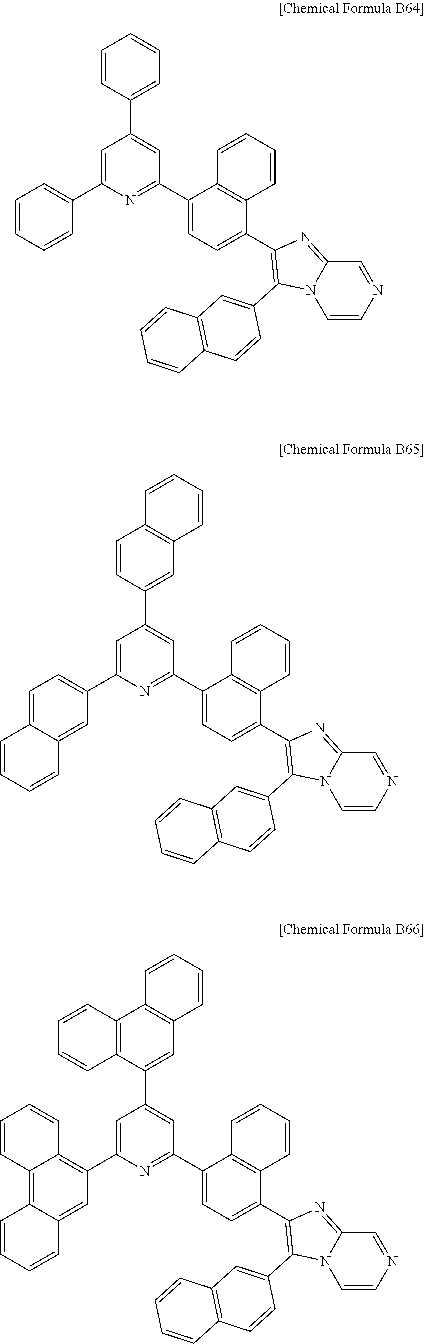 [SMILES: c1ccc(-c2cc(-c3ccccc3)nc(-c3ccc(-c4nc5cnccn5c4-c4ccc5ccccc5c4)c4ccccc34)c2)cc1 ; c1ccc2cc(-c3cc(-c4ccc5ccccc5c4)nc(-c4ccc(-c5nc6cnccn6c5-c5ccc6ccccc6c5)c5ccccc45)c3)ccc2c1 ; c1ccc2cc(-c3c(-c4ccc(-c5cc(-c6cc7ccccc7c7ccccc67)cc(-c6cc7ccccc7c7ccccc67)n5)c5ccccc45)nc4cnccn34)ccc2c1]

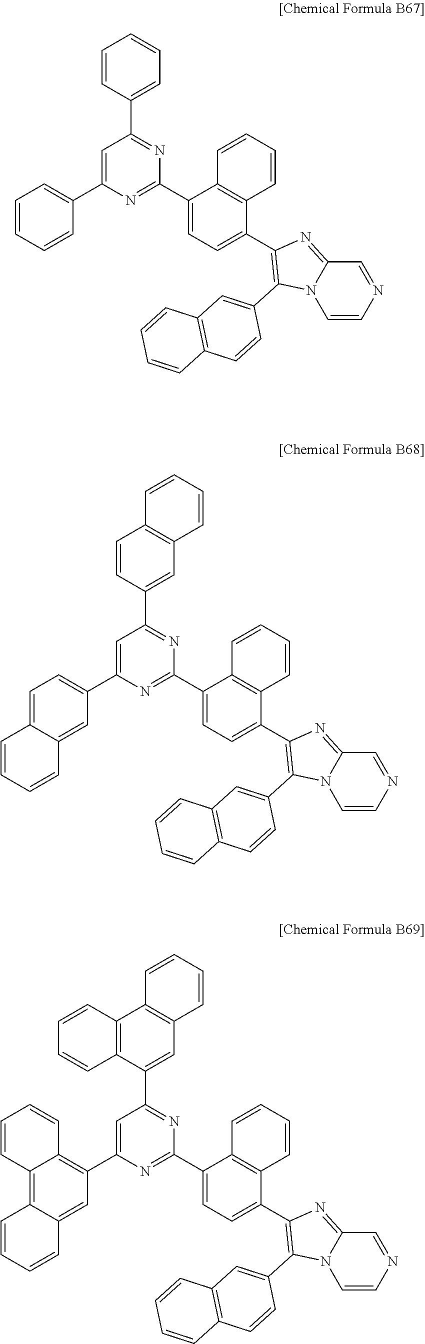 [SMILES: c1ccc(-c2cc(-c3ccccc3)nc(-c3ccc(-c4nc5cnccn5c4-c4ccc5ccccc5c4)c4ccccc34)n2)cc1 ; c1ccc2cc(-c3cc(-c4ccc5ccccc5c4)nc(-c4ccc(-c5nc6cnccn6c5-c5ccc6ccccc6c5)c5ccccc45)n3)ccc2c1 ; c1ccc2cc(-c3c(-c4ccc(-c5nc(-c6cc7ccccc7c7ccccc67)cc(-c6cc7ccccc7c7ccccc67)n5)c5ccccc45)nc4cnccn34)ccc2c1]

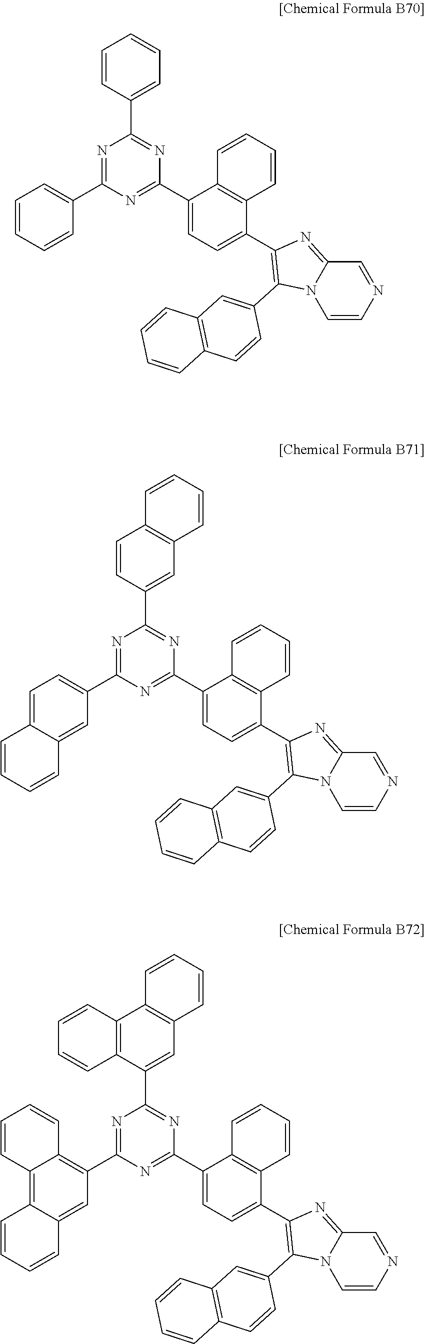 [SMILES: c1ccc(-c2nc(-c3ccccc3)nc(-c3ccc(-c4nc5cnccn5c4-c4ccc5ccccc5c4)c4ccccc34)n2)cc1 ; c1ccc2cc(-c3nc(-c4ccc5ccccc5c4)nc(-c4ccc(-c5nc6cnccn6c5-c5ccc6ccccc6c5)c5ccccc45)n3)ccc2c1 ; c1ccc2cc(-c3c(-c4ccc(-c5nc(-c6cc7ccccc7c7ccccc67)nc(-c6cc7ccccc7c7ccccc67)n5)c5ccccc45)nc4cnccn34)ccc2c1]

The compound for an organic optoelectronic device including one of the above compounds may have a glass transition temperature of greater than or equal to 110° C., and a thermal decomposition temperature of greater than or equal to 400° C., indicating improved thermal stability. Accordingly, it is possible to produce an organic optoelectronic device having a high efficiency.

The compound for an organic optoelectronic device including one of the above compounds may play a role for emitting light or injecting and/or transporting electrons, and may also act as a light emitting host with an appropriate dopant. For example, the compound for an organic optoelectronic device may be used as a phosphorescent or fluorescent host material, a blue light emitting dopant material, or an electron transport material.

The compound for an organic optoelectronic device according to an embodiment may be used for an organic thin layer and may help improve the life-span characteristic. Thus, efficiency characteristic, electrochemical stability, and thermal stability of an organic optoelectronic device may be improved, and the driving voltage may be decreased.

Therefore, according to another embodiment, an organic optoelectronic device that includes the compound for an organic optoelectronic device may be provided. The organic optoelectronic device may be, e.g., an organic photoelectric device, an organic light emitting diode, an organic solar cell, an organic transistor, an organic photo conductor drum, an organic memory device, or the like. For example, the compound for an organic optoelectronic device according to an embodiment may be included in an electrode or an electrode buffer layer in the organic solar cell to help improve the quantum efficiency, and/or it may be used as an electrode material for a gate, a source-drain electrode, or the like in the organic transistor.

Hereinafter, an organic light emitting diode is described in detail.

According to another embodiment, an organic light emitting diode may include an anode, a cathode, and at least one organic thin layer between the anode and the cathode. The least one organic thin layer may include the compound for an organic optoelectronic device according to an embodiment.

The at least one organic thin layer may include a layer selected from the group of an emission layer, a hole transport layer (HTL), a hole injection layer (HIL), an electron transport layer (ETL), an electron injection layer (EIL), a hole blocking layer, and a combination thereof. The at least one organic thin layer may include the compound for an organic optoelectronic device according to an embodiment. For example, the compound for an organic optoelectronic device according to an embodiment may be included in an electron transport layer (ETL) or an electron injection layer (EIL). In an implementation, when the compound for an organic optoelectronic device is included in the emission layer, the compound for an organic optoelectronic device may be included as a phosphorescent or fluorescent host and/or as a fluorescent blue dopant material.

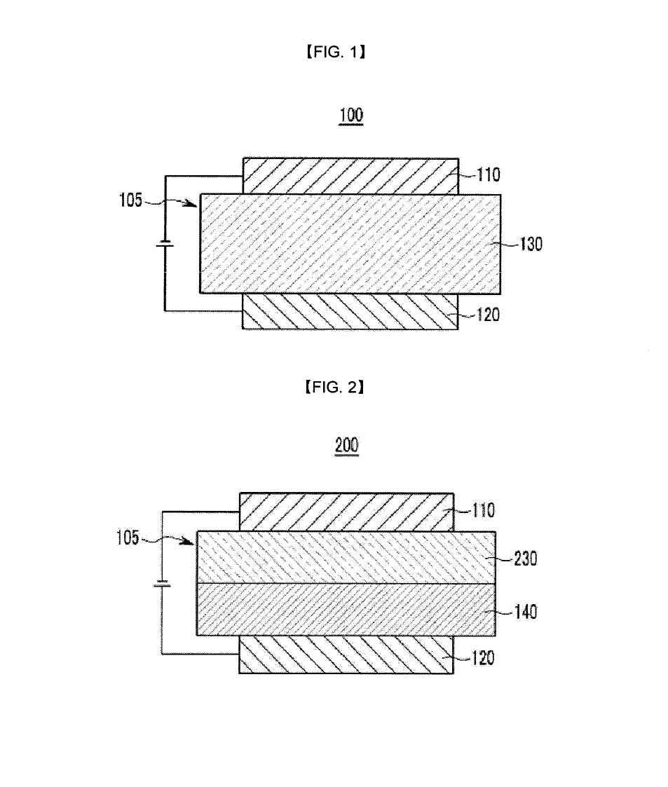

FIGS. 1 to 5 illustrate cross-sectional views showing organic light emitting diodes including the compound for an organic optoelectronic device according to an embodiment.

Referring to FIGS. 1 to 5, organic light emitting diodes 100, 200, 300, 400, and 500 according to an embodiment may include at least one organic thin layer 105 interposed between an anode 120 and a cathode 110.

The anode 120 may include an anode material having a large work function to facilitate hole injection into an organic thin layer. The anode material may include, e.g., a metal such as nickel, platinum, vanadium, chromium, copper, zinc, and gold, or alloys thereof; a metal oxide such as zinc oxide, indium oxide, indium tin oxide (ITO), and indium zinc oxide (IZO); a combined metal and oxide such as ZnO:Al or SnO₂:Sb; or a conductive polymer such as poly(3-methylthiophene), poly[3,4-(ethylene-1,2-dioxy)thiophene] (PEDT), polypyrrole, and polyaniline. In an implementation, a transparent electrode such as indium tin oxide (ITO) may be included in an anode.

The cathode 110 may include a cathode material having a small work function to facilitate electron injection into an organic thin layer. The cathode material may include, e.g., a metal such as magnesium, calcium, sodium, potassium, titanium, indium, yttrium, lithium, gadolinium, aluminum, silver, tin, and lead, or alloys thereof; or a multi-layered material such as LiF/Al, Liq/Al, LiO₂/Al, LiF/Ca, LiF/Al, and BaF₂/Ca. In an implementation, a metal electrode including aluminum may be included in a cathode.

Referring to FIG. 1, the organic photoelectric device 100 may include an organic thin layer 105 including only an emission layer 130.

Referring to FIG. 2, a double-layered organic photoelectric device 200 may include an organic thin layer 105 including an emission layer 230 including an electron transport layer (ETL), and a hole transport layer (HTL) 140. As shown in FIG. 2, the organic thin layer 105 may include a double layer of the emission layer 230 and hole transport layer (HTL) 140. The emission layer 230 may also function as an electron transport layer (ETL), and the hole transport layer (HTL) 140 layer may have an excellent binding property with a transparent electrode such as ITO or an excellent hole transport capability.

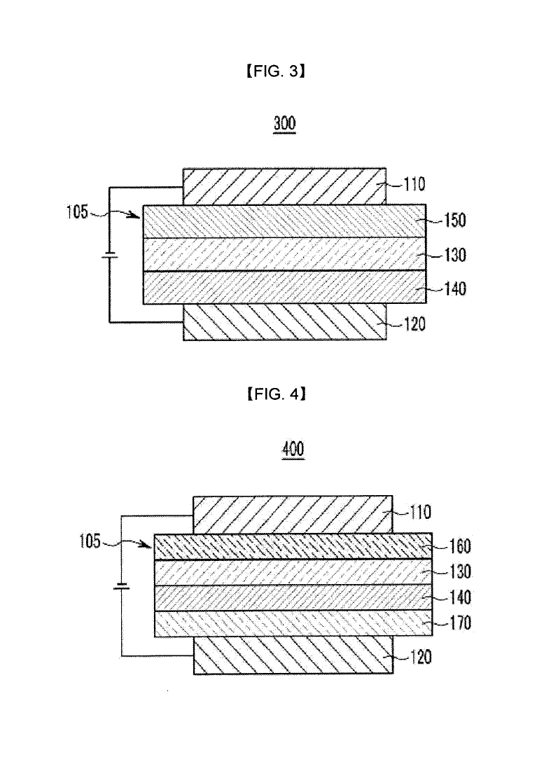

Referring to FIG. 3, a three-layered organic photoelectric device 300 may include an organic thin layer 105 including an electron transport layer (ETL) 150, an emission layer 130, and a hole transport layer (HTL) 140. The emission layer 130 may be independently installed, and layers having an excellent electron transport capability or an excellent hole transport capability may be separately stacked.

As shown in FIG. 4, a four-layered organic photoelectric device 400 may include an organic thin layer 105 including an electron injection layer (EIL) 160, an emission layer 130, a hole transport layer (HTL) 140, and a hole injection layer (HIL) 170 for adherence with the anode 120 of ITO.

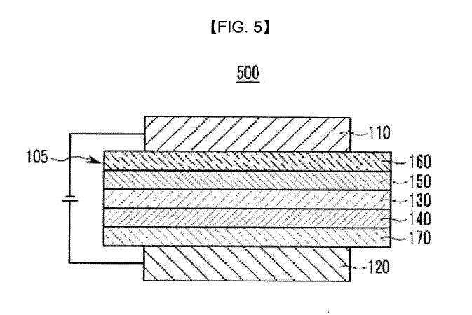

As shown in FIG. 5, a five layered organic photoelectric device 500 may include an organic thin layer 105 including an electron transport layer (ETL) 150, an emission layer 130, a hole transport layer (HTL) 140, and a hole injection layer (HIL) 170, and further includes an electron injection layer (EIL) 160 to achieve a low voltage.

In FIGS. 1 to 5, the organic thin layer 105 including at least one selected from the group of an electron transport layer (ETL) 150, an electron injection layer (EIL) 160, emission layers 130 and 230, a hole transport layer (HTL) 140, a hole injection layer (HIL) 170, and combinations thereof may include the compound for an organic optoelectronic device. The compound for an organic optoelectronic device may be used for an electron transport layer (ETL) 150 or electron injection layer (EIL) 160. When it is used for the electron transport layer (ETL), it is possible to provide an organic photoelectric device having a more simple structure because an additional hole blocking layer (not shown) may be omitted.

When the compound for an organic optoelectronic device is included in the emission layers 130 and 230, the material for the organic photoelectric device may be included as a phosphorescent or fluorescent host or a fluorescent blue dopant.

The organic light emitting diode may be fabricated by, e.g., forming an anode on a substrate; forming an organic thin layer in accordance with a dry coating method such as evaporation, sputtering, plasma plating, and ion plating or a wet coating method such as spin coating, dipping, and flow coating; and providing a cathode thereon.

Another embodiment provides a display device including the organic photoelectric device according to the above embodiment.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

(Preparation of Compound for Organic Photoelectric Device)

### EXAMPLE 1

### Synthesis of Compound Represented by Chemical Formula A1

The compound represented by Chemical Formula A1 was synthesized through 6 steps as shown in of the following Reaction Scheme 1:

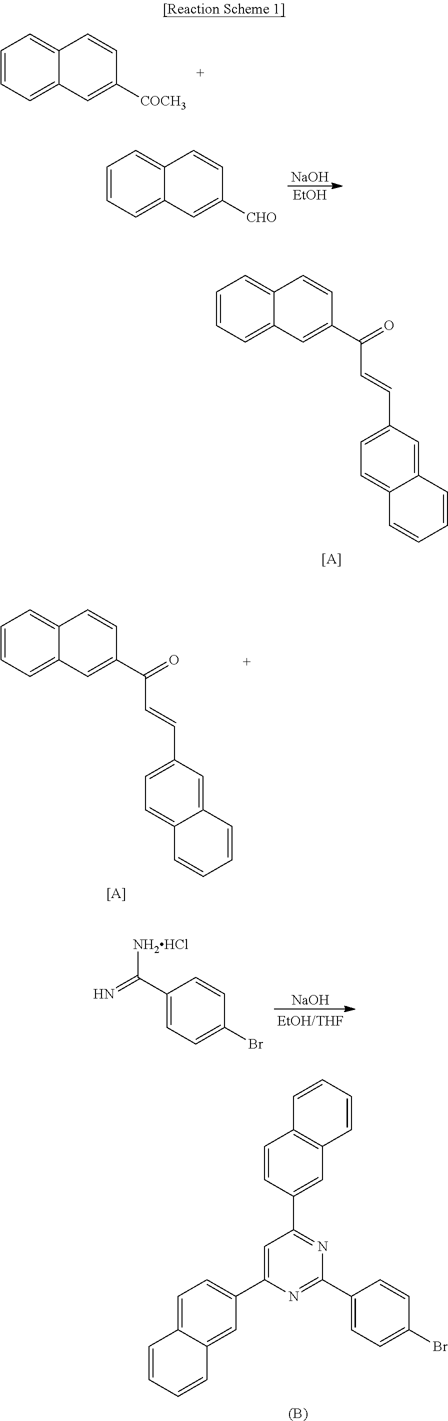

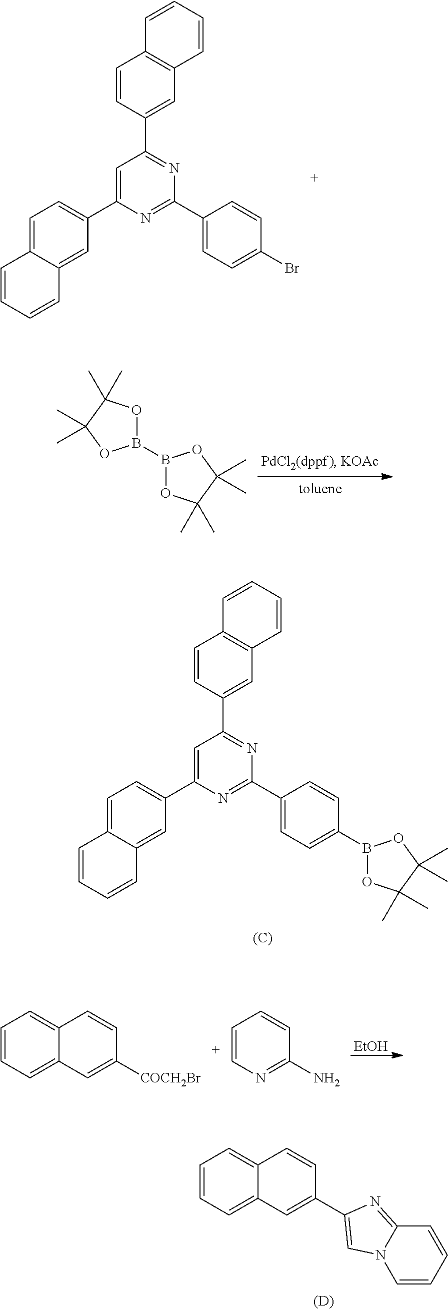

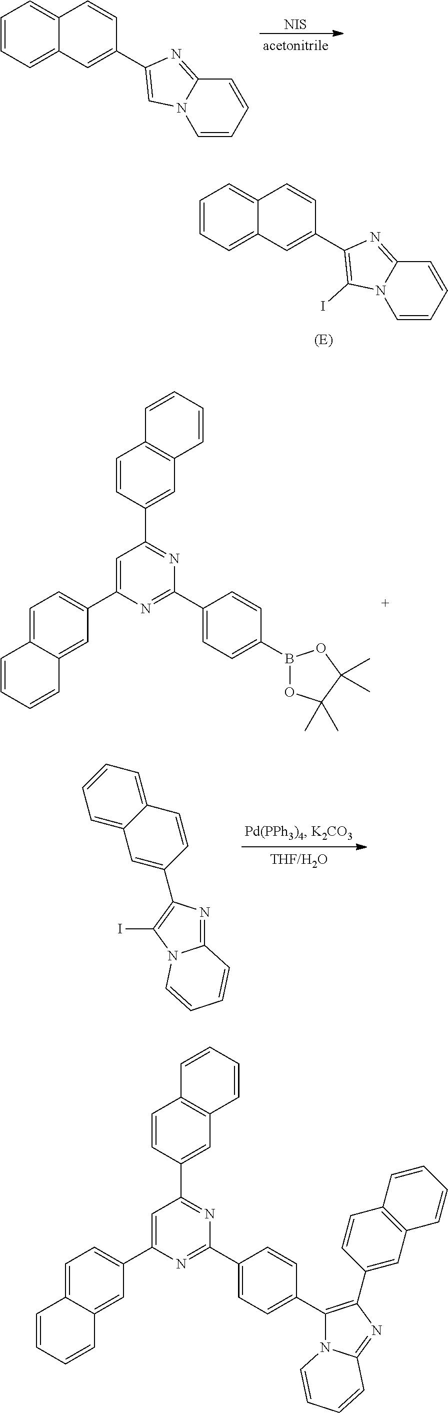

First Step; Synthesis of Intermediate Product (A)

27.3 g (160.1 mmol) of 2′-acetonaphtone, 25 g (160.1 mmol) of 2-naphthaldehyde, and 9.6 g (240.2 mmol) of sodium hydroxide were suspended in 700 mL of ethanol and agitated at room temperature (˜25° C.) for 1 hour. The mixed solid was extracted with chloroform and recrystallized with methanol to provide 49 g (yield: 99%) of an intermediate product A.

Second Step; Synthesis of Intermediate Product (B)

38 g (123.2 mmol) of the intermediate product (A), 34.8 g (147.8 mmol) of 2-bromobenzidine hydrochloride, and 9.9 g (246.4 mmol) of sodium hydroxide were suspended in a mixed solvent of 380 mL of ethanol and 380 mL of tetrahydrofuran and heated and refluxed at 80° C. for 12 hours. After cooling, the deposited solid was separated by a filter and rinsed with methanol to obtain 26.6 g (yield: 44%) of an intermediate product (B).

Third Step: Synthesis of Intermediate Product (C)

25 g (51.3 mmol) of the intermediate product (B), 15.6g (61.6 mmol) of bis(pinacolato)diboron, 1.1 g (1.3 mmol) of [1,1′-bis(diphenylphosphino)ferrocene]dichloropalladium(II), and 15.1 g (153.9 mmol) of potassium acetate were suspended in 600 mL of toluene and agitated at 120° C. for 12 hours. After cooling, the reaction solution was poured in distilled water to deposit a solid, and it was filtered and separated. The filtered solid was recrystallized with ethyl acetate/hexane to provide 18.4 g (yield: 67%) of the intermediate product (C).

Fourth Step; Synthesis of Intermediate Product (D)

31.6 g (126.9 mmol) of 2-bromoacetylnaphthalene and 14.3 g (152.2 mmol) of 2-aminopyridine were suspended in 300 mL of ethanol and agitated at 80° C. for 12 hours. After cooling, ethanol was distilled and residues were separated by a filter, and rinsed with a sodium hydrogen carbonate aqueous solution. The solid was recrystallized with a methanol/water mixed solvent to obtain 32.7 g (yield: 99%) of an intermediate product (D).

Fifth Step; Synthesis of Intermediate Product (E)

31 g (127 mmol) of the intermediate product (D) and 31.4 g (140 mmol) of N-iodosuccinimide (NIS) were suspended in 600 mL of acetonitrile and agitated at 50° C. for 1 hour. After cooling, the mixture was poured into 800 mL of water followed by extraction with methylene chloride and distillation under a reduced pressure. The residues were recrystallized with methanol to provide 17.5 g (yield: 37%) of an intermediate product (E).

Sixth Step: Synthesis of Compound of Chemical Formula A1

4.3 g (11.6 mmol) of the intermediate product (E), 7.4 g (13.9 mmol) of the intermediate product (C), 0.34 g (0.29 mmol) of tetrakis(triphenylphosphine)palladium, and 3.2 g (23.2 mmol) of potassium carbonate were suspended in a mixed solvent of 160 mL of tetrahydrofuran and 80 mL of water, and suspended and agitated at 80° C. for 12 hours. After cooling, the reaction fluid was separated into two layers, and then an organic layer was cleaned with a saturated sodium chloride aqueous solution and dried with anhydrous sodium sulfate. The organic solvent was removed by distillation under a reduced pressure, and the residues were recrystallized with methanol and ethyl acetate to provide 4.94 g (yield: 65%) of a compound. (element analysis/Calcd: C, 86.74; H, 4.65; N, 8.61, Found, C, 86.77; H, 4.63; N, 8.60)

### EXAMPLE 2

### Synthesis of Compound Represented by Chemical Formula B6

The compound represented by Chemical Formula B6 was synthesized through 3 steps as shown in the following Reaction Scheme 2:

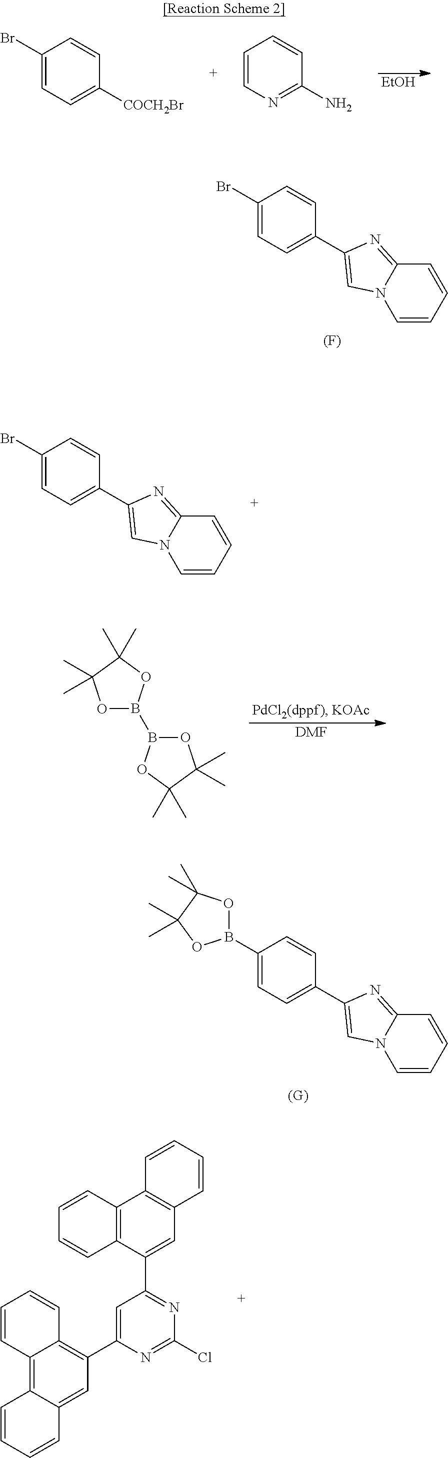

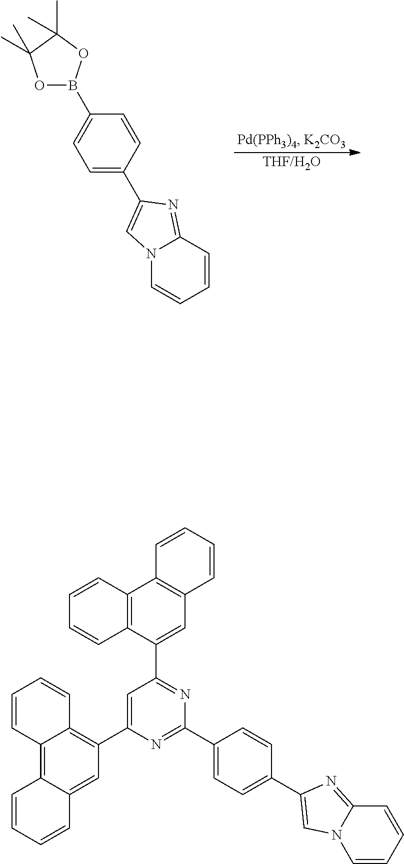 [SMILES: CC1(C)OB(c2ccc(-c3cn4ccccc4n3)cc2)OC1(C)C ; "THF/H2O" ; c1ccc2c(c1)cc(-c1cc(-c3cc4ccccc4c4ccccc34)nc(-c3ccc(-c4cn5ccccc5n4)cc3)n1)c1ccccc12]

First Step; Synthesis of Intermediate Product (F)

50 g (180 mmol) of 4-bromophenacyl bromide and 20.3 g (220 mmol) of 2-aminopyridine were suspended in 300 mL of ethanol and agitated at 80° C. for 12 hours. After cooling, ethanol was distilled and residues were separated by filter, and then resultant was rinsed with a sodium hydrogen carbonate aqueous solution. The solid was recrystallized with a methanol/water mixed solvent to provide 32.7 g (yield: 99%) of an intermediate product (F).

Second Step; Synthesis of Intermediate Product (G)

17 g (62.2 mmol) of the intermediate product (F), 19 g (74.6 mmol) of bis(pinacolato)diboron, 1.5 g (1.6 mmol) of [1,1′-bis(diphenylphosphino)ferrocene]dichloropalladium(II), and 18.3 g (186.6 mmol) of potassium acetate were suspended in 180 mL of dimethylformaldehyde and agitated at 80° C. for 12 hours. After cooling, the reaction solution was poured in distilled water to deposit a solid, and it was filtered and separated. The filtered solid was recrystallized with ethyl acetate/hexane to provide 8.9 g (yield: 44%) of the intermediate product (C).

Third Step: Synthesis of Compound of Chemical Formula B2

10.7 g (23 mmol) of 2-chloro-4-(phenanthren-10-yl)-6-(phenanthren-9-yl)pyrimidine, 8.8 g (27.6 mmol) of the intermediate product (G), 0.66 g (0.58 mmol) of tetrakis(triphenylphosphine)palladium, and 9.5 g (69 mmol) of potassium carbonate were suspended in a mixed solvent of 200 mL of tetrahydrofuran and 100 mL of water and agitated at 80° C. for 12 hours. After cooling, the reaction fluid was separated into two layers, and then an organic layer was cleaned with a saturated sodium chloride aqueous solution and dried with anhydrous sodium sulfate. The organic solvent was removed by distillation under a reduced pressure, and the residues were recrystallized with methanol and ethyl acetate to provide 9.8 g (yield: 68%) of a compound. (element analysis/Calcd: C, 86.51; H, 4.52; N, 8.97, Found, C, 86.56; H, 4.49; N, 8.94)

(Manufacture of Organic Light Emitting Diode)

### EXAMPLE 3

An organic photoelectric device was fabricated using a 1,000 Å-thick ITO layer as an anode and a 1,000 Å-thick aluminum (Al) layer as a cathode.

In particular, the anode was prepared cutting an ITO glass substrate having a sheet resistance of 15 Ω/cm² into a size of 50 mm×50 mm×0.7 mm and cleaning it in acetone, isopropyl alcohol, and pure water, respectively for 5 minutes and with UV ozone for 30 minutes.

Then, N1,N1′-(biphenyl-4,4′-diyl)bis(N1-(naphthalen-2-yl)-N4,N4-diphenylbenzene-1,4-diamine) was deposited to be 65 nm thick as a hole injection layer (HIL) on the glass substrate, and N,N′-di(1-naphthyl)-N,N′-diphenylbenzidine was deposited to be 40 nm thick as a hole transport layer (HTL).

Then, 4% of N,N,N′,N′-tetrakis(3,4-dimethylphenyl)chrysene-6,12-diamine and 96% of 9-(3-(naphthalen-1-yl)phenyl)-10-(naphthalen-2-yl)anthracene were deposited to be 25 nm thick as an emission layer on the hole transport layer (HTL).

Then, the compound according to Example 1 was deposited to be 30 nm thick on the emission layer as an electron transport layer (ETL).

On the electron transport layer (ETL), Liq was vacuum-deposited to be 0.5 nm thick on the electron injection layer (EIL), and Al was vacuum-deposited to be 100 nm thick, forming a Liq/Al electrode.

### EXAMPLE 4

An organic light emitting diode was fabricated in accordance with the same procedure as in Example 3, except that the electron transport layer (ETL) was fabricated by using the compound obtained in Example 2 instead of the compound obtained in Example 1.

### EXAMPLE 5

An organic light emitting diode was fabricated in accordance with the same procedure as in Example 3, except that the electron transport layer (ETL) was fabricated by depositing the compound obtained in Example 1 and Liq at 1:1 (v/v) instead of the compound obtained in Example 1.

### EXAMPLE 6

An organic light emitting diode was fabricated in accordance with the same procedure as in Example 3, except that the electron transport layer (ETL) was fabricated by depositing the compound obtained in Example 2 and Liq at 1:1 (v/v) instead of the compound obtained in Example 1.

### COMPARATIVE EXAMPLE 1

An organic light emitting diode was fabricated in accordance with the same procedure as in Example 3, except that the electron transport layer (ETL) was fabricated by using the compound of the following Chemical Formula ET1 instead of the compound obtained of Chemical Formula A1 in Example 1.

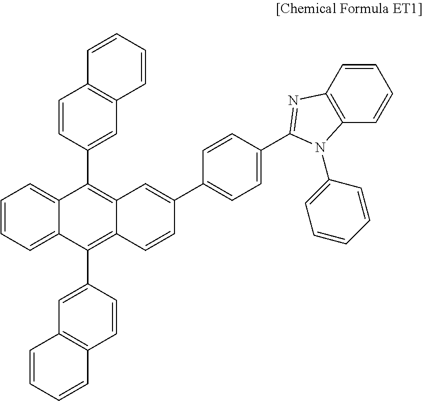 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1]

### COMPARATIVE EXAMPLE 2

An organic light emitting diode was fabricated in accordance with the same procedure as in Example 5, except that the electron transport layer (ETL) was fabricated by using the compound of the above Chemical Formula ET1 (with Liq) instead of the compound obtained of Chemical Formula A1 in Example 1.

(Performance Measurement of Organic Light Emitting Diode)

### EXPERIMENTAL EXAMPLE

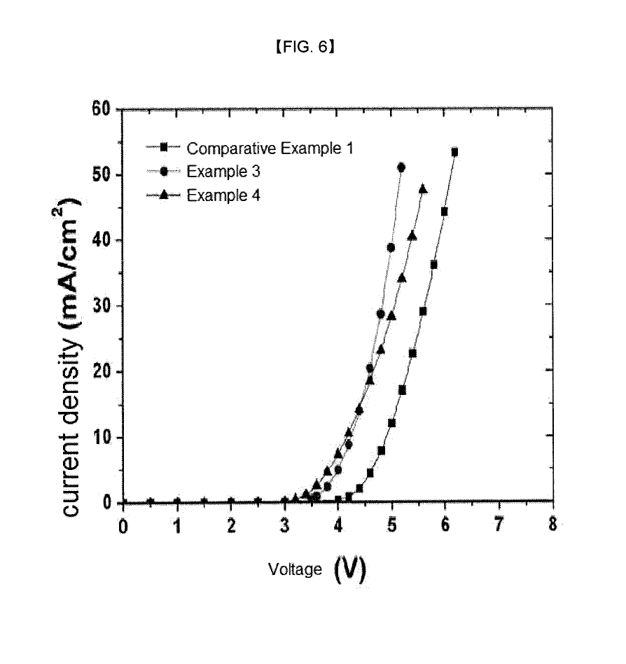

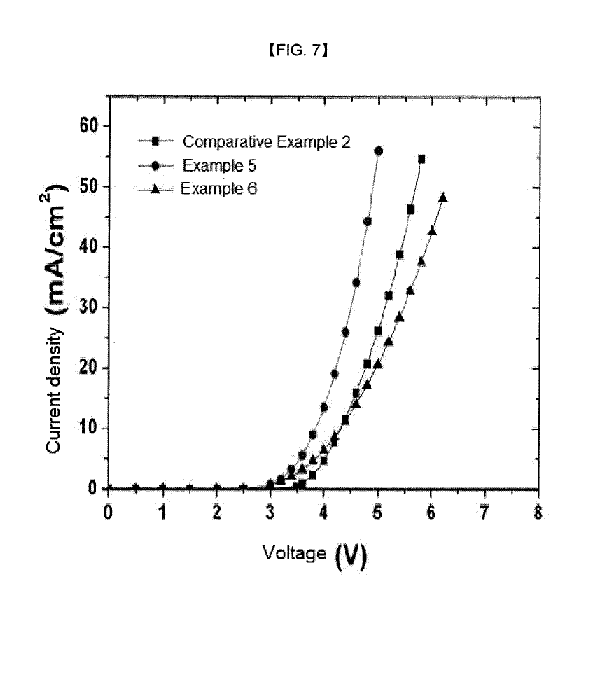

Each of the obtained organic photoelectric devices according to Examples 3, 4, 5, 6, and Comparative Examples 1 and 2 was measured for luminance change, current density change depending upon the voltage, and luminous efficiency. The specific method was as follows. The results are shown in the following Table 1 and in FIGS. 6 to 13.

(1) Measurement of Current Density Change Depending on Voltage Change

The obtained organic light emitting diode was measured for current value flowing in the unit device while increasing the voltage from 0 V to 10 V using a current-voltage meter (Keithley 2400), and the measured current value was divided by area to provide the result.

(2) Measurement of Luminance Change Depending on Voltage Change

The organic light emitting diode was measured for luminance using a luminance meter (Minolta Cs-1000A) while increasing the voltage from 0 V to 10 V.

(3) Measurement of Luminous Efficiency

Current efficiency (cd/A) and electric power efficiency (lm/W) at the same luminance (1,000 cd/m²) were calculated by using luminance and current density from (1) and (2) and voltage.

FIG. 6 illustrates a graph showing changes in current density depending on a voltage of devices according to Examples 3 and 4, and Comparative Example 1.

FIG. 7 illustrates a graph showing changes in current density depending on a voltage of devices according to Examples 5 and 6, and Comparative Example 2.

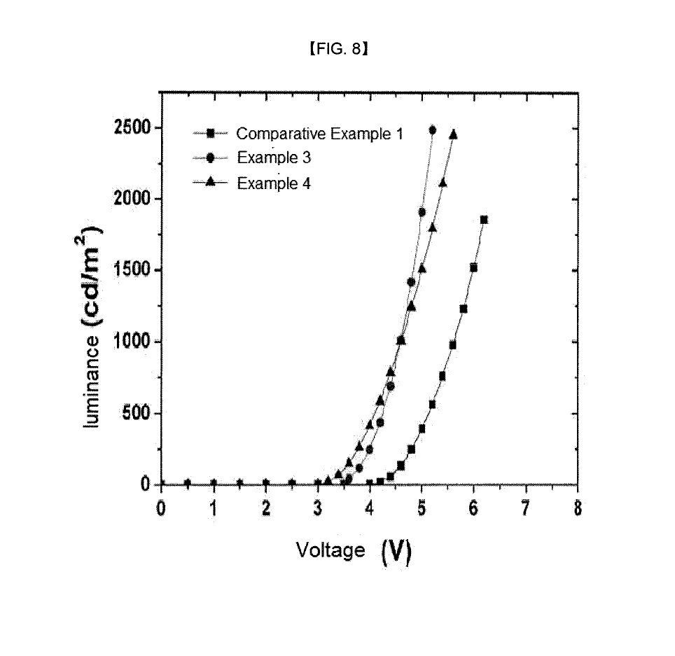

FIG. 8 illustrates a graph showing changes in luminance depending on a voltage of devices according to Examples 3 and 4, and Comparative Example 1.

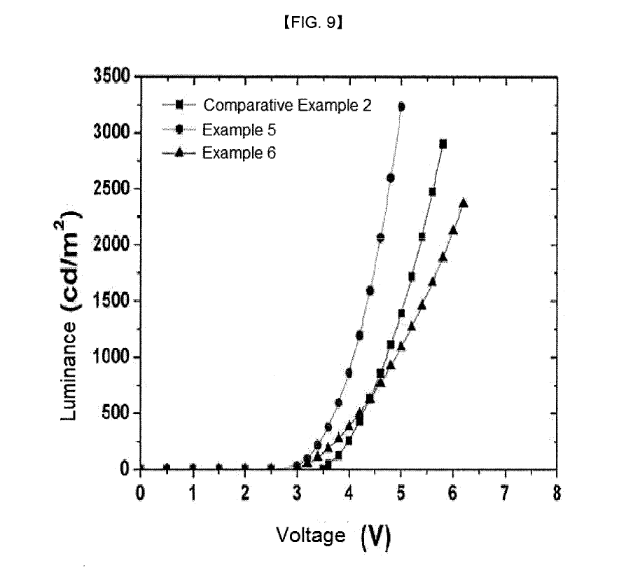

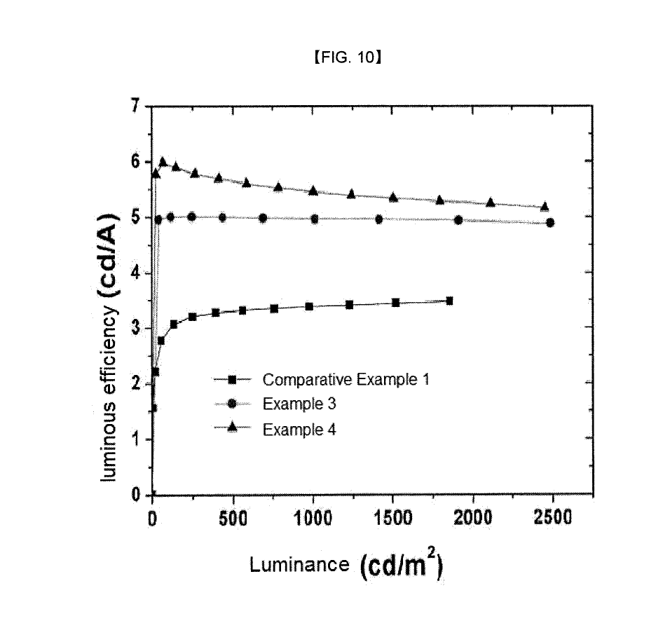

FIG. 9 illustrates a graph showing changes in luminance depending on a voltage of devices according to Examples 5 and 6, and Comparative Example 2.

FIG. 10 illustrates a graph showing changes in luminous efficiency depending on luminance of devices according to Examples 3 and 4, and Comparative Example 1.

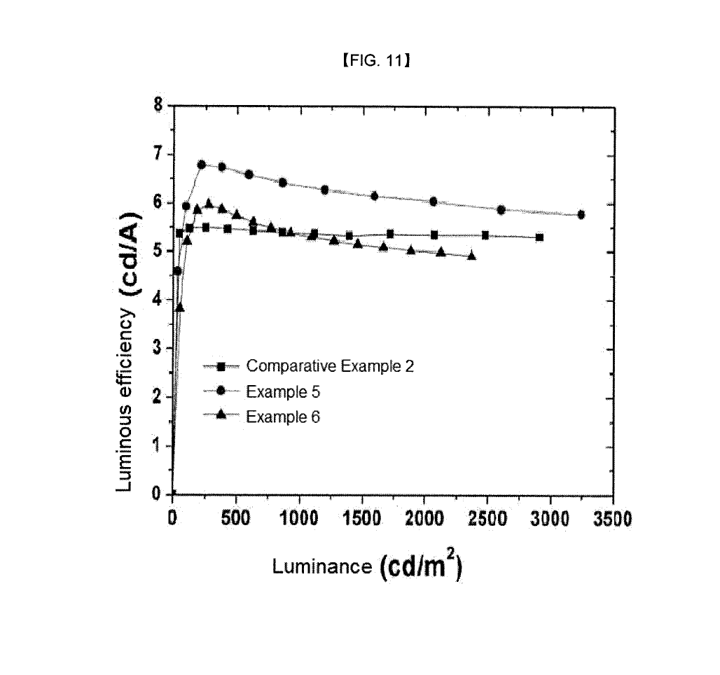

FIG. 11 illustrates a graph showing changes in luminous efficiency depending on luminance of devices according to Examples 5 and 6, and Comparative Example 2.

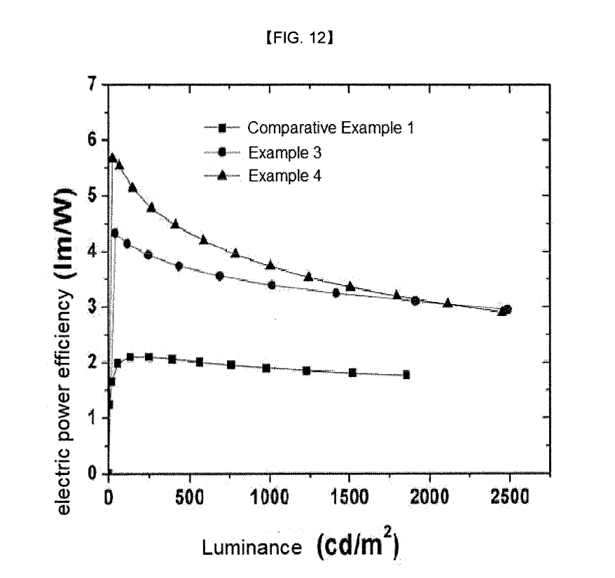

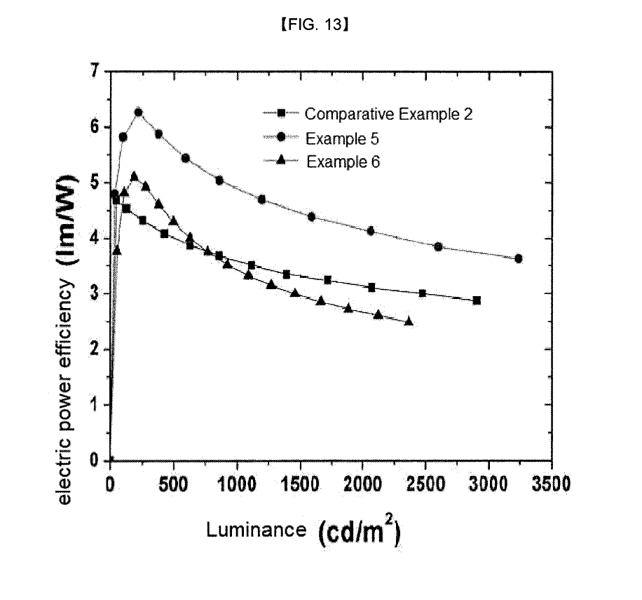

FIG. 12 illustrates a graph showing changes in electric power efficiency depending on luminance of devices according to Examples 3 and 4, and Comparative Example 1.

FIG. 13 illustrates a graph showing changes in electric power efficiency depending on luminance of devices according to Examples 5 and 6, and Comparative Example 2.

TABLE 1

| | Luminance 500 cd/m² | | | | |
|---|---|---|---|---|---|
| | | Luminous | Electric power | | |
| | Driving voltage | efficiency | efficiency | CIE | |
| | (V) | (cd/A) | (lm/W) | x | y |
| Example 3 | 4.4 | 5.0 | 3.6 | 0.14 | 0.05 |
| Example 4 | 4.2 | 5.6 | 4.2 | 0.14 | 0.05 |
| Comparative | 5.2 | 3.3 | 2.0 | 0.14 | 0.05 |
| Example 1 | | | | | |
| Example 5 | 3.8 | 6.6 | 5.4 | 0.14 | 0.04 |
| Example 6 | 4.2 | 5.7 | 4.3 | 0.14 | 0.05 |
| Comparative | 4.4 | 5.4 | 3.9 | 0.14 | 0.06 |
| Example 2 | | | | | |

As may be seen in Table 1, the organic light emitting diodes according to Examples 3 and 4 exhibited excellent luminous efficiency and electric power efficiency with a low driving voltage, compared to that of Comparative Example 1.

It may also be seen that the organic light emitting diode according to Examples 5 and 6 exhibited excellent luminous efficiency and electric power efficiency with a low driving voltage, compared to that of Comparative Example 2.

By way of summation and review, an organic light emitting diode (OLED) has recently drawn attention due to an increasing demand for a flat panel display. In general, organic light emission refers to conversion of electrical energy into photo-energy.

Such an organic light emitting diode may convert electrical energy into light by applying current to an organic light emitting material. It may have a structure in which a functional organic material layer is interposed between an anode and a cathode. The organic material layer may include a multi-layer including different materials, e.g., a hole injection layer (HIL), a hole transport layer (HTL), an emission layer, an electron transport layer (ETL), and an electron injection layer (EIL), in order to help improve efficiency and stability of an organic photoelectric device.

In such an organic light emitting diode, when a voltage is applied between an anode and a cathode, holes from the anode and electrons from the cathode may be injected to the organic material layer and recombined to generate excitons having high energy. The generated excitons may generate light having certain wavelengths while shifting to a ground state.

A phosphorescent light emitting material may be used for a light emitting material of an organic light emitting diode, in addition to the fluorescent light emitting material. Such a phosphorescent material may emit light by transporting the electrons from a ground state to an exited state, non-radiance transiting of a singlet exciton to a triplet exciton through intersystem crossing, and transiting a triplet exciton to a ground state to emit light.

As described above, in an organic light emitting diode, an organic material layer may include a light emitting material and a charge transport material, e.g., a hole injection material, a hole transport material, an electron transport material, an electron injection material, and the like.

The light emitting material may be classified as blue, green, and red light emitting materials according to emitted colors, and yellow and orange light emitting materials to emit colors approaching natural colors.

When one material is used as a light emitting material, a maximum light emitting wavelength may be shifted to a long wavelength or color purity may decrease because of interactions between molecules, or device efficiency may decrease because of a light emitting quenching effect. Therefore, a host/dopant system may be included as a light emitting material in order to help improve color purity and to help increase luminous efficiency and stability through energy transfer.

In order to implement excellent performance of an organic light emitting diode, a material constituting an organic material layer, e.g., a hole injection material, a hole transport material, a light emitting material, an electron transport material, an electron injection material, and/or a light emitting material such as a host and/or a dopant, should be stable and have good efficiency. In addition, the material may be useful for other organic photoelectric devices.

A low molecular weight organic light emitting diode may be manufactured as a thin film in a vacuum deposition method and may have good efficiency and life-span performance. A polymer organic light emitting diode may be manufactured using an Inkjet or spin coating method, and may have an advantage of low initial cost and being large-sized.

Both low molecular weight organic light emitting and polymer organic light emitting diodes may have an advantage of being self-light emitting, having high speed response, wide viewing angle, ultra-thin, high image quality, durability, large driving temperature range, and the like. For example, they may have good visibility due to self-light emitting characteristics, compared with a LCD (liquid crystal display), and may have an advantage of decreasing thickness and weight of LCD up to a third, because a backlight is not required.

In addition, since they may have a response speed of a microsecond unit, which is 1,000 time faster than an LCD, they may realize a perfect motion picture without after-image. Based on these advantages, they have been remarkably developed to have 80 times efficiency and more than 100 times life-span since their initial introduction. Recently, they keep being rapidly larger such as a 40-inch organic light emitting diode panel.

Simultaneously exhibiting improved luminous efficiency and life-span in order to be larger may be particularly desirable. For example, luminous efficiency may require smooth combination between holes and electrons in an emission layer. However, an organic material in general may have slower electron mobility than hole mobility. Thus, it may exhibit an inefficient combination between holes and electrons. Accordingly, it may be desirable to increase electron injection and mobility from a cathode while simultaneously preventing movement of holes.

In order to improve life-span, a material crystallization caused by Joule heating generated during device operating should be prevented. Accordingly, the embodiments provide an organic compound having excellent electron injection and mobility, and high electrochemical stability.

The embodiments provide a compound for an organic optoelectronic device that may act as light emitting, or electron injection and/or transport material, and also act as a light emitting host along with an appropriate dopant is provided.

The embodiments provide an organic optoelectronic device having excellent life-span, efficiency, driving voltage, electrochemical stability, and thermal stability.

An organic optoelectronic device having excellent electrochemical and thermal stability and life-span characteristics, and high luminous efficiency at a low driving voltage may be provided.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A compound for an organic optoelectronic device, the compound being represented by the following Chemical Formula 1: 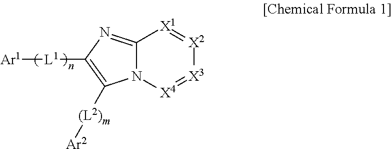
wherein, in Chemical Formula 1,
X¹ to X⁴ are each independently —N—, —CR¹—, —CR²—, —CR³— or —CR⁴—,
R¹ to R⁴ are each independently hydrogen, deuterium, a substituted or unsubstituted C1 to C20 alkyl group, a substituted or unsubstituted C6 to C30 aryl group, a substituted or unsubstituted C3 to C30 heteroaryl group, or a combination thereof,
L¹ and L² are each independently a single bond, a substituted or unsubstituted C2 to C6 alkenyl group, a substituted or unsubstituted C2 to C6 alkynyl group, a substituted or unsubstituted C6 to C30 arylene group, a substituted or unsubstituted C3 to C30 heteroarylene group, or a combination thereof,
n and m are each independently 1 or 2,
Ar¹ and Ar² are each independently hydrogen, deuterium, a substituted or unsubstituted C1 to C20 alkyl group, a substituted or unsubstituted C6 to C30 aryl group, a substituted or unsubstituted C3 to C30 heteroaryl group, or a combination thereof, and
at least one of Ar¹ or Ar² is a substituted or unsubstituted C3 to C30 heteroaryl group having electronic properties.

2. The compound for an organic optoelectronic device as claimed in claim 1, wherein the compound is represented by the following Chemical Formula 2: 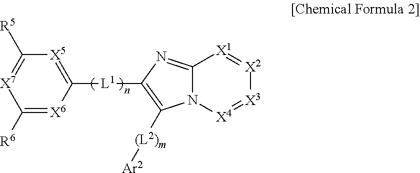
wherein, in Chemical Formula 2,
X¹ to X⁴ are each independently —N—, —CR¹—, —CR²—, —CR³— or —CR⁴—,
R¹ to R⁶ are each independently hydrogen, deuterium, a substituted or unsubstituted C1 to C20 alkyl group, a substituted or unsubstituted C6 to C30 aryl group, a substituted or unsubstituted C3 to C30 heteroaryl group, or a combination thereof,
L¹ and L² are each independently a single bond, a substituted or unsubstituted C2 to C6 alkenyl group, a substituted or unsubstituted C2 to C6 alkynyl group, a substituted or unsubstituted C6 to C30 arylene group, a substituted or unsubstituted C3 to C30 heteroarylene group, or a combination thereof,
n and m are each independently 1 or 2,
Ar² is hydrogen, deuterium, a substituted or unsubstituted C1 to C20 alkyl group, a substituted or unsubstituted C6 to C30 aryl group, a substituted or unsubstituted C3 to C30 heteroaryl group, or a combination thereof,
X⁵ to X⁷ are each independently —N— or —CR′—, wherein R′ is hydrogen or deuterium, and at least one of X⁵ to X⁷ is —N—.

3. The compound for an organic optoelectronic device as claimed in claim 2, wherein Ar² is a substituted or unsubstituted naphthyl group, a substituted or unsubstituted anthracenyl group, a substituted or unsubstituted phenanthrenyl group, a substituted or unsubstituted triphenylenyl group, a substituted or unsubstituted pyrenyl group, a substituted or unsubstituted chrysenyl group, or a combination thereof.

4. The compound for an organic optoelectronic device as claimed in claim 1, wherein the compound is represented by the following Chemical Formula 3: 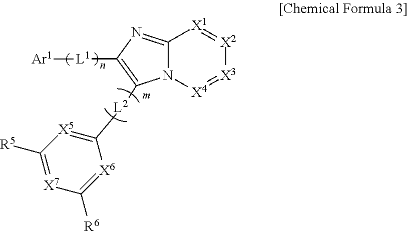
wherein, in Chemical Formula 3,
X¹ to X⁴ are each independently —N—, —CR¹—, —CR²—, —CR³— or —CR⁴—,
R¹ to R⁶ are each independently hydrogen, deuterium, a substituted or unsubstituted C1 to C20 alkyl group, a substituted or unsubstituted C6 to C30 aryl group, a substituted or unsubstituted C3 to C30 heteroaryl group, or a combination thereof,
L¹ and L² are each independently a single bond, a substituted or unsubstituted C2 to C6 alkenyl group, a substituted or unsubstituted C2 to C6 alkynyl group, a substituted or unsubstituted C6 to C30 arylene group, a substituted or unsubstituted C3 to C30 heteroarylene group, or a combination thereof,
n and m are each independently 1 or 2,
Ar¹ is hydrogen, deuterium, a substituted or unsubstituted C1 to C20 alkyl group, a substituted or unsubstituted C6 to C30 aryl group, a substituted or unsubstituted C3 to C30 heteroaryl group, or a combination thereof,
X⁵ to X⁷ are each independently —N— or —CR′—, wherein R′ is hydrogen or deuterium, and at least one of X⁵ to X⁷ is —N—.

5. The compound for an organic optoelectronic device as claimed in claim 3, wherein Ar¹ is a substituted or unsubstituted naphthyl group, a substituted or unsubstituted anthracenyl group, a substituted or unsubstituted phenanthrenyl group, a substituted or unsubstituted triphenylenyl group, a substituted or unsubstituted pyrenyl group, a substituted or unsubstituted chrysenyl group, or a combination thereof.

6. The compound for an organic optoelectronic device as claimed in claim 1, wherein the substituted or unsubstituted C3 to C30 heteroaryl group having the electronic properties is a substituted or unsubstituted imidazolyl group, a substituted or unsubstituted triazolyl group, a substituted or unsubstituted tetrazolyl group, a substituted or unsubstituted carbazolyl group, a substituted or unsubstituted oxadiazolyl group, a substituted or unsubstituted oxatriazolyl group, a substituted or unsubstituted thiatriazolyl group, a substituted or unsubstituted benzimidazolyl group, a substituted or unsubstituted benzotriazolyl group, a substituted or unsubstituted pyridinyl group, a substituted or unsubstituted pyrimidinyl group, a substituted or unsubstituted triazinyl group, a substituted or unsubstituted pyrazinyl group, a substituted or unsubstituted pyridazinyl group, a substituted or unsubstituted purinyl group, a substituted or unsubstituted quinolinyl group, a substituted or unsubstituted isoquinolinyl group, a substituted or unsubstituted phthalazinyl group, a substituted or unsubstituted naphpyridinyl group, a substituted or unsubstituted quinoxalinyl group, a substituted or unsubstituted quinazolinyl group, a substituted or unsubstituted acridinyl group, a substituted or unsubstituted phenanthrolinyl group, a substituted or unsubstituted phenazinyl group, or a combination thereof.

7. The compound for an organic optoelectronic device as claimed in claim 1, wherein the compound is represented by one of the following Chemical Formulae A1 to A63:

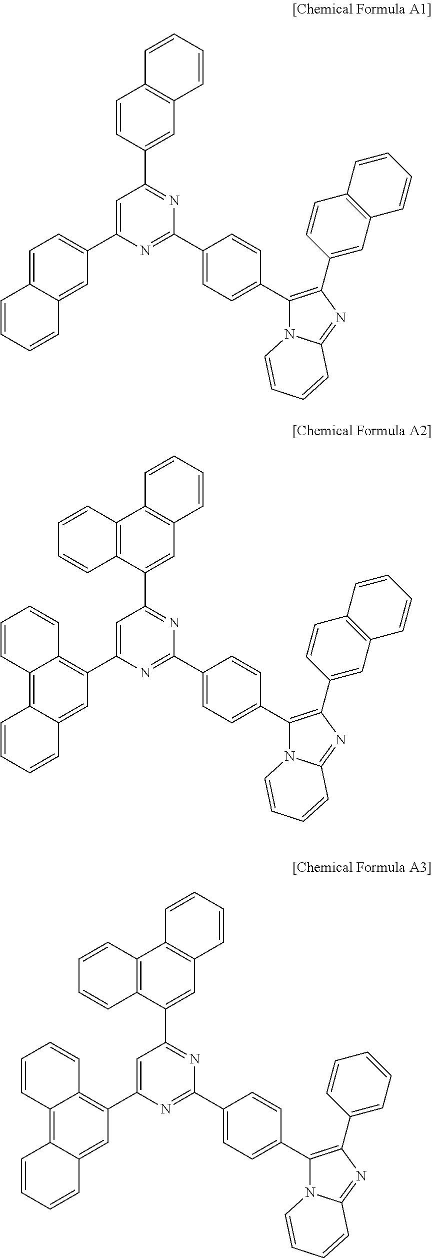 [SMILES: c1ccc2cc(-c3cc(-c4ccc5ccccc5c4)nc(-c4ccc(-c5c(-c6ccc7ccccc7c6)nc6ccccn56)cc4)n3)ccc2c1 ; c1ccc2cc(-c3nc4ccccn4c3-c3ccc(-c4nc(-c5cc6ccccc6c6ccccc56)cc(-c5cc6ccccc6c6ccccc56)n4)cc3)ccc2c1 ; c1ccc(-c2nc3ccccn3c2-c2ccc(-c3nc(-c4cc5ccccc5c5ccccc45)cc(-c4cc5ccccc5c5ccccc45)n3)cc2)cc1]

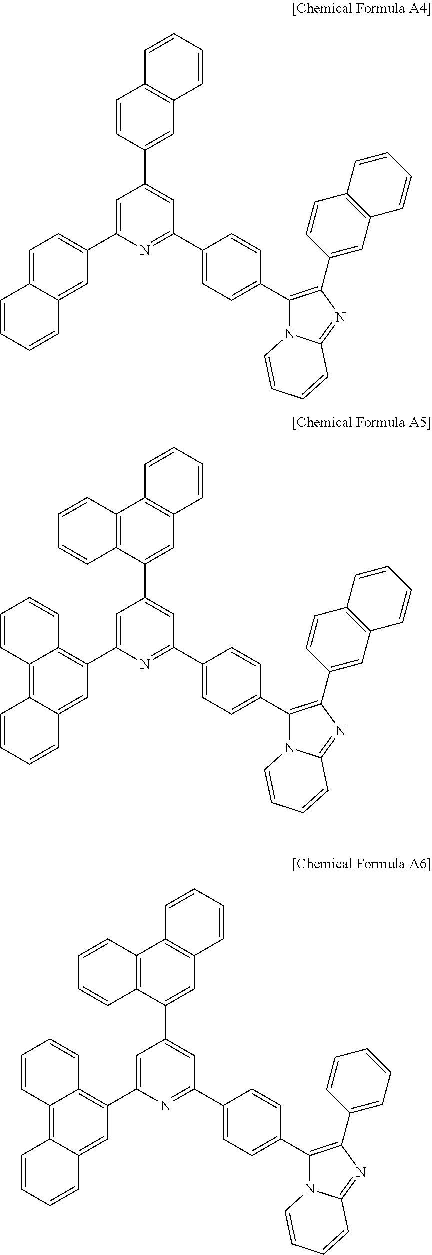 [SMILES: c1ccc2cc(-c3cc(-c4ccc(-c5c(-c6ccc7ccccc7c6)nc6ccccn56)cc4)nc(-c4ccc5ccccc5c4)c3)ccc2c1 ; c1ccc2cc(-c3nc4ccccn4c3-c3ccc(-c4cc(-c5cc6ccccc6c6ccccc56)cc(-c5cc6ccccc6c6ccccc56)n4)cc3)ccc2c1 ; c1ccc(-c2nc3ccccn3c2-c2ccc(-c3cc(-c4cc5ccccc5c5ccccc45)cc(-c4cc5ccccc5c5ccccc45)n3)cc2)cc1]

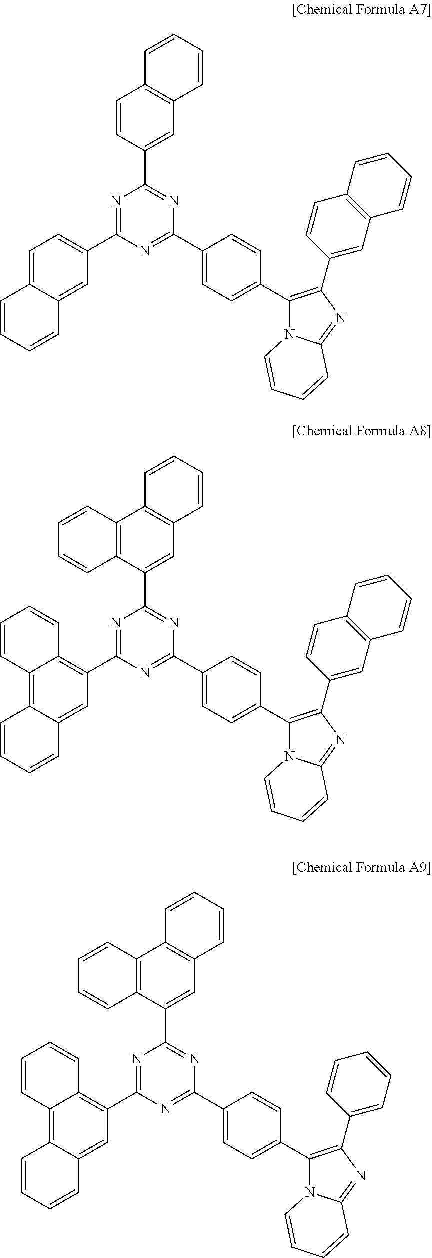 [SMILES: c1ccc2cc(-c3nc(-c4ccc(-c5c(-c6ccc7ccccc7c6)nc6ccccn56)cc4)nc(-c4ccc5ccccc5c4)n3)ccc2c1 ; c1ccc2cc(-c3nc4ccccn4c3-c3ccc(-c4nc(-c5cc6ccccc6c6ccccc56)nc(-c5cc6ccccc6c6ccccc56)n4)cc3)ccc2c1 ; c1ccc(-c2nc3ccccn3c2-c2ccc(-c3nc(-c4cc5ccccc5c5ccccc45)nc(-c4cc5ccccc5c5ccccc45)n3)cc2)cc1]

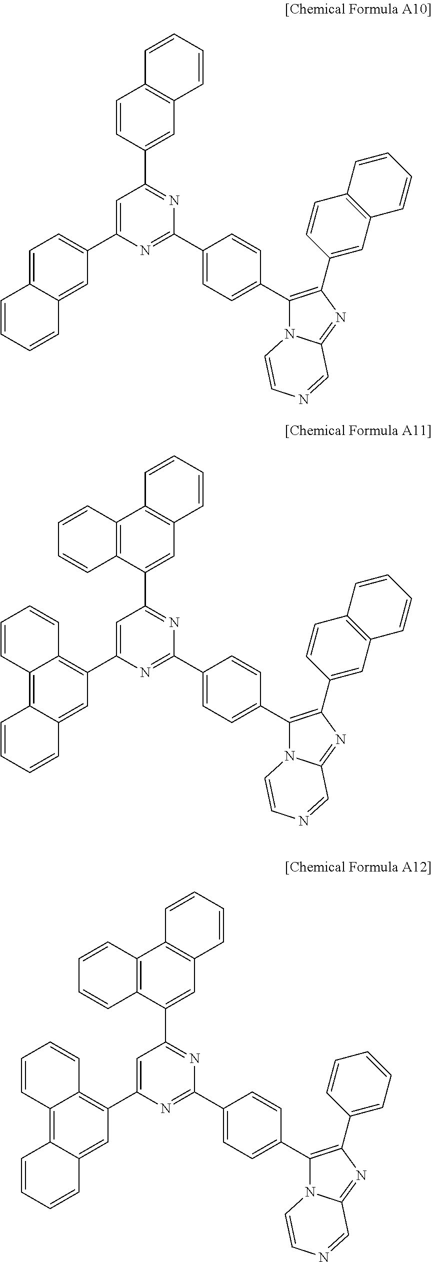 [SMILES: c1ccc2cc(-c3cc(-c4ccc5ccccc5c4)nc(-c4ccc(-c5c(-c6ccc7ccccc7c6)nc6cnccn56)cc4)n3)ccc2c1 ; c1ccc2cc(-c3nc4cnccn4c3-c3ccc(-c4nc(-c5cc6ccccc6c6ccccc56)cc(-c5cc6ccccc6c6ccccc56)n4)cc3)ccc2c1 ; c1ccc(-c2nc3cnccn3c2-c2ccc(-c3nc(-c4cc5ccccc5c5ccccc45)cc(-c4cc5ccccc5c5ccccc45)n3)cc2)cc1]

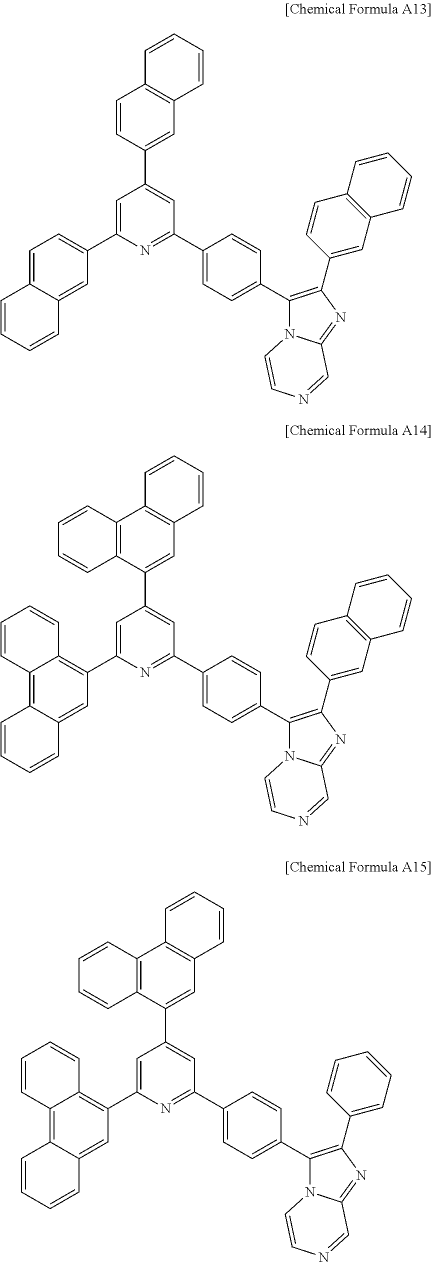 [SMILES: c1ccc2cc(-c3cc(-c4ccc(-c5c(-c6ccc7ccccc7c6)nc6cnccn56)cc4)nc(-c4ccc5ccccc5c4)c3)ccc2c1 ; c1ccc2cc(-c3nc4cnccn4c3-c3ccc(-c4cc(-c5cc6ccccc6c6ccccc56)cc(-c5cc6ccccc6c6ccccc56)n4)cc3)ccc2c1 ; c1ccc(-c2nc3cnccn3c2-c2ccc(-c3cc(-c4cc5ccccc5c5ccccc45)cc(-c4cc5ccccc5c5ccccc45)n3)cc2)cc1]

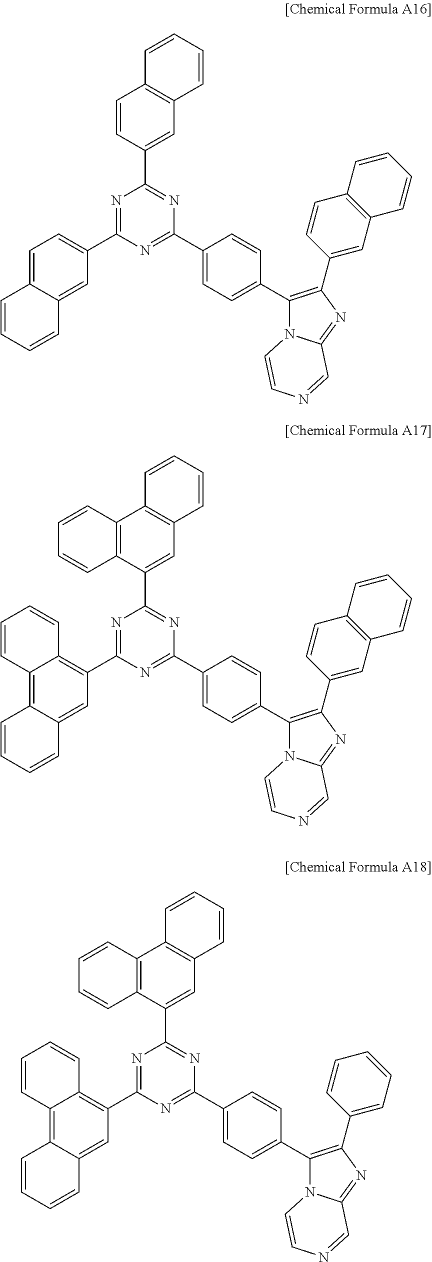 [SMILES: c1ccc2cc(-c3nc(-c4ccc(-c5c(-c6ccc7ccccc7c6)nc6cnccn56)cc4)nc(-c4ccc5ccccc5c4)n3)ccc2c1 ; c1ccc2cc(-c3nc4cnccn4c3-c3ccc(-c4nc(-c5cc6ccccc6c6ccccc56)nc(-c5cc6ccccc6c6ccccc56)n4)cc3)ccc2c1 ; c1ccc(-c2nc3cnccn3c2-c2ccc(-c3nc(-c4cc5ccccc5c5ccccc45)nc(-c4cc5ccccc5c5ccccc45)n3)cc2)cc1]

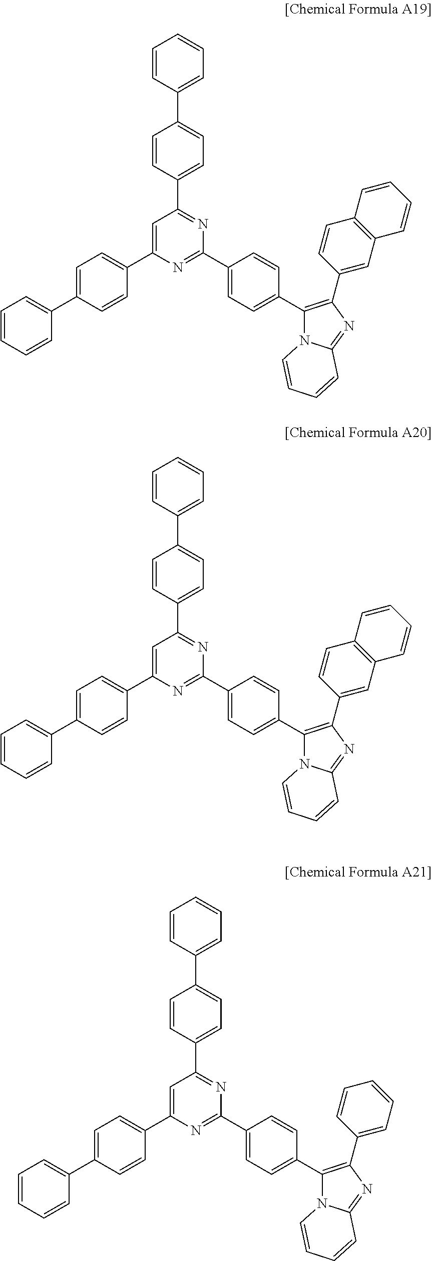 [SMILES: c1ccc(-c2ccc(-c3cc(-c4ccc(-c5ccccc5)cc4)nc(-c4ccc(-c5c(-c6ccc7ccccc7c6)nc6ccccn56)cc4)n3)cc2)cc1 ; c1ccc(-c2ccc(-c3cc(-c4ccc(-c5ccccc5)cc4)nc(-c4ccc(-c5c(-c6ccc7ccccc7c6)nc6ccccn56)cc4)n3)cc2)cc1 ; c1ccc(-c2ccc(-c3cc(-c4ccc(-c5ccccc5)cc4)nc(-c4ccc(-c5c(-c6ccccc6)nc6ccccn56)cc4)n3)cc2)cc1]

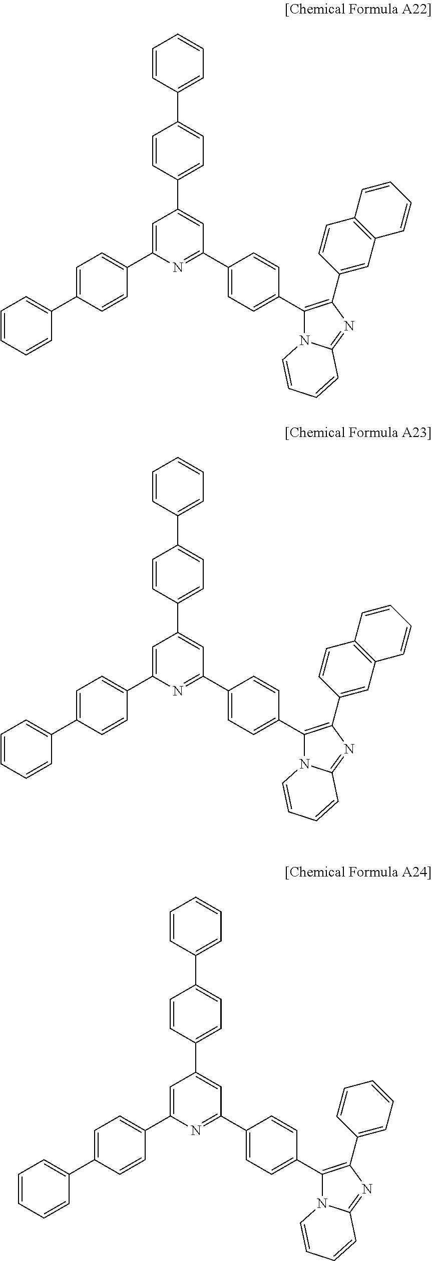 [SMILES: c1ccc(-c2ccc(-c3cc(-c4ccc(-c5ccccc5)cc4)nc(-c4ccc(-c5c(-c6ccc7ccccc7c6)nc6ccccn56)cc4)c3)cc2)cc1 ; c1ccc(-c2ccc(-c3cc(-c4ccc(-c5ccccc5)cc4)nc(-c4ccc(-c5c(-c6ccc7ccccc7c6)nc6ccccn56)cc4)c3)cc2)cc1 ; c1ccc(-c2ccc(-c3cc(-c4ccc(-c5ccccc5)cc4)nc(-c4ccc(-c5c(-c6ccccc6)nc6ccccn56)cc4)c3)cc2)cc1]

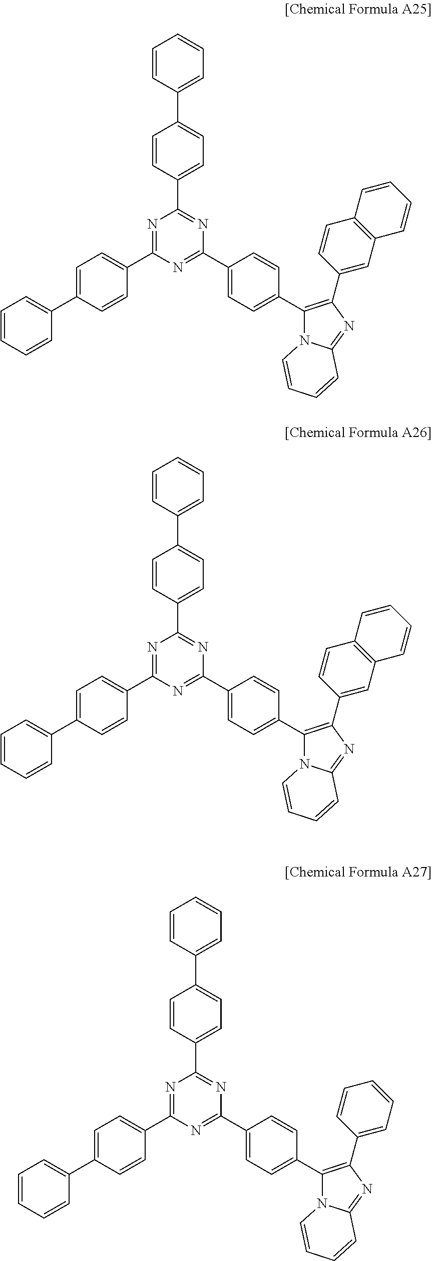 [SMILES: c1ccc(-c2ccc(-c3nc(-c4ccc(-c5ccccc5)cc4)nc(-c4ccc(-c5c(-c6ccc7ccccc7c6)nc6ccccn56)cc4)n3)cc2)cc1 ; c1ccc(-c2ccc(-c3nc(-c4ccc(-c5ccccc5)cc4)nc(-c4ccc(-c5c(-c6ccc7ccccc7c6)nc6ccccn56)cc4)n3)cc2)cc1 ; c1ccc(-c2ccc(-c3nc(-c4ccc(-c5ccccc5)cc4)nc(-c4ccc(-c5c(-c6ccccc6)nc6ccccn56)cc4)n3)cc2)cc1]

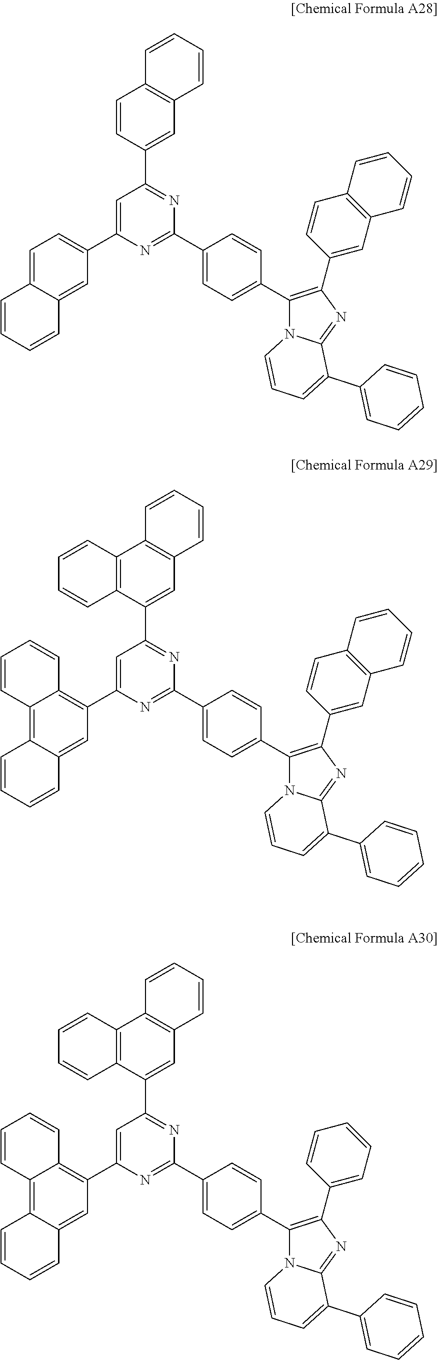 [SMILES: c1ccc(-c2cccn3c(-c4ccc(-c5nc(-c6ccc7ccccc7c6)cc(-c6ccc7ccccc7c6)n5)cc4)c(-c4ccc5ccccc5c4)nc23)cc1 ; c1ccc(-c2cccn3c(-c4ccc(-c5nc(-c6cc7ccccc7c7ccccc67)cc(-c6cc7ccccc7c7ccccc67)n5)cc4)c(-c4ccc5ccccc5c4)nc23)cc1 ; c1ccc(-c2nc3c(-c4ccccc4)cccn3c2-c2ccc(-c3nc(-c4cc5ccccc5c5ccccc45)cc(-c4cc5ccccc5c5ccccc45)n3)cc2)cc1]

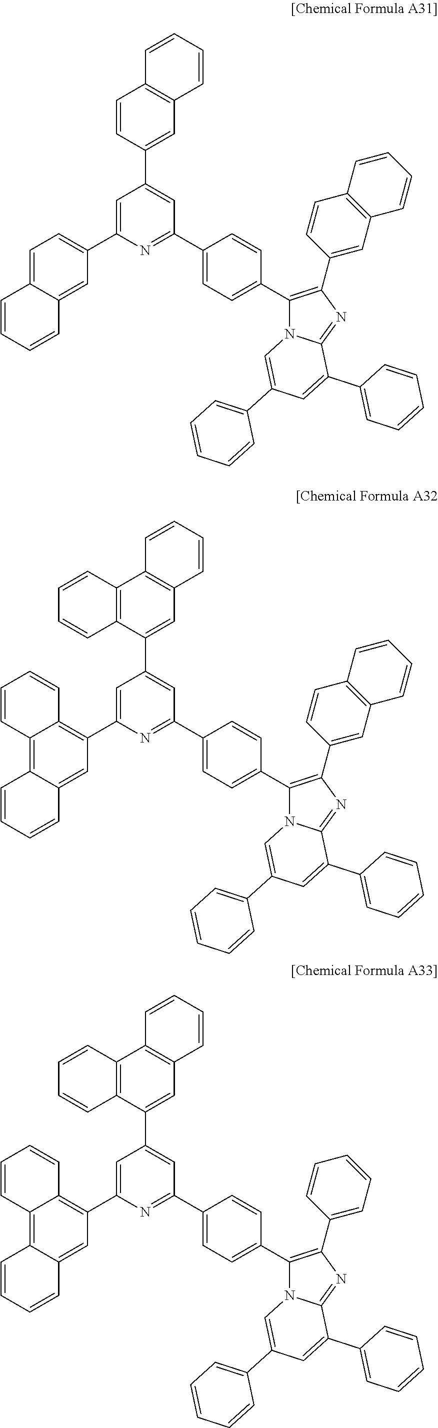 [SMILES: c1ccc(-c2cc(-c3ccccc3)c3nc(-c4ccc5ccccc5c4)c(-c4ccc(-c5cc(-c6ccc7ccccc7c6)cc(-c6ccc7ccccc7c6)n5)cc4)n3c2)cc1 ; c1ccc(-c2cc(-c3ccccc3)c3nc(-c4ccc5ccccc5c4)c(-c4ccc(-c5cc(-c6cc7ccccc7c7ccccc67)cc(-c6cc7ccccc7c7ccccc67)n5)cc4)n3c2)cc1 ; c1ccc(-c2cc(-c3ccccc3)c3nc(-c4ccccc4)c(-c4ccc(-c5cc(-c6cc7ccccc7c7ccccc67)cc(-c6cc7ccccc7c7ccccc67)n5)cc4)n3c2)cc1]

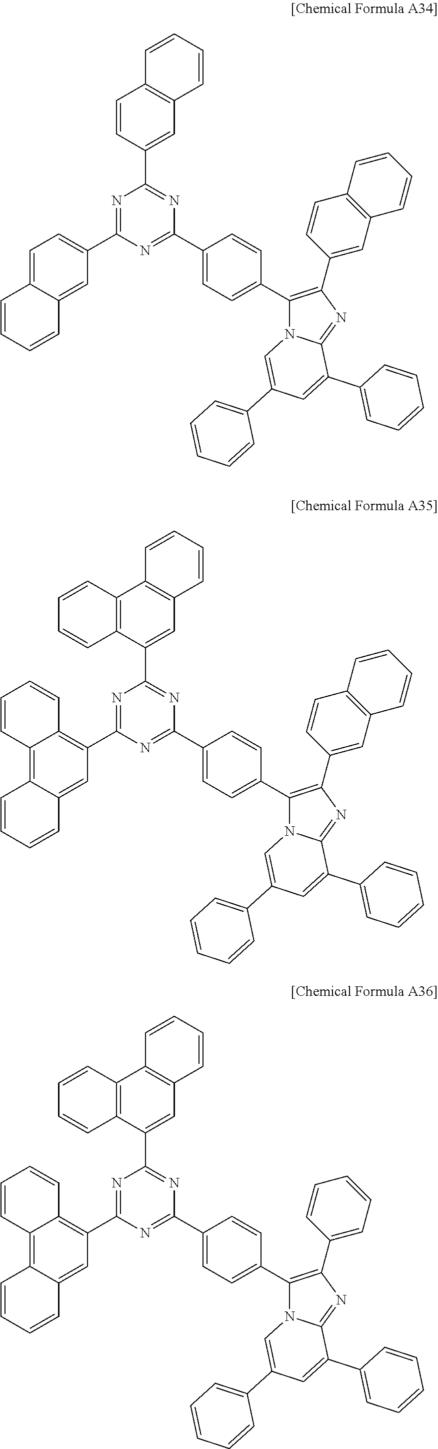 [SMILES: c1ccc(-c2cc(-c3ccccc3)c3nc(-c4ccc5ccccc5c4)c(-c4ccc(-c5nc(-c6ccc7ccccc7c6)nc(-c6ccc7ccccc7c6)n5)cc4)n3c2)cc1 ; c1ccc(-c2cc(-c3ccccc3)c3nc(-c4ccc5ccccc5c4)c(-c4ccc(-c5nc(-c6cc7ccccc7c7ccccc67)nc(-c6cc7ccccc7c7ccccc67)n5)cc4)n3c2)cc1 ; c1ccc(-c2cc(-c3ccccc3)c3nc(-c4ccccc4)c(-c4ccc(-c5nc(-c6cc7ccccc7c7ccccc67)nc(-c6cc7ccccc7c7ccccc67)n5)cc4)n3c2)cc1]

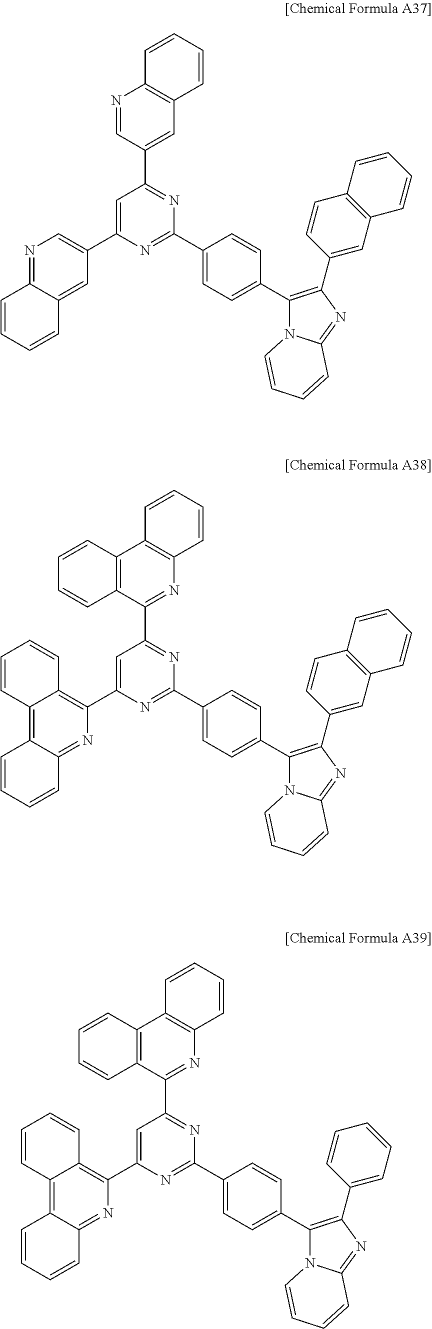 [SMILES: c1ccc2cc(-c3nc4ccccn4c3-c3ccc(-c4nc(-c5cnc6ccccc6c5)cc(-c5cnc6ccccc6c5)n4)cc3)ccc2c1 ; c1ccc2cc(-c3nc4ccccn4c3-c3ccc(-c4nc(-c5nc6ccccc6c6ccccc56)cc(-c5nc6ccccc6c6ccccc56)n4)cc3)ccc2c1 ; c1ccc(-c2nc3ccccn3c2-c2ccc(-c3nc(-c4nc5ccccc5c5ccccc45)cc(-c4nc5ccccc5c5ccccc45)n3)cc2)cc1]

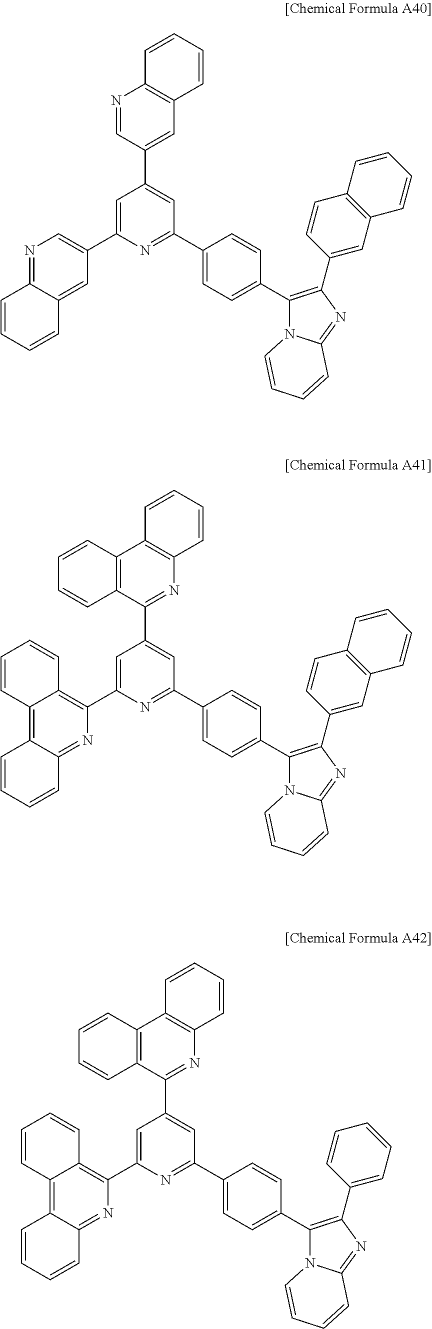 [SMILES: c1ccc2cc(-c3nc4ccccn4c3-c3ccc(-c4cc(-c5cnc6ccccc6c5)cc(-c5cnc6ccccc6c5)n4)cc3)ccc2c1 ; c1ccc2cc(-c3nc4ccccn4c3-c3ccc(-c4cc(-c5nc6ccccc6c6ccccc56)cc(-c5nc6ccccc6c6ccccc56)n4)cc3)ccc2c1 ; c1ccc(-c2nc3ccccn3c2-c2ccc(-c3cc(-c4nc5ccccc5c5ccccc45)cc(-c4nc5ccccc5c5ccccc45)n3)cc2)cc1]

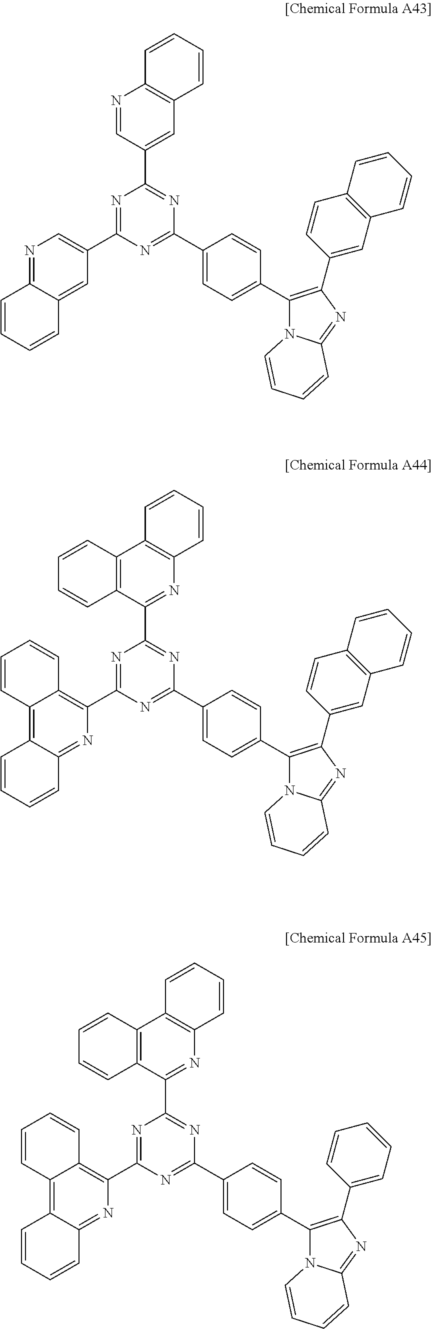 [SMILES: c1ccc2cc(-c3nc4ccccn4c3-c3ccc(-c4nc(-c5cnc6ccccc6c5)nc(-c5cnc6ccccc6c5)n4)cc3)ccc2c1 ; c1ccc2cc(-c3nc4ccccn4c3-c3ccc(-c4nc(-c5nc6ccccc6c6ccccc56)nc(-c5nc6ccccc6c6ccccc56)n4)cc3)ccc2c1 ; c1ccc(-c2nc3ccccn3c2-c2ccc(-c3nc(-c4nc5ccccc5c5ccccc45)nc(-c4nc5ccccc5c5ccccc45)n3)cc2)cc1]

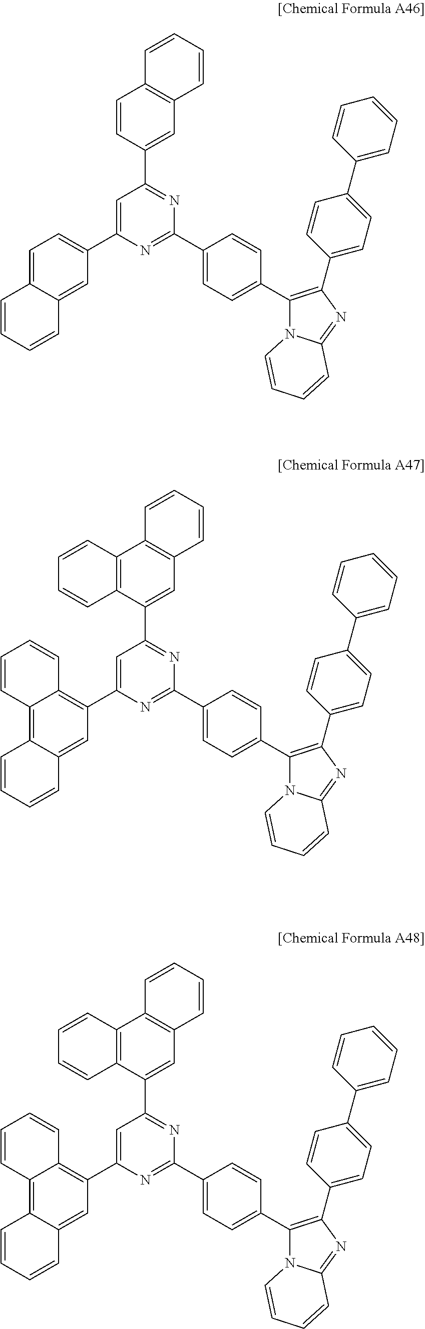 [SMILES: c1ccc(-c2ccc(-c3nc4ccccn4c3-c3ccc(-c4nc(-c5ccc6ccccc6c5)cc(-c5ccc6ccccc6c5)n4)cc3)cc2)cc1 ; c1ccc(-c2ccc(-c3nc4ccccn4c3-c3ccc(-c4nc(-c5cc6ccccc6c6ccccc56)cc(-c5cc6ccccc6c6ccccc56)n4)cc3)cc2)cc1 ; c1ccc(-c2ccc(-c3nc4ccccn4c3-c3ccc(-c4nc(-c5cc6ccccc6c6ccccc56)cc(-c5cc6ccccc6c6ccccc56)n4)cc3)cc2)cc1]

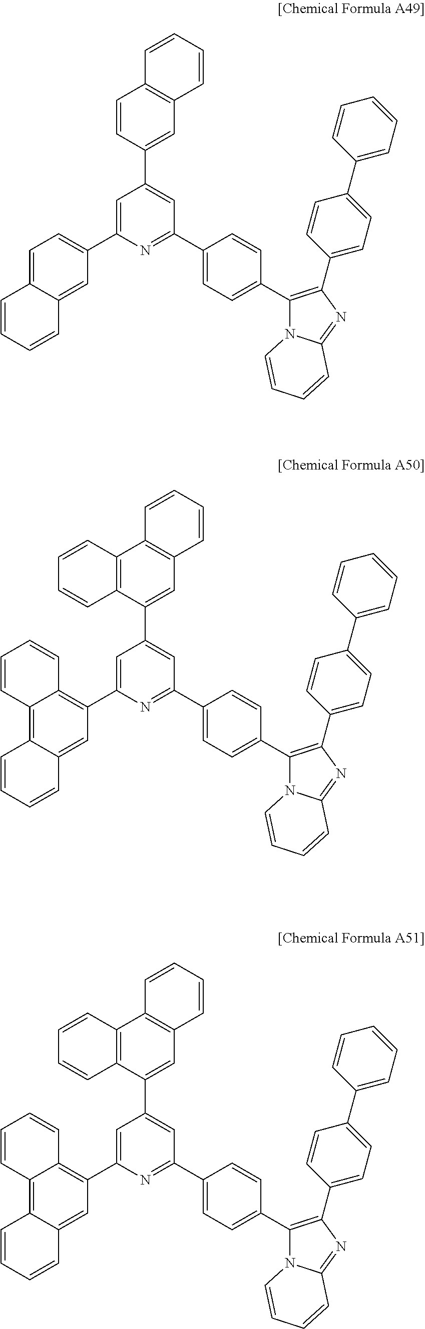 [SMILES: c1ccc(-c2ccc(-c3nc4ccccn4c3-c3ccc(-c4cc(-c5ccc6ccccc6c5)cc(-c5ccc6ccccc6c5)n4)cc3)cc2)cc1 ; c1ccc(-c2ccc(-c3nc4ccccn4c3-c3ccc(-c4cc(-c5cc6ccccc6c6ccccc56)cc(-c5cc6ccccc6c6ccccc56)n4)cc3)cc2)cc1 ; c1ccc(-c2ccc(-c3nc4ccccn4c3-c3ccc(-c4cc(-c5cc6ccccc6c6ccccc56)cc(-c5cc6ccccc6c6ccccc56)n4)cc3)cc2)cc1]

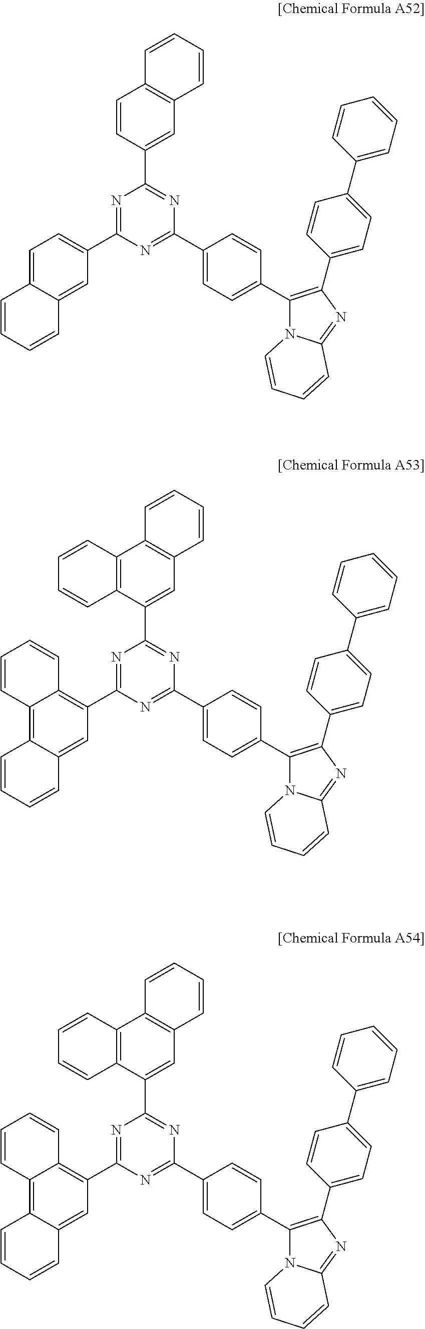 [SMILES: c1ccc(-c2ccc(-c3nc4ccccn4c3-c3ccc(-c4nc(-c5ccc6ccccc6c5)nc(-c5ccc6ccccc6c5)n4)cc3)cc2)cc1 ; c1ccc(-c2ccc(-c3nc4ccccn4c3-c3ccc(-c4nc(-c5cc6ccccc6c6ccccc56)nc(-c5cc6ccccc6c6ccccc56)n4)cc3)cc2)cc1 ; c1ccc(-c2ccc(-c3nc4ccccn4c3-c3ccc(-c4nc(-c5cc6ccccc6c6ccccc56)nc(-c5cc6ccccc6c6ccccc56)n4)cc3)cc2)cc1]

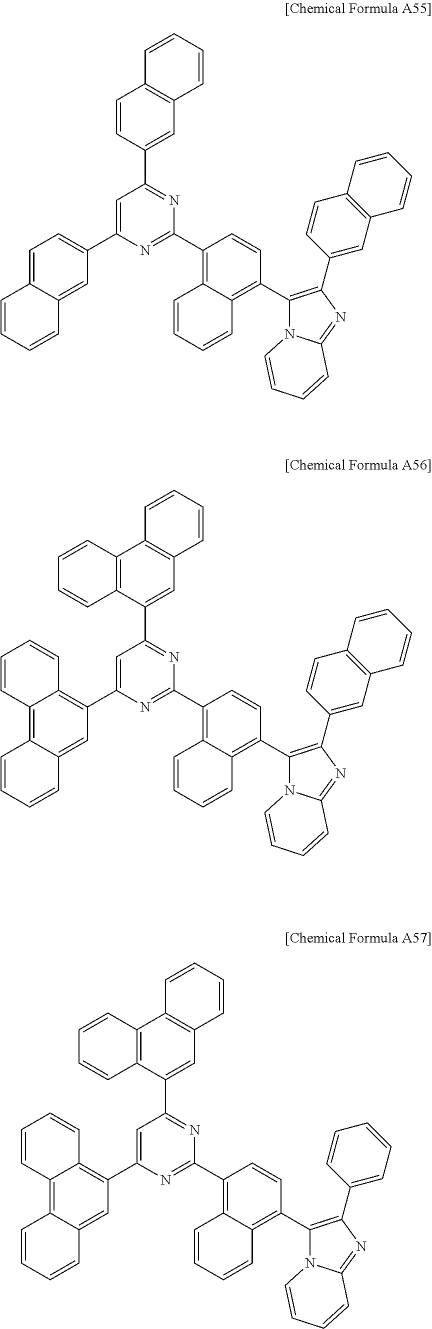 [SMILES: c1ccc2cc(-c3cc(-c4ccc5ccccc5c4)nc(-c4ccc(-c5c(-c6ccc7ccccc7c6)nc6ccccn56)c5ccccc45)n3)ccc2c1 ; c1ccc2cc(-c3nc4ccccn4c3-c3ccc(-c4nc(-c5cc6ccccc6c6ccccc56)cc(-c5cc6ccccc6c6ccccc56)n4)c4ccccc34)ccc2c1 ; c1ccc(-c2nc3ccccn3c2-c2ccc(-c3nc(-c4cc5ccccc5c5ccccc45)cc(-c4cc5ccccc5c5ccccc45)n3)c3ccccc23)cc1]

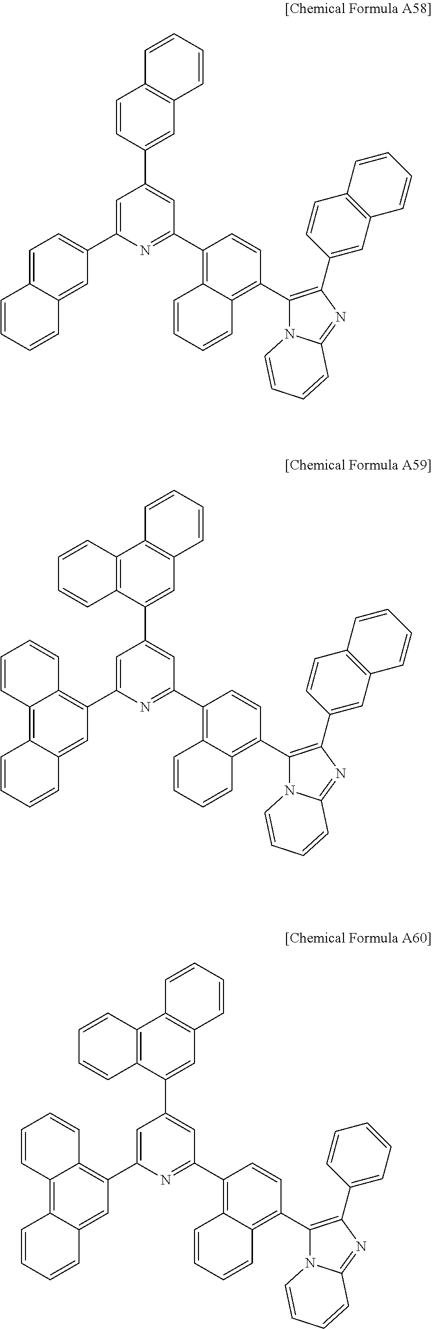 [SMILES: c1ccc2cc(-c3cc(-c4ccc5ccccc5c4)nc(-c4ccc(-c5c(-c6ccc7ccccc7c6)nc6ccccn56)c5ccccc45)c3)ccc2c1 ; c1ccc2cc(-c3nc4ccccn4c3-c3ccc(-c4cc(-c5cc6ccccc6c6ccccc56)cc(-c5cc6ccccc6c6ccccc56)n4)c4ccccc34)ccc2c1 ; c1ccc(-c2nc3ccccn3c2-c2ccc(-c3cc(-c4cc5ccccc5c5ccccc45)cc(-c4cc5ccccc5c5ccccc45)n3)c3ccccc23)cc1]

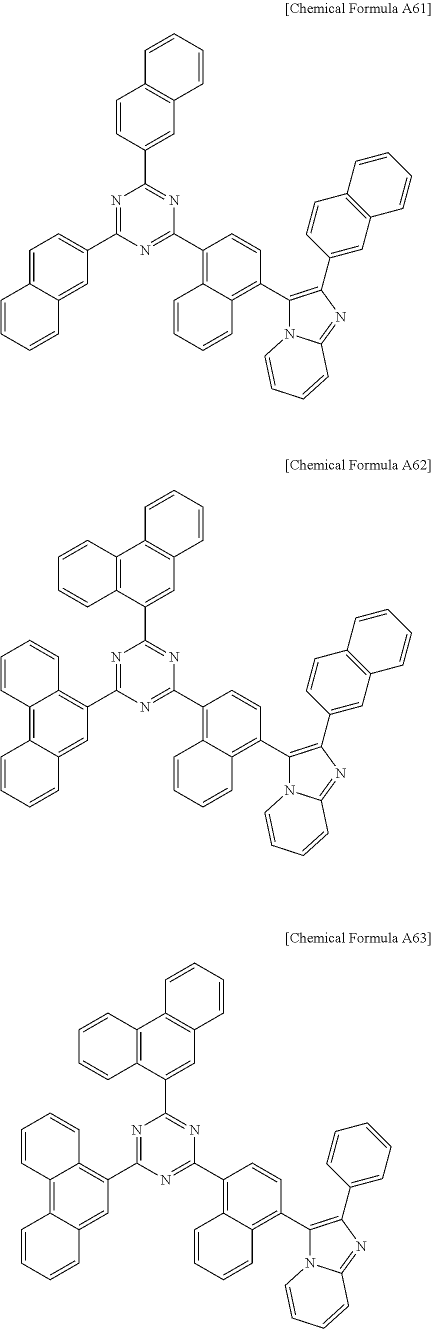 [SMILES: c1ccc2cc(-c3nc(-c4ccc5ccccc5c4)nc(-c4ccc(-c5c(-c6ccc7ccccc7c6)nc6ccccn56)c5ccccc45)n3)ccc2c1 ; c1ccc2cc(-c3nc4ccccn4c3-c3ccc(-c4nc(-c5cc6ccccc6c6ccccc56)nc(-c5cc6ccccc6c6ccccc56)n4)c4ccccc34)ccc2c1 ; c1ccc(-c2nc3ccccn3c2-c2ccc(-c3nc(-c4cc5ccccc5c5ccccc45)nc(-c4cc5ccccc5c5ccccc45)n3)c3ccccc23)cc1]

8. The compound for an organic optoelectronic device as claimed in claim 1, wherein the compound is represented by one of the following Chemical Formulae B1 to B72:

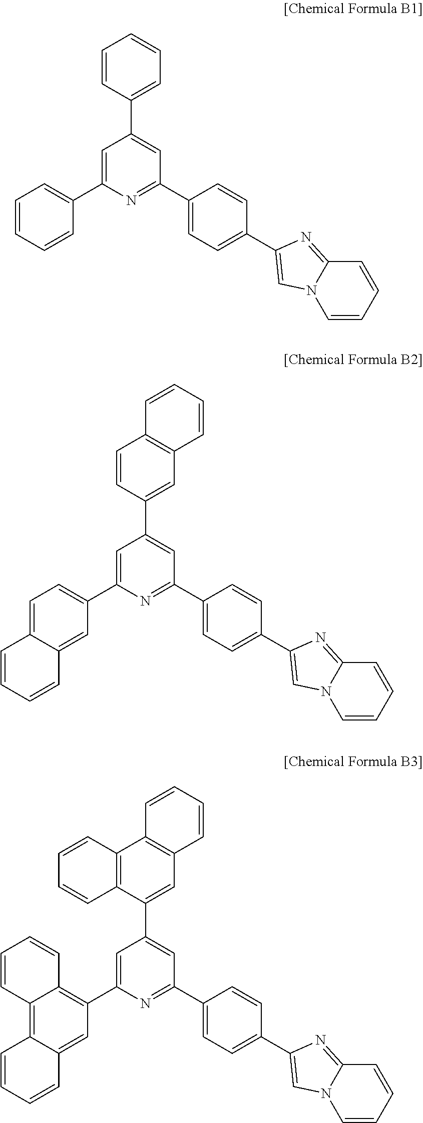 [SMILES: c1ccc(-c2cc(-c3ccccc3)nc(-c3ccc(-c4cn5ccccc5n4)cc3)c2)cc1 ; c1ccc2cc(-c3cc(-c4ccc(-c5cn6ccccc6n5)cc4)nc(-c4ccc5ccccc5c4)c3)ccc2c1 ; c1ccc2c(c1)cc(-c1cc(-c3ccc(-c4cn5ccccc5n4)cc3)nc(-c3cc4ccccc4c4ccccc34)c1)c1ccccc12]

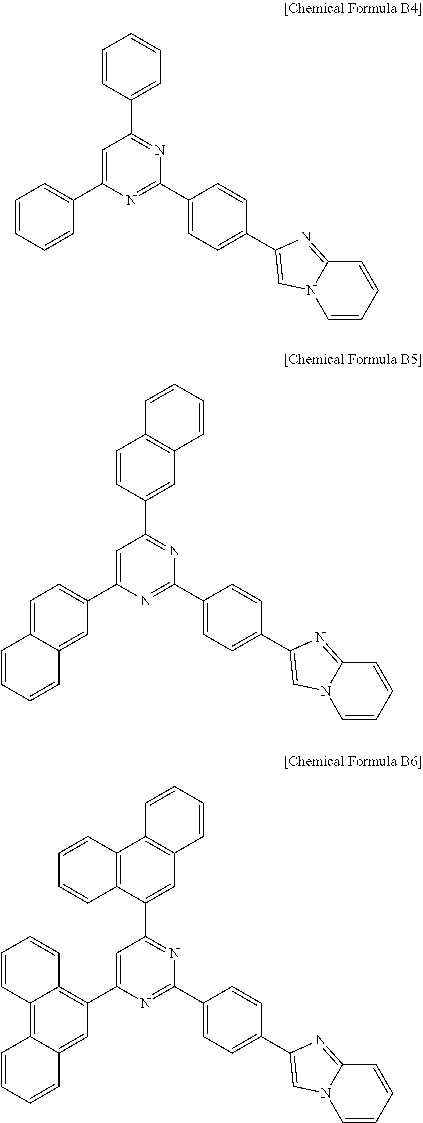 [SMILES: c1ccc(-c2cc(-c3ccccc3)nc(-c3ccc(-c4cn5ccccc5n4)cc3)n2)cc1 ; c1ccc2cc(-c3cc(-c4ccc5ccccc5c4)nc(-c4ccc(-c5cn6ccccc6n5)cc4)n3)ccc2c1 ; c1ccc2c(c1)cc(-c1cc(-c3cc4ccccc4c4ccccc34)nc(-c3ccc(-c4cn5ccccc5n4)cc3)n1)c1ccccc12]

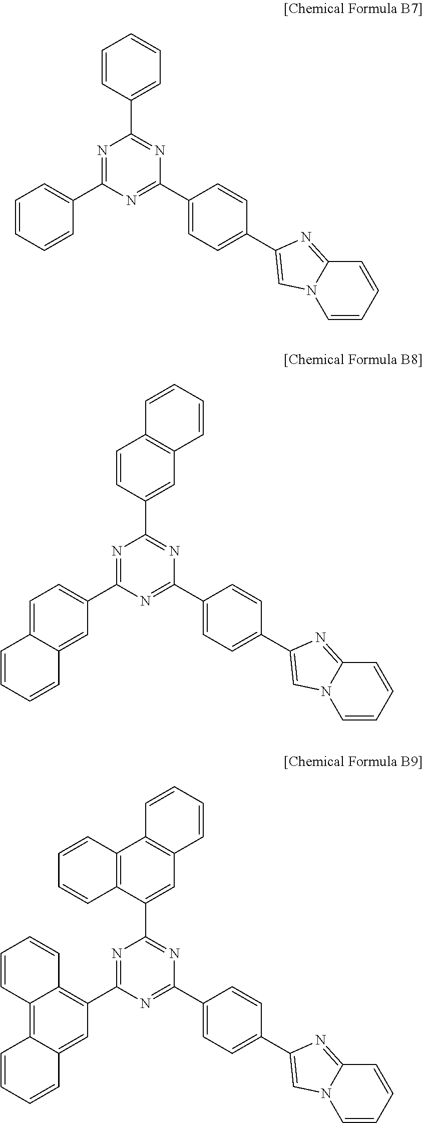 [SMILES: c1ccc(-c2nc(-c3ccccc3)nc(-c3ccc(-c4cn5ccccc5n4)cc3)n2)cc1 ; c1ccc2cc(-c3nc(-c4ccc(-c5cn6ccccc6n5)cc4)nc(-c4ccc5ccccc5c4)n3)ccc2c1 ; c1ccc2c(c1)cc(-c1nc(-c3ccc(-c4cn5ccccc5n4)cc3)nc(-c3cc4ccccc4c4ccccc34)n1)c1ccccc12]

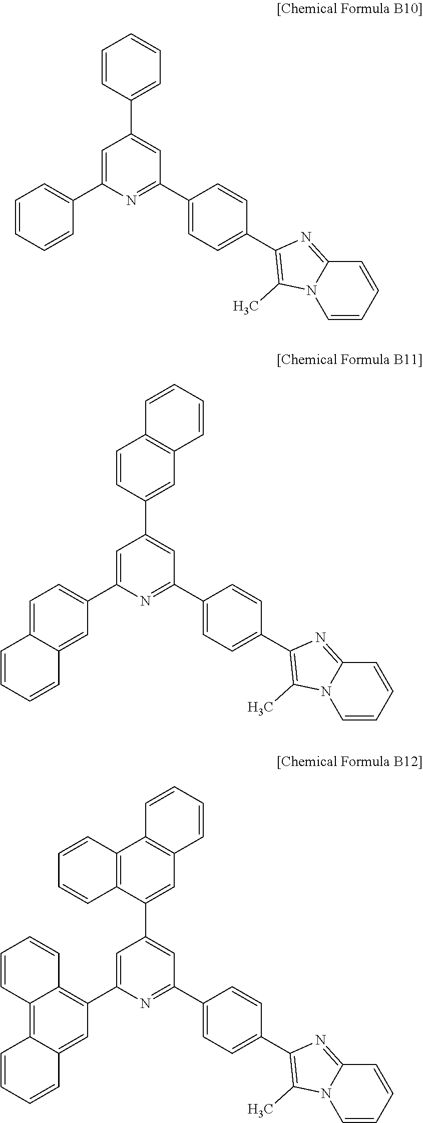 [SMILES: Cc1c(-c2ccc(-c3cc(-c4ccccc4)cc(-c4ccccc4)n3)cc2)nc2ccccn12 ; Cc1c(-c2ccc(-c3cc(-c4ccc5ccccc5c4)cc(-c4ccc5ccccc5c4)n3)cc2)nc2ccccn12 ; Cc1c(-c2ccc(-c3cc(-c4cc5ccccc5c5ccccc45)cc(-c4cc5ccccc5c5ccccc45)n3)cc2)nc2ccccn12]

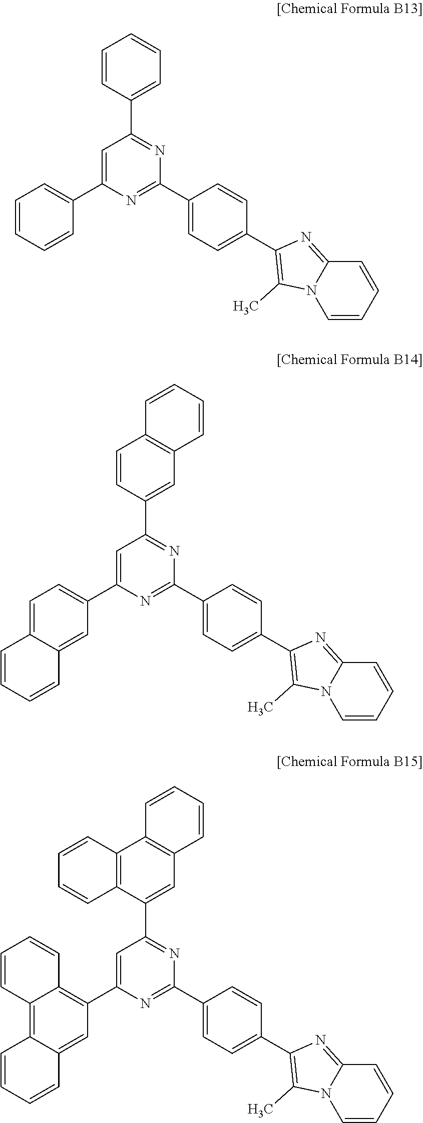 [SMILES: Cc1c(-c2ccc(-c3nc(-c4ccccc4)cc(-c4ccccc4)n3)cc2)nc2ccccn12 ; Cc1c(-c2ccc(-c3nc(-c4ccc5ccccc5c4)cc(-c4ccc5ccccc5c4)n3)cc2)nc2ccccn12 ; Cc1c(-c2ccc(-c3nc(-c4cc5ccccc5c5ccccc45)cc(-c4cc5ccccc5c5ccccc45)n3)cc2)nc2ccccn12]

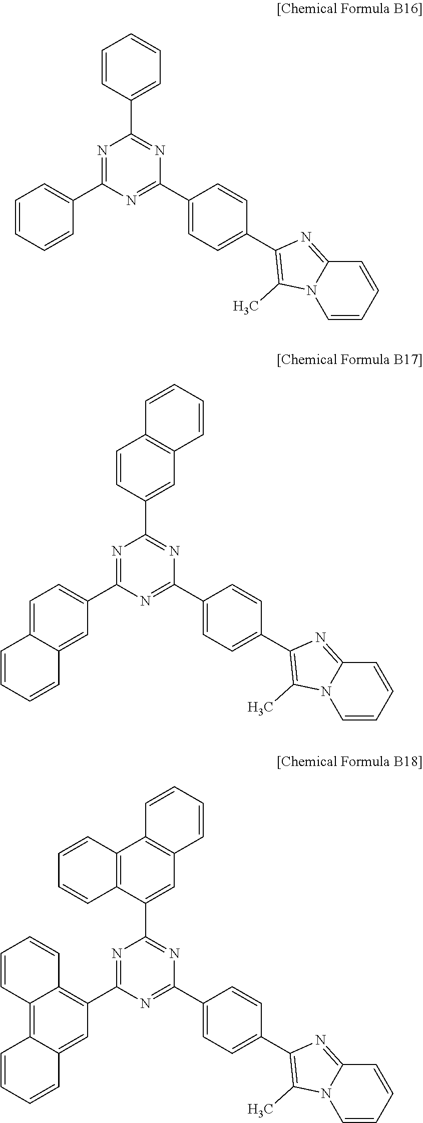 [SMILES: Cc1c(-c2ccc(-c3nc(-c4ccccc4)nc(-c4ccccc4)n3)cc2)nc2ccccn12 ; Cc1c(-c2ccc(-c3nc(-c4ccc5ccccc5c4)nc(-c4ccc5ccccc5c4)n3)cc2)nc2ccccn12 ; Cc1c(-c2ccc(-c3nc(-c4cc5ccccc5c5ccccc45)nc(-c4cc5ccccc5c5ccccc45)n3)cc2)nc2ccccn12]

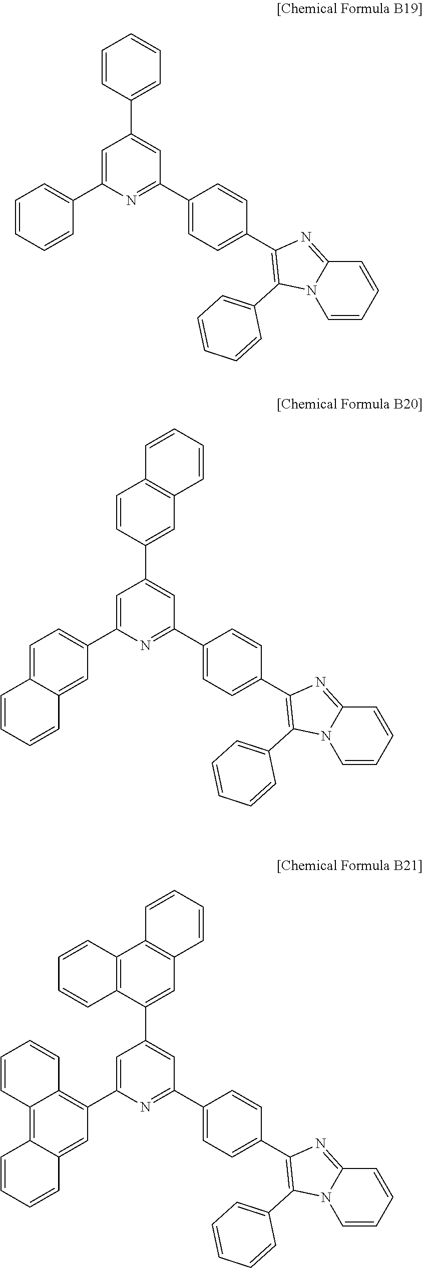 [SMILES: c1ccc(-c2cc(-c3ccccc3)nc(-c3ccc(-c4nc5ccccn5c4-c4ccccc4)cc3)c2)cc1 ; c1ccc(-c2c(-c3ccc(-c4cc(-c5ccc6ccccc6c5)cc(-c5ccc6ccccc6c5)n4)cc3)nc3ccccn23)cc1 ; c1ccc(-c2c(-c3ccc(-c4cc(-c5cc6ccccc6c6ccccc56)cc(-c5cc6ccccc6c6ccccc56)n4)cc3)nc3ccccn23)cc1]

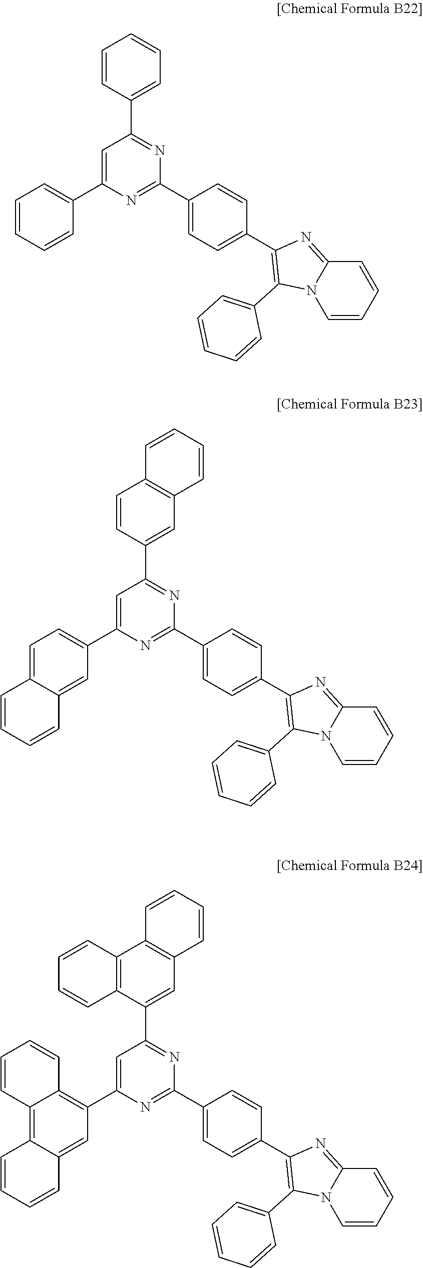 [SMILES: c1ccc(-c2cc(-c3ccccc3)nc(-c3ccc(-c4nc5ccccn5c4-c4ccccc4)cc3)n2)cc1 ; c1ccc(-c2c(-c3ccc(-c4nc(-c5ccc6ccccc6c5)cc(-c5ccc6ccccc6c5)n4)cc3)nc3ccccn23)cc1 ; c1ccc(-c2c(-c3ccc(-c4nc(-c5cc6ccccc6c6ccccc56)cc(-c5cc6ccccc6c6ccccc56)n4)cc3)nc3ccccn23)cc1]

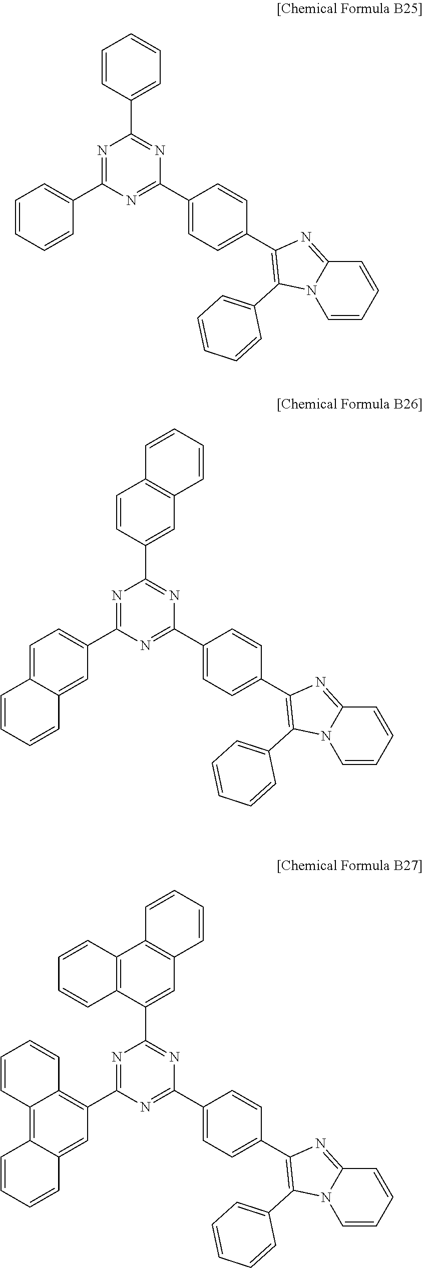 [SMILES: c1ccc(-c2nc(-c3ccccc3)nc(-c3ccc(-c4nc5ccccn5c4-c4ccccc4)cc3)n2)cc1 ; c1ccc(-c2c(-c3ccc(-c4nc(-c5ccc6ccccc6c5)nc(-c5ccc6ccccc6c5)n4)cc3)nc3ccccn23)cc1 ; c1ccc(-c2c(-c3ccc(-c4nc(-c5cc6ccccc6c6ccccc56)nc(-c5cc6ccccc6c6ccccc56)n4)cc3)nc3ccccn23)cc1]

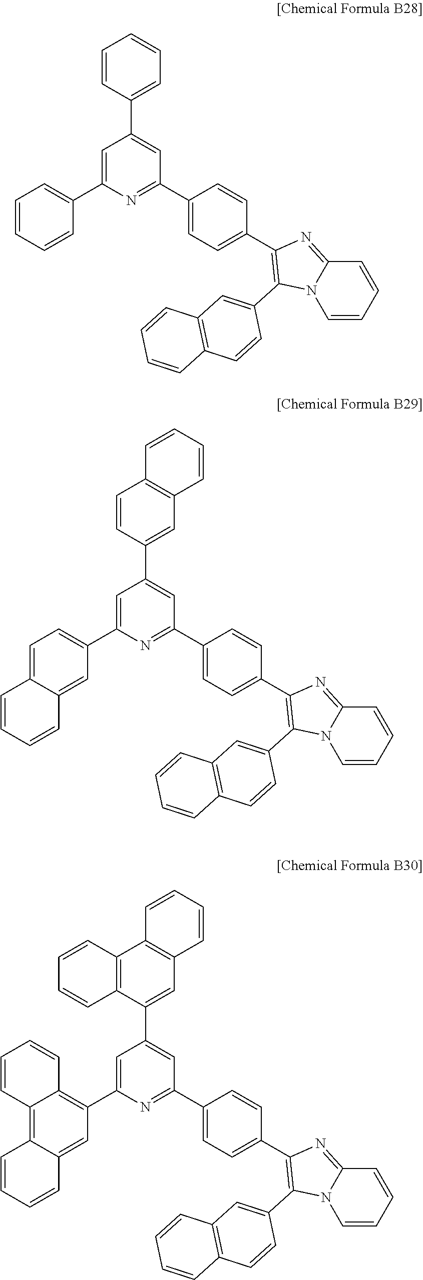 [SMILES: c1ccc(-c2cc(-c3ccccc3)nc(-c3ccc(-c4nc5ccccn5c4-c4ccc5ccccc5c4)cc3)c2)cc1 ; c1ccc2cc(-c3cc(-c4ccc(-c5nc6ccccn6c5-c5ccc6ccccc6c5)cc4)nc(-c4ccc5ccccc5c4)c3)ccc2c1 ; c1ccc2cc(-c3c(-c4ccc(-c5cc(-c6cc7ccccc7c7ccccc67)cc(-c6cc7ccccc7c7ccccc67)n5)cc4)nc4ccccn34)ccc2c1]

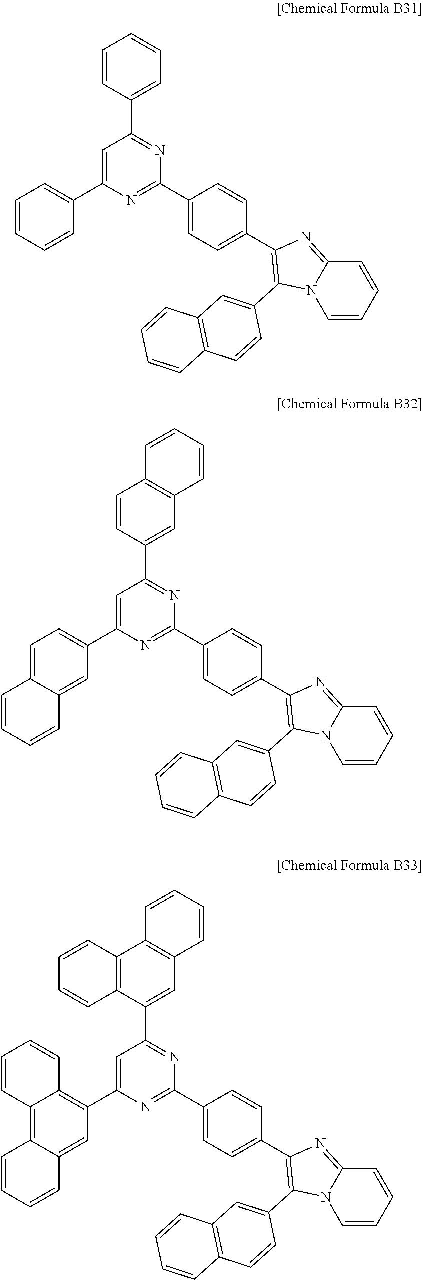 [SMILES: c1ccc(-c2cc(-c3ccccc3)nc(-c3ccc(-c4nc5ccccn5c4-c4ccc5ccccc5c4)cc3)n2)cc1 ; c1ccc2cc(-c3cc(-c4ccc5ccccc5c4)nc(-c4ccc(-c5nc6ccccn6c5-c5ccc6ccccc6c5)cc4)n3)ccc2c1 ; c1ccc2cc(-c3c(-c4ccc(-c5nc(-c6cc7ccccc7c7ccccc67)cc(-c6cc7ccccc7c7ccccc67)n5)cc4)nc4ccccn34)ccc2c1]

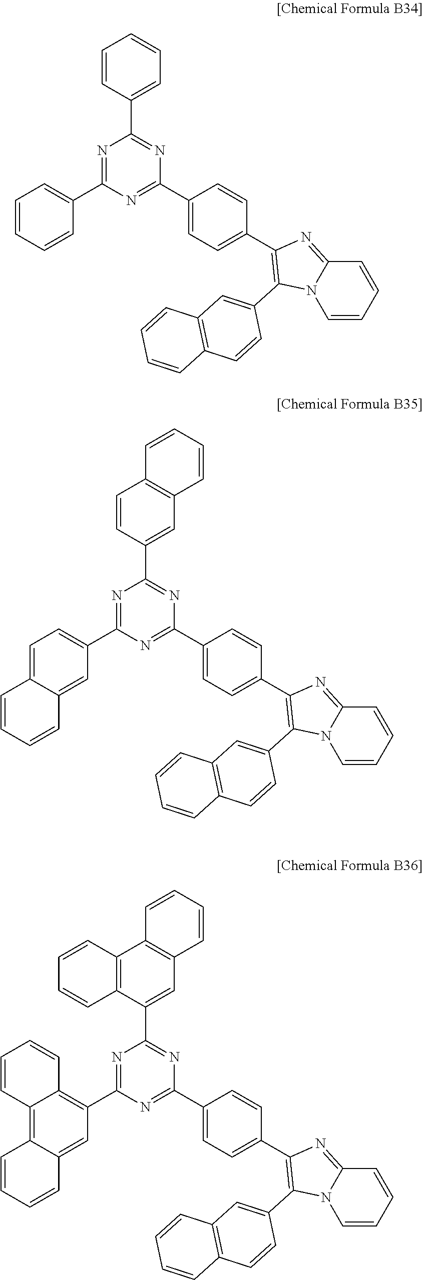 [SMILES: c1ccc(-c2nc(-c3ccccc3)nc(-c3ccc(-c4nc5ccccn5c4-c4ccc5ccccc5c4)cc3)n2)cc1 ; c1ccc2cc(-c3nc(-c4ccc(-c5nc6ccccn6c5-c5ccc6ccccc6c5)cc4)nc(-c4ccc5ccccc5c4)n3)ccc2c1 ; c1ccc2cc(-c3c(-c4ccc(-c5nc(-c6cc7ccccc7c7ccccc67)nc(-c6cc7ccccc7c7ccccc67)n5)cc4)nc4ccccn34)ccc2c1]

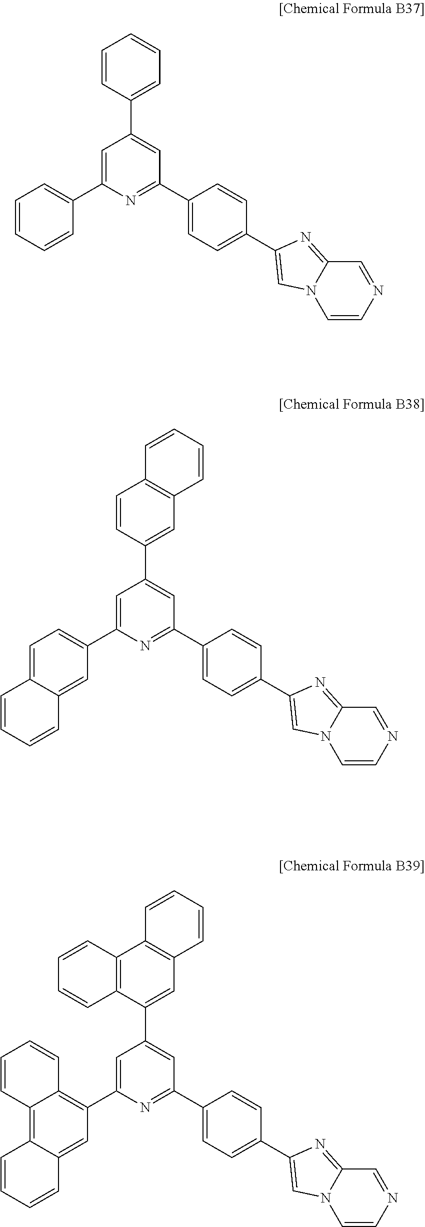 [SMILES: c1ccc(-c2cc(-c3ccccc3)nc(-c3ccc(-c4cn5ccncc5n4)cc3)c2)cc1 ; c1ccc2cc(-c3cc(-c4ccc(-c5cn6ccncc6n5)cc4)nc(-c4ccc5ccccc5c4)c3)ccc2c1 ; c1ccc2c(c1)cc(-c1cc(-c3ccc(-c4cn5ccncc5n4)cc3)nc(-c3cc4ccccc4c4ccccc34)c1)c1ccccc12]

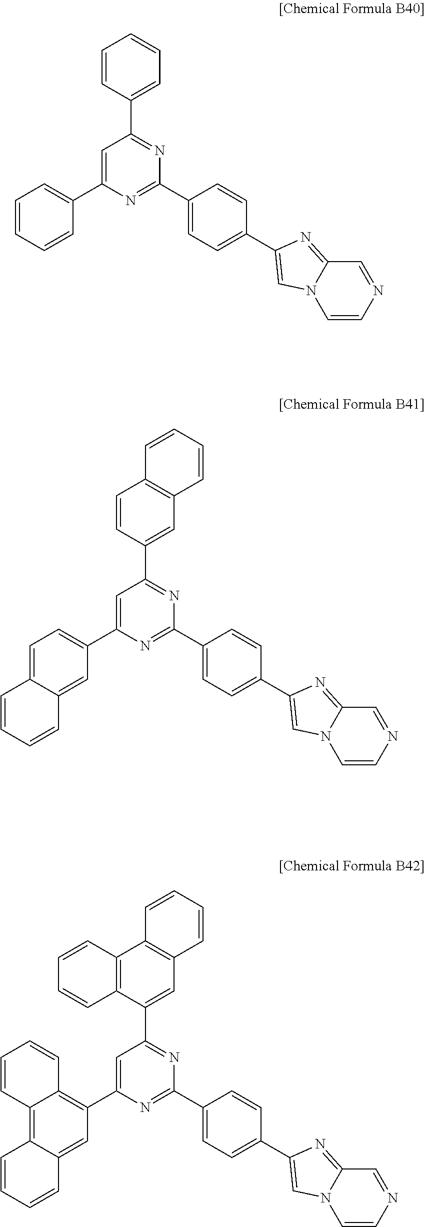 [SMILES: c1ccc(-c2cc(-c3ccccc3)nc(-c3ccc(-c4cn5ccncc5n4)cc3)n2)cc1 ; c1ccc2cc(-c3cc(-c4ccc5ccccc5c4)nc(-c4ccc(-c5cn6ccncc6n5)cc4)n3)ccc2c1 ; c1ccc2c(c1)cc(-c1cc(-c3cc4ccccc4c4ccccc34)nc(-c3ccc(-c4cn5ccncc5n4)cc3)n1)c1ccccc12]

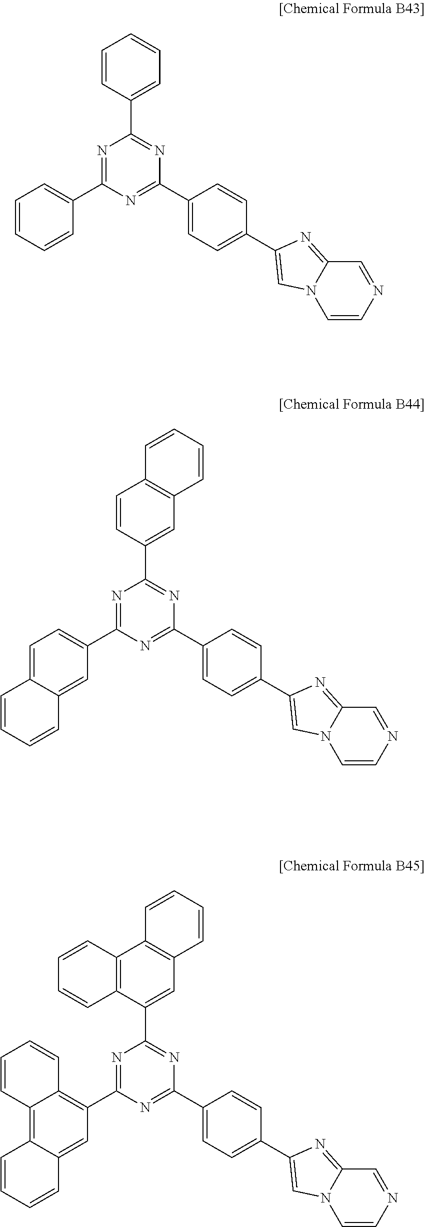 [SMILES: c1ccc(-c2nc(-c3ccccc3)nc(-c3ccc(-c4cn5ccncc5n4)cc3)n2)cc1 ; c1ccc2cc(-c3nc(-c4ccc(-c5cn6ccncc6n5)cc4)nc(-c4ccc5ccccc5c4)n3)ccc2c1 ; c1ccc2c(c1)cc(-c1nc(-c3ccc(-c4cn5ccncc5n4)cc3)nc(-c3cc4ccccc4c4ccccc34)n1)c1ccccc12]

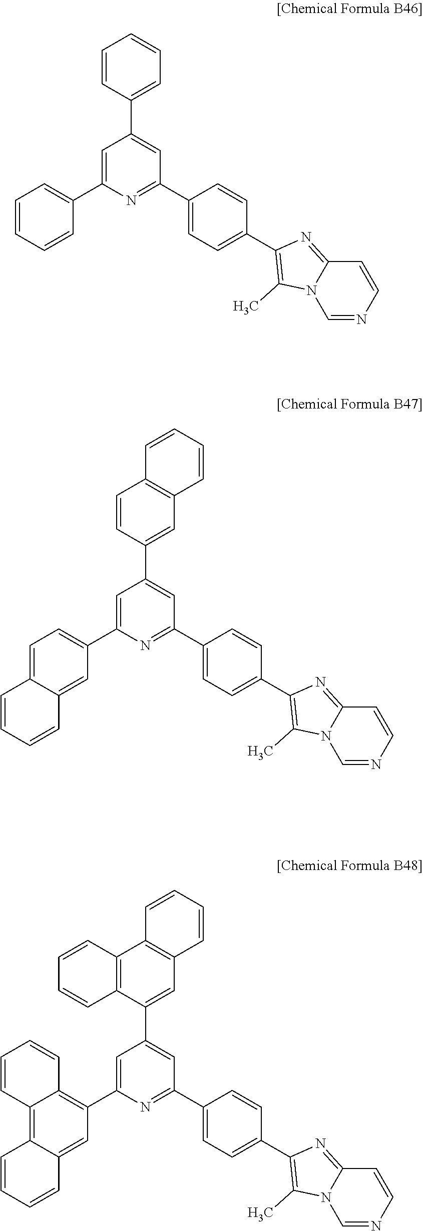 [SMILES: Cc1c(-c2ccc(-c3cc(-c4ccccc4)cc(-c4ccccc4)n3)cc2)nc2ccncn12 ; Cc1c(-c2ccc(-c3cc(-c4ccc5ccccc5c4)cc(-c4ccc5ccccc5c4)n3)cc2)nc2ccncn12 ; Cc1c(-c2ccc(-c3cc(-c4cc5ccccc5c5ccccc45)cc(-c4cc5ccccc5c5ccccc45)n3)cc2)nc2ccncn12]

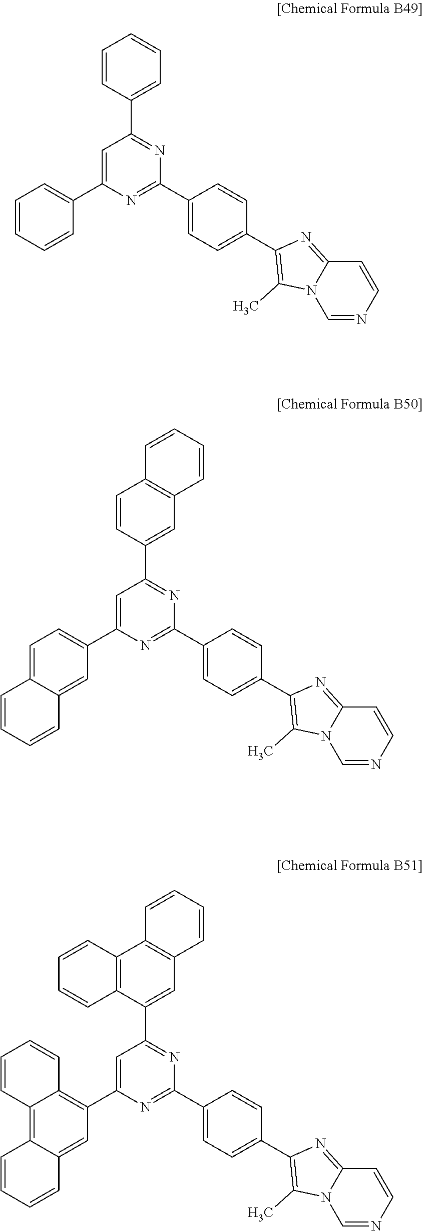 [SMILES: Cc1c(-c2ccc(-c3nc(-c4ccccc4)cc(-c4ccccc4)n3)cc2)nc2ccncn12 ; Cc1c(-c2ccc(-c3nc(-c4ccc5ccccc5c4)cc(-c4ccc5ccccc5c4)n3)cc2)nc2ccncn12 ; Cc1c(-c2ccc(-c3nc(-c4cc5ccccc5c5ccccc45)cc(-c4cc5ccccc5c5ccccc45)n3)cc2)nc2ccncn12]

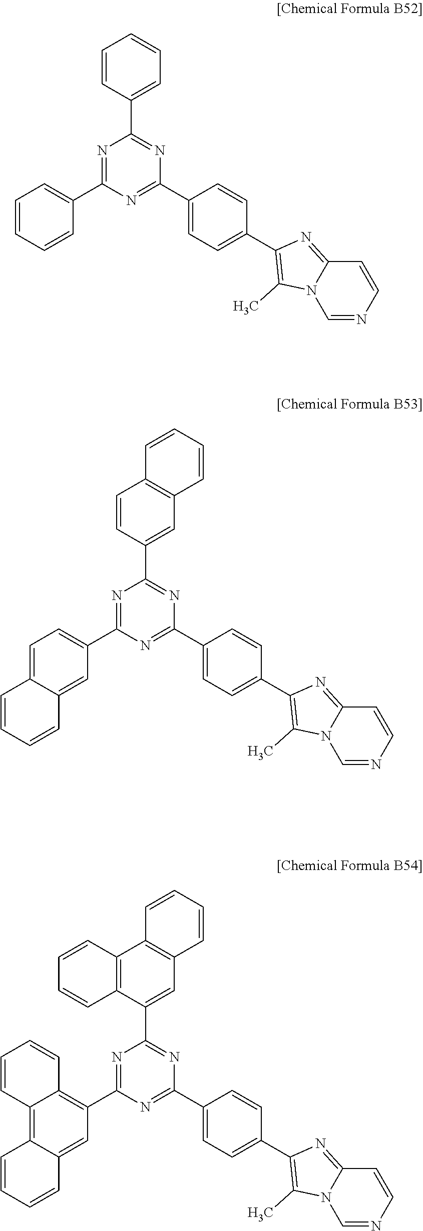 [SMILES: Cc1c(-c2ccc(-c3nc(-c4ccccc4)nc(-c4ccccc4)n3)cc2)nc2ccncn12 ; Cc1c(-c2ccc(-c3nc(-c4ccc5ccccc5c4)nc(-c4ccc5ccccc5c4)n3)cc2)nc2ccncn12 ; Cc1c(-c2ccc(-c3nc(-c4cc5ccccc5c5ccccc45)nc(-c4cc5ccccc5c5ccccc45)n3)cc2)nc2ccncn12]

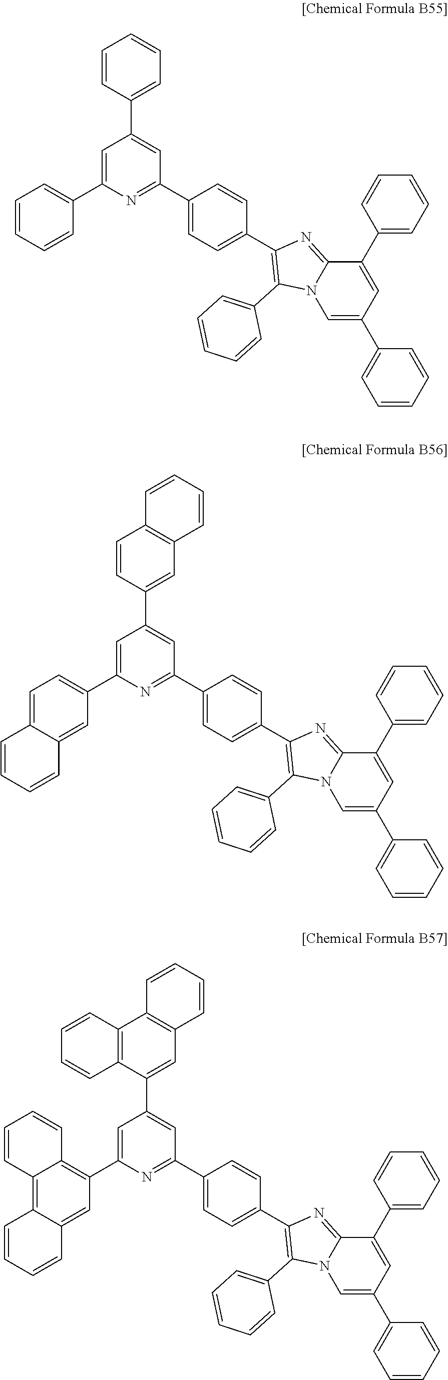 [SMILES: c1ccc(-c2cc(-c3ccccc3)nc(-c3ccc(-c4nc5c(-c6ccccc6)cc(-c6ccccc6)cn5c4-c4ccccc4)cc3)c2)cc1 ; c1ccc(-c2cc(-c3ccccc3)c3nc(-c4ccc(-c5cc(-c6ccc7ccccc7c6)cc(-c6ccc7ccccc7c6)n5)cc4)c(-c4ccccc4)n3c2)cc1 ; c1ccc(-c2cc(-c3ccccc3)c3nc(-c4ccc(-c5cc(-c6cc7ccccc7c7ccccc67)cc(-c6cc7ccccc7c7ccccc67)n5)cc4)c(-c4ccccc4)n3c2)cc1]

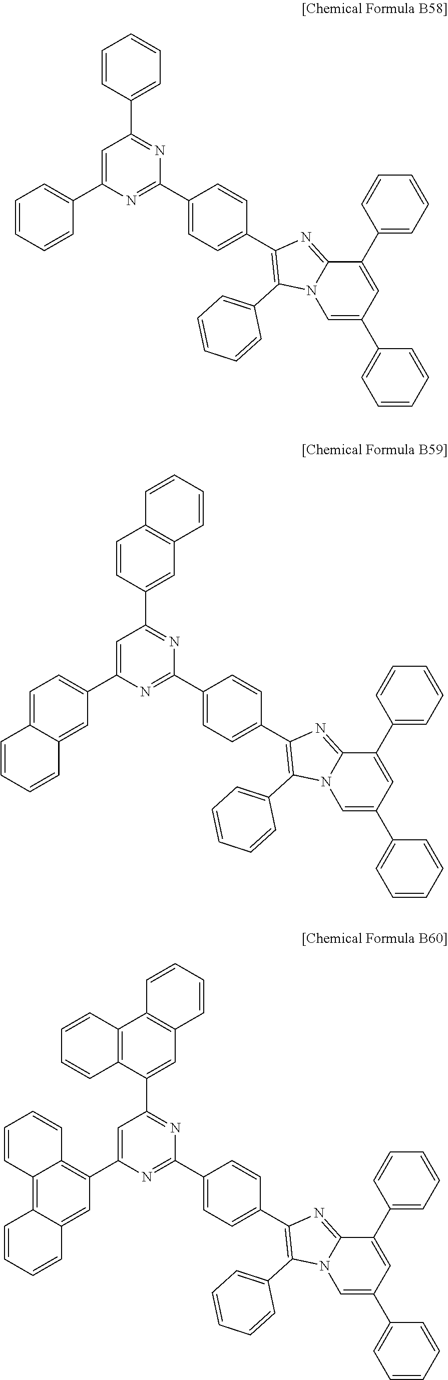 [SMILES: c1ccc(-c2cc(-c3ccccc3)c3nc(-c4ccc(-c5nc(-c6ccccc6)cc(-c6ccccc6)n5)cc4)c(-c4ccccc4)n3c2)cc1 ; c1ccc(-c2cc(-c3ccccc3)c3nc(-c4ccc(-c5nc(-c6ccc7ccccc7c6)cc(-c6ccc7ccccc7c6)n5)cc4)c(-c4ccccc4)n3c2)cc1 ; c1ccc(-c2cc(-c3ccccc3)c3nc(-c4ccc(-c5nc(-c6cc7ccccc7c7ccccc67)cc(-c6cc7ccccc7c7ccccc67)n5)cc4)c(-c4ccccc4)n3c2)cc1]

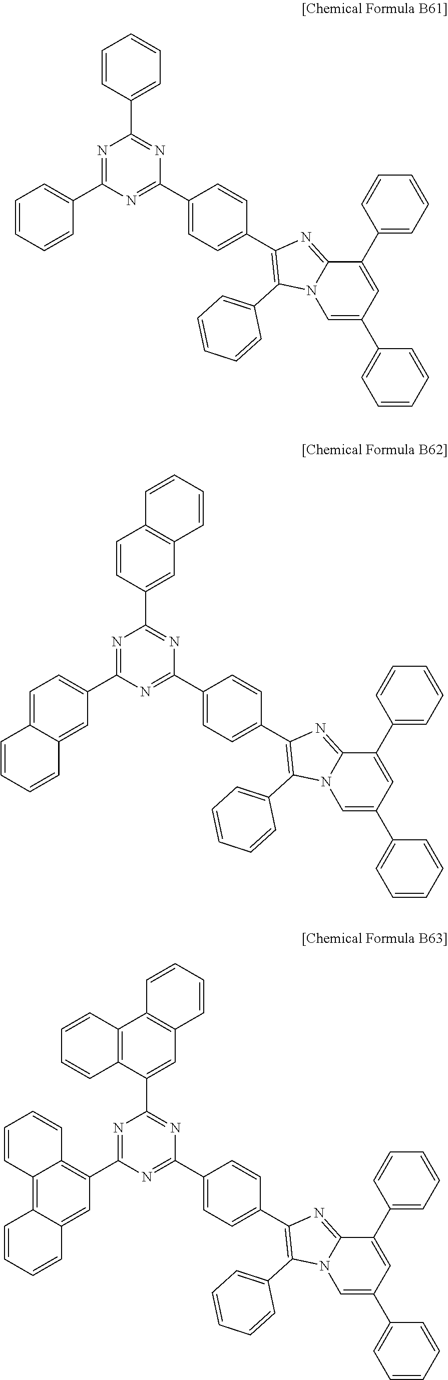 [SMILES: c1ccc(-c2cc(-c3ccccc3)c3nc(-c4ccc(-c5nc(-c6ccccc6)nc(-c6ccccc6)n5)cc4)c(-c4ccccc4)n3c2)cc1 ; c1ccc(-c2cc(-c3ccccc3)c3nc(-c4ccc(-c5nc(-c6ccc7ccccc7c6)nc(-c6ccc7ccccc7c6)n5)cc4)c(-c4ccccc4)n3c2)cc1 ; c1ccc(-c2cc(-c3ccccc3)c3nc(-c4ccc(-c5nc(-c6cc7ccccc7c7ccccc67)nc(-c6cc7ccccc7c7ccccc67)n5)cc4)c(-c4ccccc4)n3c2)cc1]

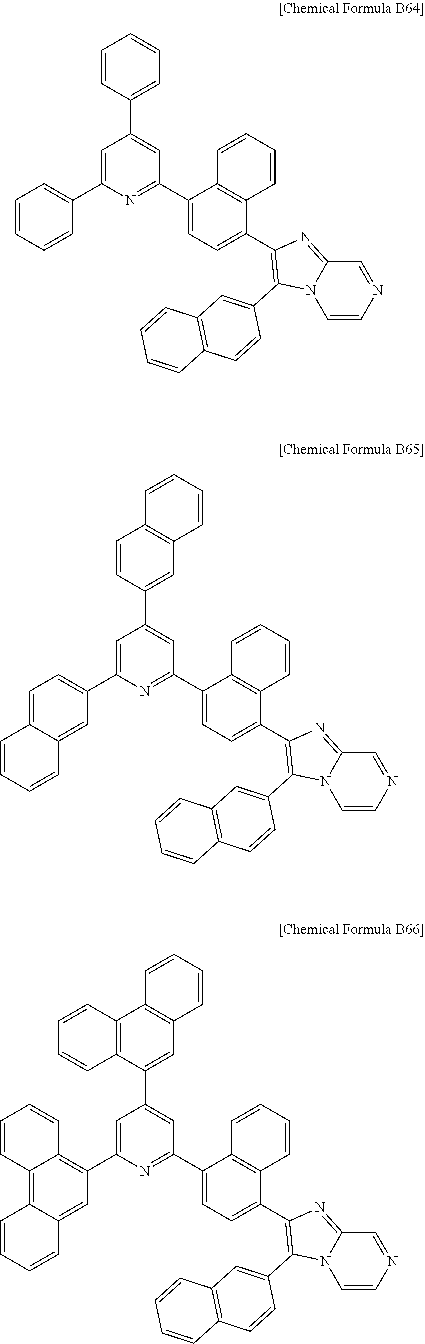 [SMILES: c1ccc(-c2cc(-c3ccccc3)nc(-c3ccc(-c4nc5cnccn5c4-c4ccc5ccccc5c4)c4ccccc34)c2)cc1 ; c1ccc2cc(-c3cc(-c4ccc5ccccc5c4)nc(-c4ccc(-c5nc6cnccn6c5-c5ccc6ccccc6c5)c5ccccc45)c3)ccc2c1 ; c1ccc2cc(-c3c(-c4ccc(-c5cc(-c6cc7ccccc7c7ccccc67)cc(-c6cc7ccccc7c7ccccc67)n5)c5ccccc45)nc4cnccn34)ccc2c1]

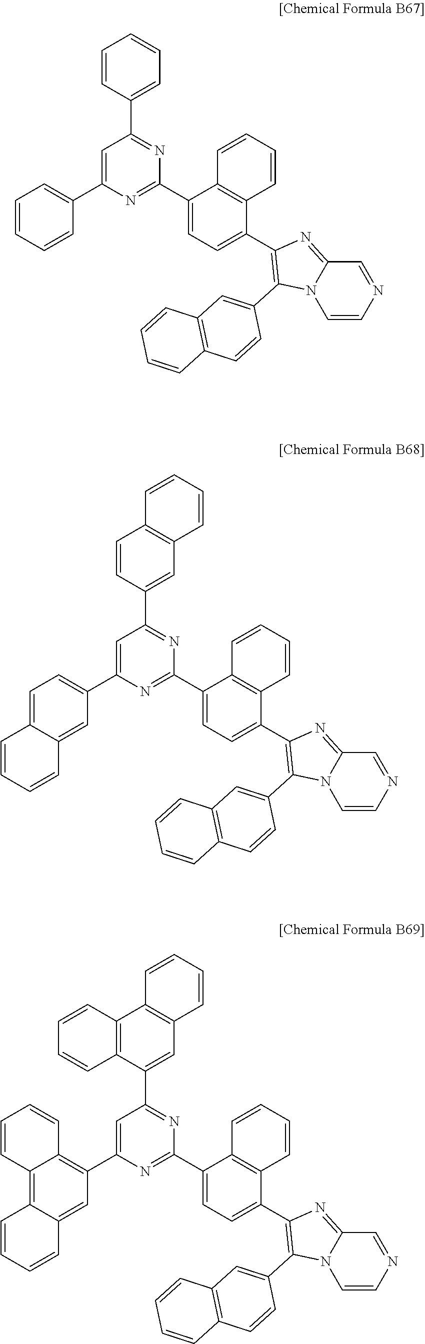 [SMILES: c1ccc(-c2cc(-c3ccccc3)nc(-c3ccc(-c4nc5cnccn5c4-c4ccc5ccccc5c4)c4ccccc34)n2)cc1 ; c1ccc2cc(-c3cc(-c4ccc5ccccc5c4)nc(-c4ccc(-c5nc6cnccn6c5-c5ccc6ccccc6c5)c5ccccc45)n3)ccc2c1 ; c1ccc2cc(-c3c(-c4ccc(-c5nc(-c6cc7ccccc7c7ccccc67)cc(-c6cc7ccccc7c7ccccc67)n5)c5ccccc45)nc4cnccn34)ccc2c1]

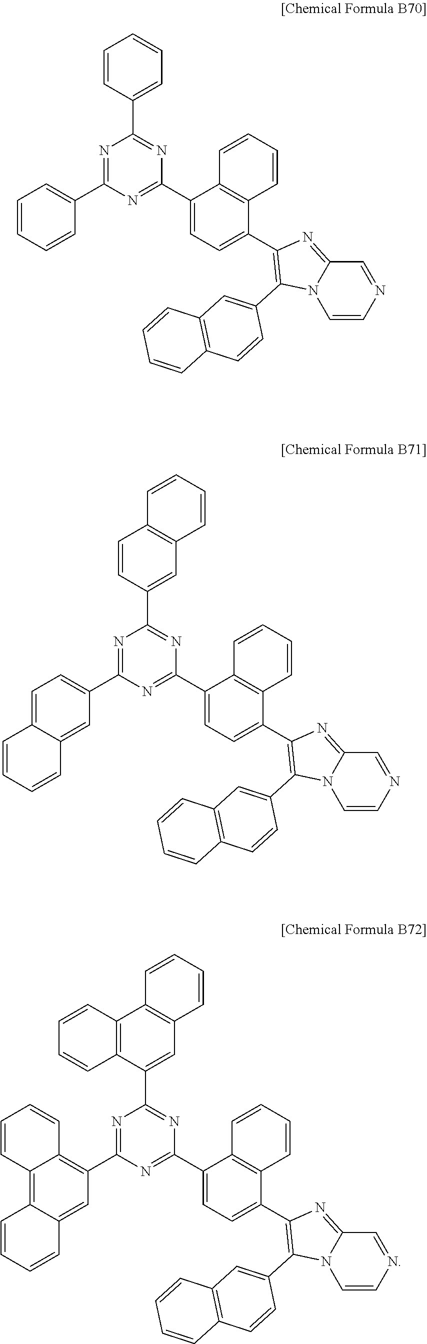 [SMILES: c1ccc(-c2nc(-c3ccccc3)nc(-c3ccc(-c4nc5cnccn5c4-c4ccc5ccccc5c4)c4ccccc34)n2)cc1 ; c1ccc2cc(-c3nc(-c4ccc5ccccc5c4)nc(-c4ccc(-c5nc6cnccn6c5-c5ccc6ccccc6c5)c5ccccc45)n3)ccc2c1 ; c1ccc2cc(-c3c(-c4ccc(-c5nc(-c6cc7ccccc7c7ccccc67)nc(-c6cc7ccccc7c7ccccc67)n5)c5ccccc45)nc4cnccn34)ccc2c1]

9. The compound for an organic optoelectronic device as claimed in claim 1, wherein the organic optoelectronic device is selected from the group of an organic light emitting diode, an organic solar cell, an organic transistor, an organic photo-conductor drum, and an organic memory device.

10. An organic light emitting diode, comprising:
an anode;
a cathode; and
at least one organic thin layer between the anode and cathode,
wherein the at least one organic thin layer includes the compound for an organic optoelectronic device as claimed in claim 1.

11. The organic light emitting diode as claimed in claim 10, wherein the at least one organic thin layer includes one selected from the group of an emission layer, a hole transport layer (HTL), a hole injection layer (HIL), an electron transport layer (ETL), an electron injection layer (EIL), a hole blocking layer, and a combination thereof.

12. The organic light emitting diode as claimed in claim 10, wherein:
the at least one organic thin layer includes an electron transport layer (ETL) or an electron injection layer (EIL), and
the compound for an organic optoelectronic device is included in the electron transport layer (ETL) or the electron injection layer (EIL).

13. The organic light emitting diode as claimed in claim 10, wherein:
the at least one organic thin layer includes an emission layer, and
the compound for an organic optoelectronic device is included in the emission layer.

14. The organic light emitting diode as claimed in claim 10, wherein:
the at least one organic thin layer includes an emission layer, and
the compound for an organic optoelectronic device is a phosphorescent or fluorescent host material in the emission layer.

15. The organic light emitting diode as claimed in claim 10, wherein:
the at least one organic thin layer includes an emission layer, and
the compound for an organic optoelectronic device is a fluorescent blue dopant material in the emission layer.

16. A display device comprising the organic light emitting diode as claimed in claim 10.
